(19) United States
(12) Patent Application Publication
(10) Pub. No.: US 2025/0008793 A1
(43) Pub. Date: Jan. 2, 2025

(54) ELECTRONIC DEVICE

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Kenichi OKAZAKI, Atsugi, Kanagawa (JP); Satoru IDOJIRI, Tochigi, Tochigi (JP); Hiroki ADACHI, Tochigi, Tochigi (JP)

(21) Appl. No.: 18/560,082

(22) PCT Filed: Apr. 27, 2022
(86) PCT No.: PCT/IB2022/053882

§ 371 Date: Nov. 9, 2023

(30) Foreign Application Priority Data
May 13, 2021 (JP) 2021-081788

(51) Int. Cl. H10K 59/131; H10K 59/00; H10K 59/35; H10K 102/00

(52) U.S. Cl. CPC H10K 59/131; H10K 59/771; H10K 59/353; H10K 2102/311

(57) ABSTRACT

One embodiment of the present invention provides a novel display apparatus that is highly convenient or reliable. A plurality of pixel regions (also referred to as display regions) are combined to obtain a display apparatus for components inside a motor vehicle. Specifically, a display with a curved display surface is installed as a vehicle interior of a motor vehicle or the like. A wiring layer is provided in a support body having a curved surface, and the wiring layer and part of a signal line in a pixel region are electrically connected to each other. Moreover, by using a structure in which a plurality of adjacent pixel regions overlap with each other so as to have a small gap therebetween, a joint between the pixel regions is made less noticeable, and preferably invisible.

### TECHNICAL FIELD

One embodiment of the present invention relates to a display apparatus, an electronic device, or a semiconductor device.

Note that one embodiment of the present invention is not limited to the above technical field. The technical field of one embodiment of the invention disclosed in this specification and the like relates to an object, a method, or a manufacturing method. Alternatively, one embodiment of the present invention relates to a process, a machine, manufacture, or a composition of matter. Thus, more specifically, examples of the technical field of one embodiment of the present invention disclosed in this specification include a semiconductor device, a display apparatus, a light-emitting apparatus, a power storage device, a memory device, a driving method thereof, and a manufacturing method thereof.

Note that semiconductor devices in this specification mean all devices that can function by utilizing semiconductor characteristics, and an electro-optical device, a semiconductor circuit, and an electronic device are all semiconductor devices.

### BACKGROUND ART

Development is advanced to replace part of an instrument display in a motor vehicle or the like with a liquid crystal display apparatus. Development is also advanced to use an organic light-emitting display apparatus in part of an instrument display. Approaches to supporting a driver in a vehicle such as a motor vehicle have also been taken by displaying more information (e.g., information on the situation around a car, traffic information, and geographic information).

In the future, there is a possibility that a large number of cameras or sensors will be installed inside and outside a motor vehicle and thus a large number of displays will be needed.

Patent Document 1 discloses a structure in which a display portion is provided around a driver's seat of a motor vehicle and a structure in which a display panel having a curved surface is provided in a motor vehicle.

Patent Document 2 discloses a structure in which a display panel having a curved portion is provided using a plurality of light-emitting panels.

Patent Document 3 discloses a dual-emission display apparatus that is installed in a vehicle.

### REFERENCES

### Patent Documents

[Patent Document 1] Japanese Published Patent Application No. 2003-229548
[Patent Document 2] Japanese Published Patent Application No. 2015-207556
[Patent Document 3] Japanese Published Patent Application No. 2005-67367

### SUMMARY OF THE INVENTION

### Problems to be Solved by the Invention

An object of one embodiment of the present invention is to provide a novel light-emitting apparatus that is highly convenient or reliable. Another object is to provide a novel display apparatus that is highly convenient or reliable. Another object is to provide a novel input/output apparatus that is highly convenient or reliable. Another object is to provide a novel light-emitting apparatus, a novel display apparatus, a novel input/output apparatus, or a novel semiconductor device.

Light-emitting apparatuses (also referred to as EL devices or EL elements) utilizing electroluminescence (hereinafter referred to as EL) that are used in organic light-emitting display apparatuses have features such as ease of reduction in thickness and weight, high-speed response to input signals, and driving with a constant DC voltage power source, and are used in display apparatuses.

Note that the description of these objects does not preclude the presence of other objects. Note that one embodiment of the present invention does not have to achieve all the objects. Other objects will be apparent from the description of the specification, the drawings, the claims, and the like, and other objects can be derived from the description of the specification, the drawings, the claims, and the like.

### Means for Solving the Problems

A plurality of pixel regions (also referred to as display regions) are combined to obtain a display apparatus for components provided inside a motor vehicle. Specifically, a display with a curved display surface is installed as a vehicle interior of a motor vehicle or the like.

In one embodiment of the present invention, a wiring layer is provided over a support body having a curved surface, and the wiring layer and part of a signal line in a pixel region are electrically connected to each other. Moreover, by using a structure in which a plurality of adjacent pixel regions overlap with each other so as to have a small gap therebetween, a joint between the pixel regions is made less noticeable, and preferably invisible.

A driver circuit may be provided, and a display surface is provided to overlap with the driver circuit, so that a large display screen can be obtained.

One embodiment of the present invention disclosed in this specification is an electronic device including a display apparatus and a support body. The display apparatus includes a first flexible substrate, a second flexible substrate, a first display apparatus formed over the first flexible substrate, a second display apparatus formed over the second flexible substrate, a first electrode electrically connected to the first display apparatus, and a second electrode electrically connected to the second display apparatus. The support body includes a curved surface and a wiring layer formed along the curved surface. The first display apparatus is electrically connected to the wiring layer through the first electrode, and the second display apparatus is electrically connected to the wiring layer through the second electrode. Each of the first display apparatus and the second display apparatus is provided along the curved surface.

In the above structure, the first display apparatus includes a pixel region. The pixel region includes a first light-emitting apparatus and a second light-emitting apparatus adjacent to the first light-emitting apparatus. Each of the first light-emitting apparatus and the second light-emitting apparatus includes a lower electrode, a first functional layer over the lower electrode, a light-emitting layer over the first functional layer, a second functional layer over the light-emitting layer, and an upper electrode over the second functional layer. A side surface of the first functional layer and a side surface of the light-emitting layer are aligned or substantially aligned in a cross-sectional view. A side surface of the second functional layer and a side surface of the light-emitting layer are aligned or substantially aligned in a cross-sectional view.

Light-emitting apparatuses may have a structure for white light emission. Each of the first light-emitting apparatus and the second light-emitting apparatus includes a lower electrode, a first functional layer over the lower electrode, a light-emitting layer over the first functional layer, a second functional layer over the light-emitting layer, and an upper electrode over the second functional layer.

A structure in which light-emitting apparatuses are stacked may be employed for white light emission. Each of the first light-emitting apparatus and the second light-emitting apparatus includes a lower electrode, a first functional layer over the lower electrode, a first light-emitting layer over the first functional layer, a common layer over the first light-emitting layer, a second light-emitting layer over the common layer, a second functional layer over the second light-emitting layer, and an upper electrode over the second functional layer.

The light-emitting apparatuses may have a structure without a hole-transport layer or the like. In that case, the first functional layer includes one or both of a hole-injection layer and a hole-transport layer, and the second functional layer includes one or both of an electron-transport layer and an electron-injection layer.

Without being limited to the white light emission, light emitted from the first light-emitting apparatus and light emitted from the second light-emitting apparatus may have the same color.

The first light-emitting apparatus includes a first lower electrode, a first functional layer over the first lower electrode, a first light-emitting layer over the first functional layer, a second functional layer over the first light-emitting layer, and an upper electrode over the second functional layer. The second light-emitting apparatus includes a second lower electrode, a third functional layer over the second lower electrode, a second light-emitting layer over the third functional layer, and a fourth functional layer over the second light-emitting layer.

The first light-emitting apparatus includes a first lower electrode, a first functional layer over the first lower electrode, a third light-emitting layer over the first functional layer, a first common layer over the third light-emitting layer, a fourth light-emitting layer over the first common layer, a second functional layer over the fourth light-emitting layer, and an upper electrode over the second functional layer. The second light-emitting apparatus includes a second lower electrode, a third functional layer over the second lower electrode, a fifth light-emitting layer over the third functional layer, a second common layer over the fifth light-emitting layer, a sixth light-emitting layer over the second common layer, a fourth functional layer over the sixth light-emitting layer, and an upper electrode over the fourth functional layer.

Each of the first functional layer and the third functional layer includes one or both of a hole-injection layer and a hole-transport layer. Each of the second functional layer and the fourth functional layer includes one or both of an electron-transport layer and an electron-injection layer.

Light emitted from the first light-emitting apparatus and light emitted from the second light-emitting apparatus may be different from each other.

Each of the above structures may include a region in which a distance between a side surface of the first light-emitting apparatus and a side surface of the second light-emitting apparatus is less than or equal to 1 μm.

Each of the above structures may include a region in which a distance between a side surface of the first light-emitting apparatus and a side surface of the second light-emitting apparatus is less than or equal to 100 nm.

This structure may be employed for a lighting device emitting light of a single color or a plurality of colors without being limited to a display apparatus displaying full-color images.

In this specification and the like, a device manufactured using a metal mask or an FMM (a fine metal mask or a high-resolution metal mask) is sometimes referred to as a device having an MM (metal mask) structure. In this specification and the like, a device manufactured without using a metal mask or an FMM is sometimes referred to as a device having an MML (metal maskless) structure.

Note that in this specification and the like, a structure in which light-emitting layers in light-emitting apparatuses of respective colors (here, blue (B), green (G), and red (R)) are at least separately formed or the light-emitting layers are at least separately patterned is sometimes referred to as an SBS (Side By Side) structure. In this specification and the like, a light-emitting apparatus capable of emitting white light is sometimes referred to as a white-light-emitting device. Note that a combination of a white light-emitting apparatus with a coloring layer (e.g., a color filter) enables a full-color display apparatus.

Note that in this specification, an EL (Electroluminescence) layer refers to a layer provided between a pair of electrodes in a light-emitting apparatus. Thus, a light-emitting layer containing an organic compound that is a light-emitting substance, which is interposed between electrodes, is one embodiment of the EL layer.

The light-emitting apparatus can be roughly classified into a single structure and a tandem structure. A device having a single structure includes one light-emitting unit between a pair of electrodes, and the light-emitting unit preferably includes one or more light-emitting layers. To obtain white light emission, two or more light-emitting layers are selected such that emission colors of the light-emitting layers are complementary colors. For example, when emission color of a first light-emitting layer and emission color of a second light-emitting layer are complementary colors, the light-emitting apparatus can be configured to emit white light as a whole. The same applies to a light-emitting apparatus including three or more light-emitting layers.

A light-emitting apparatus having a tandem structure includes two or more light-emitting units between a pair of electrodes, and each light-emitting unit preferably includes one or more light-emitting layers. To obtain white light emission, the structure is made so that light from light-emitting layers of the light-emitting units can be combined to be white light. Note that a structure for obtaining white light emission is similar to a structure in the case of a single structure. Note that for the light-emitting apparatus having a tandem structure, it is preferable that an intermediate layer such as a charge-generation layer be provided between a plurality of light-emitting units.

When the above white light-emitting apparatus (the single structure or the tandem structure) and a light-emitting apparatus having an SBS structure are compared, the light-emitting apparatus having the SBS structure can have lower power consumption than the white light-emitting apparatus. To reduce power consumption, the light-emitting apparatus having an SBS structure is suitably used. By contrast, the white light-emitting apparatus is suitable in terms of lower manufacturing cost or higher manufacturing yield because the manufacturing process of the white light-emitting apparatus is simpler than that of the light-emitting apparatus having an SBS structure.

Note that in this specification, the light-emitting apparatus refers to an image display apparatus or a light source (including a lighting device). In addition, a light-emitting apparatus includes any of the following modules in its category: a module in which a connector such as a flexible printed circuit (FPC) or a TCP (Tape Carrier Package) is attached to a display apparatus; a module having a TCP provided with a printed wiring board at the end thereof; and a module having an IC (integrated circuit) directly mounted on a substrate over which a light-emitting apparatus is formed by a COG (Chip On Glass) method.

### Effect of the Invention

According to one embodiment of the present invention, the manufacturing method disclosed herein enables a display surface area of a display apparatus to be increased, enabling fabrication of the display apparatus with a high yield.

In the case where an omnidirectional camera is used as an in-vehicle camera, the display apparatus of one embodiment of the present invention enables images captured by the omnidirectional camera to be displayed at once in an easy-to-see manner for a user.

The use of the display apparatus of one embodiment of the present invention enables the design flexibility of the display apparatus to be increased, which improves the convenience of the display apparatus and the design of the display apparatus.

Note that the description of these effects does not preclude the presence of other effects. Note that one embodiment of the present invention does not necessarily have all of these effects. Other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A and FIG. 1B are schematic cross-sectional views illustrating one embodiment of the present invention.

FIG. 2A and FIG. 2B are schematic cross-sectional views illustrating one embodiment of the present invention.

FIG. 3A to FIG. 3D are cross-sectional views illustrating a manufacturing process of one embodiment of the present invention.

FIG. 4A to FIG. 4C are cross-sectional views illustrating a manufacturing process of one embodiment of the present invention.

FIG. 5A to FIG. 5D are cross-sectional views illustrating a manufacturing process of one embodiment of the present invention.

FIG. 6A is a top view illustrating an example of a display region 100, and FIG. 6B is a cross-sectional view illustrating an example of the display region 100.

FIG. 7A to FIG. 7E are top views illustrating examples of a pixel.

FIG. 8A to FIG. 8E are top views illustrating examples of a pixel.

FIG. 9A and FIG. 9B are diagrams illustrating a structure example of a display apparatus.

FIG. 10A to FIG. 10C are diagrams illustrating a structure example of a display apparatus.

FIG. 11A, FIG. 11B, and FIG. 11D are cross-sectional views illustrating an example of a display apparatus. FIG. 11C and FIG. 11E are diagrams illustrating examples of images. FIG. 11F to FIG. 11H are top views illustrating examples of a pixel.

FIG. 12A is a cross-sectional view illustrating a structure example of a display apparatus. FIG. 12B to FIG. 12D are top views illustrating examples of a pixel.

FIG. 13A is a cross-sectional view illustrating a structure example of a display apparatus. FIG. 13B to FIG. 13I are top views illustrating examples of a pixel.

FIG. 14A to FIG. 14F are diagrams each illustrating a structure example of a light-emitting apparatus.

FIG. 15A and FIG. 15B are diagrams each illustrating a structure example of a light-emitting apparatus and a light-receiving device.

FIG. 16A and FIG. 16B are diagrams illustrating a structure example of a display apparatus.

FIG. 17A to FIG. 17D are diagrams each illustrating a structure example of a display apparatus.

FIG. 18A to FIG. 18C are diagrams each illustrating a structure example of a display apparatus.

FIG. 19A to FIG. 19D are diagrams each illustrating a structure example of a display apparatus.

FIG. 20A to FIG. 20F are diagrams each illustrating a structure example of a display apparatus.

FIG. 21A to FIG. 21F are diagrams each illustrating a structure example of a display apparatus.

FIG. 22 is a diagram showing a structure example of a display apparatus.

FIG. 23A is a cross-sectional view illustrating an example of a display apparatus. FIG. 23B is a cross-sectional view illustrating an example of a transistor.

FIG. 24A to FIG. 24D are diagrams illustrating examples of a pixel. FIG. 24E and FIG. 24F are diagrams illustrating examples of a circuit diagram of a pixel.

FIG. 25 is a diagram showing a structure example of a vehicle interior.

FIG. 26A is a schematic cross-sectional view of the sample in Example 1, and FIG. 26B is an enlarged view thereof.

FIG. 27A is an optical micrograph without a black matrix, and FIG. 27B is an optical micrograph with a black matrix.

### MODE FOR CARRYING OUT THE INVENTION

In the case where there is a description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relation, for example, a connection relation shown in drawings or texts, a connection relation other than one shown in drawings or texts is regarded as being disclosed in the drawings or the texts. Each of X and Y denotes an object (e.g., a device, an element, a circuit, a wiring, an electrode, a terminal, a conductive film, or a layer).

For example, in the case where X and Y are electrically connected, one or more elements that allow an electrical connection between X and Y (e.g., a switch, a transistor, a capacitor, an inductor, a resistor, a diode, a display apparatus, a light-emitting apparatus, and a load) can be connected between X and Y. Note that a switch has a function of being controlled to be turned on or off. That is, the switch has a function of being in a conduction state (on state) or a non-conduction state (off state) to control whether current flows or not.

For example, in the case where X and Y are functionally connected, one or more circuits that allow functional connection between X and Y (e.g., a logic circuit (an inverter, a NAND circuit, or a NOR circuit): a signal converter circuit (a digital-to-analog converter circuit, an analog-to-digital converter circuit, a gamma correction circuit, or the like): a potential level converter circuit (a power supply circuit (a step-up circuit, a step-down circuit, or the like), a level shifter circuit for changing the potential level of a signal, or the like): a voltage source: a current source: a switching circuit: an amplifier circuit (a circuit that can increase signal amplitude, the amount of current, or the like, an operational amplifier, a differential amplifier circuit, a source follower circuit, a buffer circuit, or the like): a signal generation circuit: a memory circuit: or a control circuit) can be connected between X and Y. For instance, even if another circuit is interposed between X and Y, X and Y are regarded as being functionally connected when a signal output from X is transmitted to Y.

Note that an explicit description “X and Y are electrically connected” includes the case where X and Y are electrically connected (i.e., the case where X and Y are connected with another element or another circuit provided therebetween) and the case where X and Y are directly connected (i.e., the case where X and Y are connected without another element or another circuit provided therebetween).

In this specification and the like, a transistor includes three terminals called a gate, a source, and a drain. The gate is a control terminal for controlling the conduction state of the transistor. Two terminals functioning as the source and the drain are input/output terminals of the transistor. One of the two input/output terminals serves as the source and the other serves as the drain based on the conductivity type (n-channel type or p-channel type) of the transistor and the levels of potentials applied to the three terminals of the transistor. Thus, the terms “source” and “drain” can be sometimes replaced with each other in this specification and the like. In this specification and the like, expressions “one of a source and a drain” (or a first electrode or a first terminal) and “the other of the source and the drain” (or a second electrode or a second terminal) are used in description of the connection relation of a transistor. Depending on the transistor structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, and a third gate, for example, in this specification and the like.

Unless otherwise specified, off-state current in this specification and the like refers to drain current of a transistor in an off state (also referred to as a non-conducting state or a cutoff state). Unless otherwise specified, an off state refers to, in an n-channel transistor, a state where voltage V_{gs} between its gate and source is lower than the threshold voltage Vₜₕ (in a p-channel transistor, higher than Vₜₕ).

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used in an active layer of a transistor, the metal oxide is referred to as an oxide semiconductor in some cases. That is, an OS transistor can also be called a transistor including a metal oxide or an oxide semiconductor.

Ordinal numbers such as “first”, “second”, and “third” in this specification and the like are used to avoid confusion among components. Thus, the ordinal numbers do not limit the number of components. In addition, the ordinal numbers do not limit the order of components. In this specification and the like, for example, a “first” component in one embodiment can be referred to as a “second” component in other embodiments or the scope of claims. Moreover, in this specification and the like, for example, a “first” component in one embodiment can be omitted in other embodiments or the scope of claims.

In this specification and the like, the terms for describing positioning, such as “over” and “under”, are sometimes used for convenience to describe the positional relation between components with reference to drawings. The positional relation between components is changed as appropriate in accordance with the direction in which the components are described. Thus, the positional relation is not limited to the terms described in the specification and the like, and can be described with another term as appropriate depending on the situation. For example, the expression “an insulator positioned over (on) a top surface of a conductor” can be replaced with the expression “an insulator positioned under (on) a bottom surface of a conductor” when the direction of a drawing showing these components is rotated by 180°.

Furthermore, the term “over” or “under” does not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B.

In this specification and the like, the terms “film”, “layer”, and the like can be interchanged with each other depending on the situation. For example, the term “conductive layer” can be changed into the term “conductive film” in some cases. As another example, the term “insulating film” can be changed into the term “insulating layer” in some cases. Alternatively, the term “film”, “layer”, or the like is not used and can be interchanged with another term depending on the case or the situation. For example, the term “conductive layer” or “conductive film” can be changed into the term “conductor” in some cases. As another example, the term “insulating layer” or “insulating film” can be changed into the term “insulator” in some cases.

Embodiments of the present invention will be described in detail below with reference to the drawings. However, the present invention is not limited to the description below and it is easily understood by those skilled in the art that the mode and details can be modified in various ways. In addition, the present invention should not be construed as being limited to the description of the embodiments below.

### Embodiment 1

In this embodiment, an example of a display apparatus including a plurality of flexible substrates, pixel regions formed over the flexible substrates, and a display surface having a curved surface will be described below.

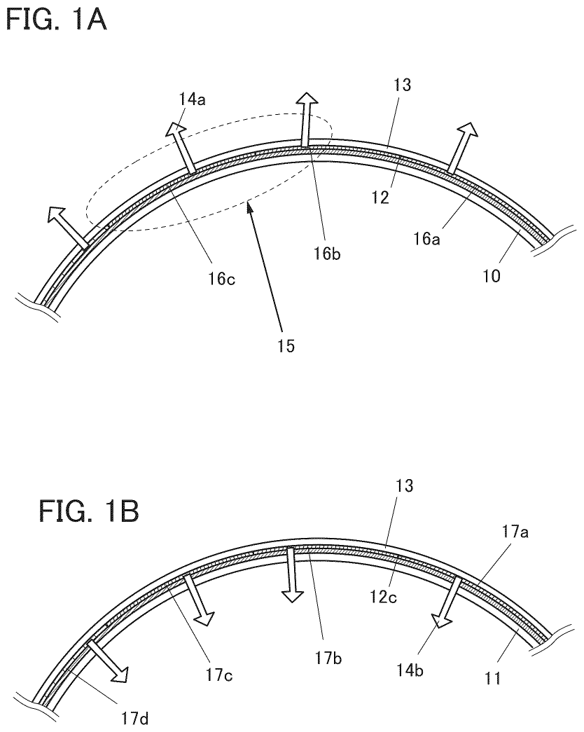

FIG. 1A illustrates part of a schematic cross-sectional view in the case where a display apparatus is provided over a support body 10 having a curved surface.

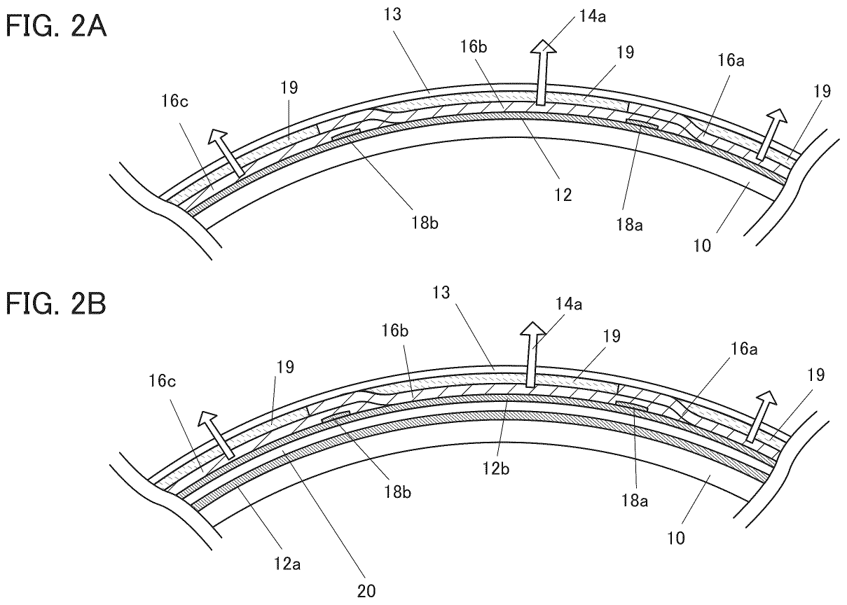

FIG. 2A is an enlarged view of a region 15 surrounded by a dotted line in the display apparatus in FIG. 1A. FIG. 2A is a structure example in which FIG. 1A is enlarged, and thus the same portions are denoted by the same reference numerals in the description below.

The support body 10 can also be referred to as a housing or a support member, and is a component having a curved surface at least in its part. In the case where a display apparatus is provided inside a vehicle, the support body 10 is made of plastic, metal, glass, rubber, or the like. Note that although the support body 10 shown here has, but is not particularly limited to, a plate shape, the support body 10 may be any component having a curved surface at least in its part.

A wiring layer 12 is provided over the support body 10, and a wiring included in the wiring layer 12 is electrically connected to an electrode of a second display apparatus 16b. The wiring layer 12 may include a wiring, an insulating film covering the wiring, and an electrode connected to the wiring through an opening provided in the insulating film. The wiring included in the wiring layer 12 functions as an auxiliary wiring, a connection wiring, a power supply line, a signal line, a fixed potential line, or the like.

The wirings of the wiring layer 12 are formed over the support body 10 having a curved surface with a known technique. For example, a method in which a silver paste is selectively formed, a transposition method, or a transfer method is used to form the wiring layer over the support body 10.

In FIG. 1A, a first display apparatus 16a, the second display apparatus 16b, and a third display apparatus 16c, which are three display panels, are provided side by side. A single display surface can be structured by arranging pixel regions of the display apparatuses. Although FIG. 1A illustrates, but is not particularly limited to, an example in which three pixel regions are used as one display surface, a display apparatus having pixel regions of m rows (m is a natural number of 2 or more) and n columns (n is a natural number of 1 or more) as a display surface can be manufactured. In addition, one of a plurality of arrows in FIG. 1A represents a light-emitting direction 14a of the second display apparatus 16b.

In the display apparatuses illustrated in FIG. 1A, a wiring of the wiring layer 12 can also function as a common wiring. A wiring of the wiring layer 12 can be electrically connected to an electrode of the first display apparatus 16a, and further may be electrically connected to the electrode of the second display apparatus 16b. In the case where a wiring of the wiring layer 12 is a power supply line, power is supplied from the wiring of the wiring layer 12, and thus, the wiring layer 12 can also be referred to as part of the first display apparatus 16a.

In this manner, the first display apparatus 16a, the second display apparatus 16b, and the third display apparatus 16c are combined (aggregated) over the wiring layer 12 to configure a display apparatus. Thus, the wiring layer 12 can be referred to as part of the display apparatus.

The first display apparatus 16a, the second display apparatus 16b, and the third display apparatus 16c are covered with a cover member 13 to be firmly fixed to each other. The cover member 13 can be bonded by a resin 19 or the like as illustrated in FIG. 2A. By adjusting a refractive index of the resin 19, a vertical stripe or a horizontal stripe that might be generated in the vicinity of the boundary between the first display apparatus 16a, the second display apparatus 16b, and the third display apparatus 16c can be made less noticeable. A light-transmitting film is preferably used as the cover member 13. As a material of the cover member 13, a plastic substrate that is formed as a film, for example, a plastic substrate made from polyimide (PI), aramid, polyethylene terephthalate (PET), polyethersulfone (PES), polyethylene naphthalate (PEN), polycarbonate (PC), nylon, polyetheretherketone (PEEK), polysulfone (PSF), polyetherimide (PEI), polyarylate (PAR), polybutylene terephthalate (PBT), a silicone resin, or the like can be used.

The cover member 13 may be an optical film (a polarizing film, a circularly polarizing film, or a light scattering film) or a stack layer film.

FIG. 2A illustrates a structure in which an end portion of the second display apparatus 16b and an end portion of the third display apparatus 16c overlap with each other, and the electrode 18b is provided in a portion where the end portions overlap, and the electrode 18b and the wiring of the wiring layer 12 are electrically connected to each other. By overlapping a periphery of the electrode 18b of the second display apparatus 16b with a pixel region of the third display apparatus 16c, a vertical stripe or a horizontal stripe that might be generated in the vicinity of the boundary between the third display apparatus 16c and the second display apparatus 16b can be made less noticeable.

By overlapping a periphery of the electrode 18a of the second display apparatus 16b with a pixel region of the first display apparatus 16a, a vertical stripe or a horizontal stripe that might be generated in the vicinity of the boundary between the first display apparatus 16a and the second display apparatus 16b can be made less noticeable.

Furthermore, by using a light-blocking layer such as a black matrix, a vertical stripe or a horizontal stripe that might be generated in the vicinity of the boundary between the first display apparatus 16a and the second display apparatus 16b can be made less noticeable.

In addition, the wiring layer 12 can have a multi-layer structure and an example of such a case is illustrated in FIG. 2B.

In FIG. 2B, a wiring layer 12a over the support body 10 having a curved surface, an interlayer insulating film 20 over the wiring layer 12a, and a wiring layer 12b over the interlayer insulating film 20 are provided. The wirings of the wiring layer 12a and the wiring layer 12b may be arranged to intersect with each other. The wiring layer 12a may be configured to be electrically connected to the electrode 18b of the third display apparatus 16c through an opening provided in the interlayer insulating film 20.

By forming the wiring layer 12 over the support body 10 having a curved surface, wirings of the first display apparatus 16a, the second display apparatus 16b, and the third display apparatus 16c can be led, which decreases wiring density and also decreases parasitic capacitance or the like.

One of the plurality of arrows in FIG. 1A illustrates the light-emitting direction 14a of the second display apparatus 16b, and for the second display apparatus 16b, a top-emission display panel (also referred to as a top-emission panel), a bottom-emission display panel (also referred to as a bottom-emission panel), or a dual-emission display panel (also referred to as a dual-emission panel) is used.

FIG. 1B illustrates a modification example of the structure of FIG. 1A. Although the display surface illustrated in FIG. 1A has a convex shape, the display surface has a concave shape in FIG. 1B.

In a display apparatuses illustrated in FIG. 1B, a fourth display apparatus 17a, a fifth display apparatus 17b, a sixth display apparatus 17c, and a seventh display apparatus 17d are arranged side by side to be fixed to a support body 11 having a light-transmitting property. Note that although the term “fourth display apparatus 17a” is used here in order to be distinguished from FIG. 1A, the fourth display apparatus 17a substantially corresponds to the first display apparatus 16a. In addition, for the fourth display apparatus 17a, the fifth display apparatus 17b, the sixth display apparatus 17c, and the seventh display apparatus 17d, a top-emission display panel, a bottom-emission display panel, or a dual-emission display panel is used. In the display apparatuses illustrated in FIG. 1B, the material of the cover member 13 does not necessarily have to have a light-transmitting property, and the cover member 13 can be provided on a ceiling of a car, for example. In the case where the cover member 13 is a glass roof of a car, a dual-emission display apparatus can be used to emit or display light not only in a car interior, but also to the outside of a car. The support body 11 having a light-transmitting property has a curved surface. A light-emitting direction 14b of the fourth display apparatus 17a is different from that in FIG. 1A.

FIG. 1B illustrates, but is not particularly limited to, an example in which four pixel regions are provided as one display surface: a display apparatus having pixel regions of m rows (m is a natural number of 2 or more) and n columns (n is a natural number of 1 or more) as a display surface can be manufactured.

Although the support body used in the explanation has a uniform radius of curvature in FIG. 1A, FIG. 1B, FIG. 2A, and FIG. 2B, the structure of the support body is not particularly limited: the display surface does not have to be entirely curved, and may be partly flat or may have a combination of a convex shape and a concave shape depending on the component structure of a vehicle interior (a dashboard, a ceiling, a pillar, a window glass, a steering wheel, a seat, an inner side of a door, or the like). For example, the display apparatus of one embodiment of the present invention can be provided on an inner wall of a car, specifically, a dashboard, a ceiling, or a wall. The display apparatus of one embodiment of the present invention can be a display surface including a display region with a large area, and thus can be used as a navigation device for a means of transportation (an airplane, a submarine, or the like) without limited to a car because a map with a relatively large area can be displayed.

Furthermore, the display surface is provided with a touch sensor, whereby the display surface can be operated by touch of a driver's hand or finger. Therefore, a display apparatus that includes a touch sensor can also be referred to as a vehicle operating apparatus.

A flexible substrate is more fragile than a glass substrate. In a portable information terminal where input operations are performed by touch or approach of a finger to the terminal, especially in a case where a touch panel is mounted, it is preferable that a surface protective film be provided so that dirt such as sebum or scratches from finger nails are prevented.

Also in a display apparatus provided in a vehicle interior, input operations are performed by touch or approach of a finger: it is thus preferable that a protective film having an excellent abrasion resistance be provided on the outermost surface of the display apparatus. As the protective film, a silicon oxide film having optically favorable characteristics (a high visible light transmittance or a high infrared light transmittance) is used. Providing the protective film can prevent damages and dirt in the film.

In the case where the protective film is formed by a coating method, the protective film can be formed before a display apparatus is fixed to a support body having a curved surface or can be formed after the display apparatus is fixed to the support body having a curved surface. The protective film may be formed using DLC (diamond like carbon), alumina (AlOx), a polyester material, a polycarbonate material, or the like. Note that the protective film is preferably formed using a material that has a high hardness as well as high transmittance with respect to visible light.

As described above, with the structure of one embodiment of the present invention, a display apparatus with high display quality can be provided. The structure of one embodiment of the present invention enables the degree of design flexibility of the display apparatus to be increased and design of the display apparatus to be improved.

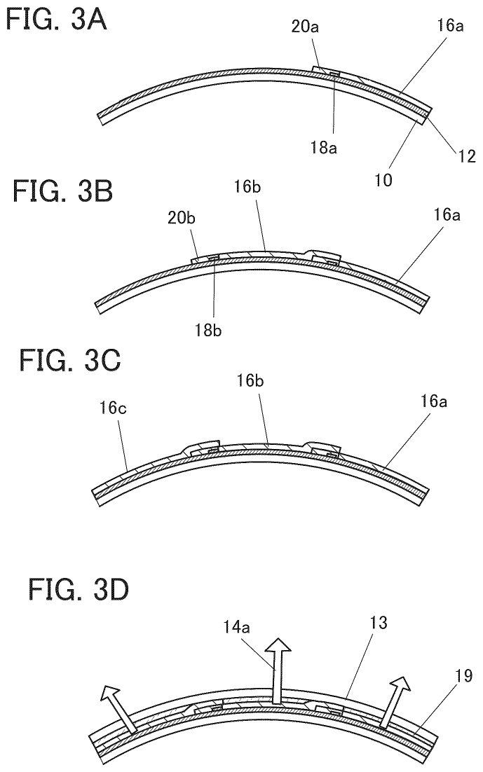

FIG. 3 illustrates an example of a method for manufacturing the display apparatus. In the example illustrated in FIG. 3, a driver circuit portion 20a is provided in part of the first display apparatus 16a. The other parts are the same as those in FIG. 1, and thus will be described using the same reference numerals.

First, a plurality of pixels arranged in a matrix and a driver circuit portion are formed over a flexible substrate. A flexible substrate including a plurality of pixels arranged in a matrix is also referred to as a flexible display. A method in which a transistor or a light-emitting apparatus is directly formed on a flexible substrate may be employed, or a method in which a transistor or a light-emitting apparatus is formed over a glass substrate or the like, separated from the glass substrate, and then bonded to a flexible substrate with an adhesive layer may be employed. Although there are various kinds of separation methods and transposition methods, there is no particular limitation: a known technique is employed as appropriate.

In the case where a glass substrate is used, a glass substrate having any of the following sizes or a larger size can be used: the 3rd generation (550 mm×650 mm), the 3.5th generation (600 mm×720 mm or 620 mm×750 mm), the 4th generation (680 mm×880 mm or 730 mm×920 mm), the 5th generation (1100 mm×1300 mm), the 6th generation (1500 mm×1850 mm), the 7th generation (1870 mm×2200 mm), the 8th generation (2200 mm×2400 mm), the 9th generation (2400 mm×2800 mm or 2450 mm×3050 mm), and the 10th generation (2950 mm×3400 mm). In the case where a glass substrate is used, heat treatment temperature that is higher than or equal to that in the case of forming a transistor or the like directly on a flexible substrate can be applied: thus, a glass substrate is suitable for the case where the temperature in the manufacturing process of a transistor is high.

Examples of materials used for the flexible substrate include polyester resins such as PET and PEN, a polyacrylonitrile resin, an acrylic resin, a polyimide resin, a polymethyl methacrylate resin, a polycarbonate resin, a polyether sulfone resin, polyamide resins (such as nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene resin, and an ABS resin. In particular, a material with a low coefficient of linear expansion is preferred, and for example, a polyamide-imide resin, a polyimide resin, a polyamide resin, or a polyethylene terephthalate resin can be suitably used. In addition, a substrate in which a fibrous body is impregnated with a resin, a substrate whose coefficient of linear expansion is reduced by mixing an inorganic filler with a resin, or the like can also be used.

Alternatively, a metal film can be used as the flexible substrate. Note that stainless steel, aluminum, or the like can be used as the metal film. Note that the metal film has a light-blocking property, and thus is used in consideration of the light-emitting direction of a light-emitting apparatus to be used.

The flexible substrate may have a stacked-layer structure in which at least one of a hard coat layer (e.g., a silicon nitride layer or the like) by which a surface of the device is protected from damage, a layer of a material for dispersing pressure (e.g., an aramid resin layer or the like), and the like is stacked with a layer of any of the above-mentioned materials.

For the adhesive layer, various curable adhesives such as a photocurable adhesive (e.g., an ultraviolet curable adhesive), a reactive curable adhesive, a thermosetting adhesive, and an anaerobic adhesive can be used. Alternatively, an adhesive tape, an adhesive sheet, or the like may be used.

Then, by employing a known technique, the pixel region of the first display apparatus 16a and the driver circuit portion 20a are formed over the flexible substrate. Then, an opening is formed in the flexible substrate and the electrode 18a is formed, and when the flexible substrate is fixed to the support body 10 having a curved surface, the wiring layer 12 over the support body 10 is electrically connected to the electrode 18a as illustrated in FIG. 3A. The electrode 18a is electrically connected to a wiring of the driver circuit portion 20a through the opening provided in the flexible substrate, and thus is also referred to as a through electrode in some cases.

Next, as illustrated in FIG. 3B, the second display apparatus 16b is fixed so that its end portion overlaps with the driver circuit portion 20a. The driver circuit portion 20a is not a pixel region and thus cannot perform display. Thus, when a pixel region of the second display apparatus 16b overlaps with the driver circuit portion 20a, a vertical stripe or a horizontal stripe that might be generated in the vicinity of the boundary between the first display apparatus 16a and the second display apparatus 16b can be made less noticeable.

Next, as illustrated in FIG. 3C, the third display apparatus 16c is fixed so that its end portion overlaps with a driver circuit 20b. The driver circuit 20b is not a pixel region and thus cannot perform display. Thus, when a pixel region of the third display apparatus 16c overlaps with the driver circuit 20b, a vertical stripe or a horizontal stripe that might be generated in the vicinity of the boundary between the second display apparatus 16b and the third display apparatus 16c can be made less noticeable.

Next, as illustrated in FIG. 3D, the cover member 13 covers the display apparatus and is fixed with the resin 19. When the cover member 13 covers the display apparatus, a step generated by the end portion of the second display apparatus 16b overlapping with the driver circuit portion 20a can be reduced. In order to make a vertical stripe or a horizontal stripe less noticeable, refractive indices of the cover member 13 and the resin 19 are selected as appropriate. For a material used in the resin 19, a resin with a high light-transmitting property is preferable: for example, a film of an organic resin such as an epoxy resin, an aramid resin, an acrylic resin, a polyimide resin, a polyamide resin, or a polyamide-imide resin can be used.

Arrows in FIG. 3D indicate the light-emitting direction 14a of the second display apparatus 16b, and the cover member 13 and the resin 19 have a light-transmitting property. Adjustment of a refractive index of the resin 19 or the cover member 13 can make a vertical stripe or a horizontal stripe that might be generated in the vicinity of the boundary between pixel regions provided over different flexible substrates less noticeable.

A difference in refractive indices between the cover member 13 and the resin 19 is preferably less than or equal to 20%, further preferably less than or equal to 10%, and still further preferably less than or equal to 5%. Note that a refractive index refers to an average refractive index with respect to visible light, specifically, light with a wavelength in the range from 400 nm to 750 nm. The average refractive index is a value obtained by dividing, by the number of measurement points, the sum of measured refractive indices with respect to light with wavelengths in the above range. Note that a refractive index of the air is 1.

Through the above-described process, a plurality of display apparatuses (also referred to as a plurality of light-emitting panels or a plurality of display panels) are arranged to partly overlap with each other as appropriate, whereby regions arranged seamlessly serve as one display region.

At least part of this embodiment can be implemented in combination with the other embodiments described in this specification as appropriate.

### Embodiment 2

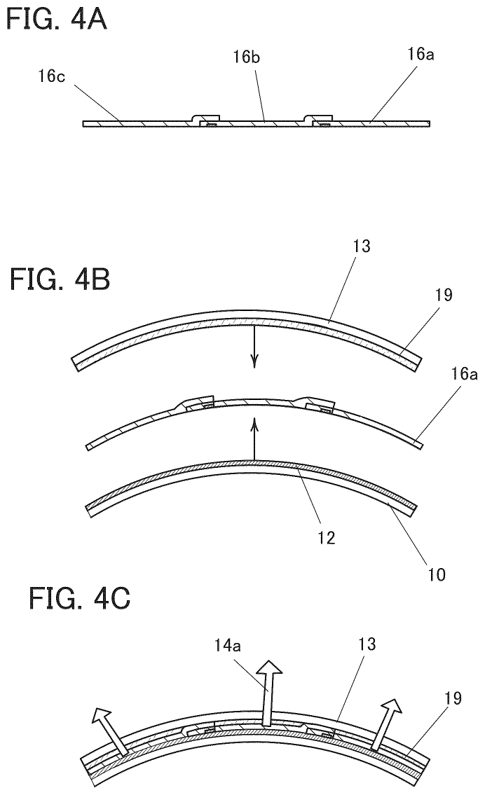

In this embodiment, an example of acquiring a display apparatus by a manufacturing method different from that described in Embodiment 1 with reference to FIG. 3 will be described with reference to FIG. 4. Note that since the display apparatus acquired in FIG. 4 is identical to that in FIG. 3 except for the manufacturing processes, the same portions in FIG. 3 and FIG. 4 are denoted by the same reference numerals.

As illustrated in FIG. 4A, first, the first display apparatus 16a, the second display apparatus 16b, and the third display apparatus 16c are fixed to each other.

Next, as illustrated in FIG. 4B and FIG. 4C, both surfaces of each of the first display apparatus 16a, the second display apparatus 16b, and the third display apparatus 16c are fixed between the support body 10 and the cover member 13. FIG. 4B illustrates, but is not particularly limited to, a figure in which the both surfaces are fixed approximately at the same time: the first display apparatus 16a, the second display apparatus 16b, and the third display apparatus 16c may be fixed to the wiring layer 12 of the support body 10 after they are fixed to the resin 19 of the cover member 13. By having a structure where the display apparatuses are provided between the support body 10 and the cover member 13, it is possible to perform the fixing using only an adhesive tape such as a Kapton tape even without having a resin or the like. Alternatively, by fixing and closely attaching the support body 10 and the cover member 13 with a tape or the like and applying pressure from top and bottom, positions of the first display apparatus 16a, the second display apparatus 16b, and the third display apparatus 16c can be fixed.

The first display apparatus 16a, the second display apparatus 16b, and the third display apparatus 16c may be fixed to the resin 19 of the cover member 13 after they are fixed to the wiring layer 12 of the support body 10.

This embodiment can be freely combined with Embodiment 1.

### Embodiment 3

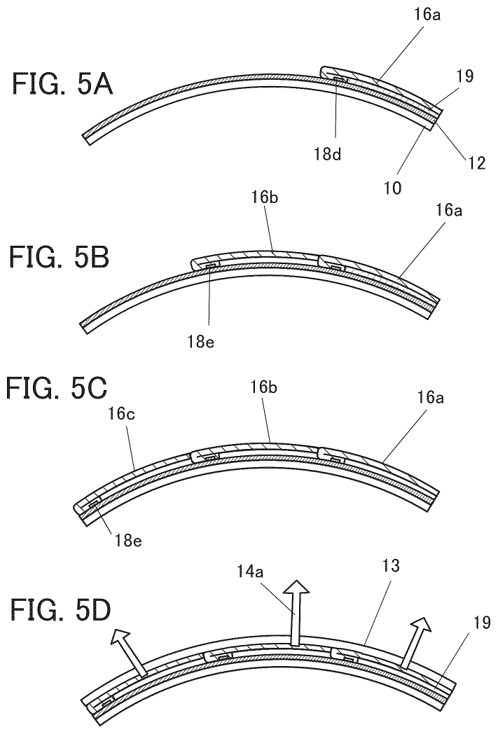

In this embodiment, an example of acquiring a display apparatus by a manufacturing method that is different from that described in Embodiment 1 with reference to FIG. 3 will be described with reference to FIG. 5. Note that since the display apparatus acquired in FIG. 5 is identical to that in FIG. 3 except for the manufacturing processes, the same portions in FIG. 3 and FIG. 5 are denoted by the same reference numerals.

As illustrated in FIG. 5A, first, the end portion of the first display apparatus 16a is folded and is fixed to the wiring layer 12 over the support body 10 with the resin 19. In the fixing, the electrode 18d and the wiring layer 12 are electrically connected to each other. The electrode 18d can be formed in the same process as the wirings of a pixel region or a driver circuit without providing an opening in the flexible substrate.

Then, as illustrated in FIG. 5B, the second display apparatus 16b is fixed such that a space formed by a folded portion of the first display apparatus 16a becomes small.

Then, as illustrated in FIG. 5C, the third display apparatus 16c is fixed such that a space formed by a folded portion of the second display apparatus 16b becomes small.

Then, as illustrated in FIG. 5D, the display apparatuses can be covered with the cover member 13 to be manufactured. The manufacturing method illustrated in FIG. 5A, FIG. 5B, FIG. 5C, and FIG. 5D can be referred to as a tiling method.

In the case where adjacent display apparatuses are fixed to each other in advance of being covered with the cover member 13 and surfaces thereof do not have a step, a protective film having an excellent abrasion resistance can be provided on the outermost surfaces of the display apparatuses without providing the cover member 13. The protective film is formed by a coating method after the display apparatuses are fixed to the support body having a curved surface. As the protective film, a silicon oxide film having optically favorable characteristics (a high visible light transmittance or a high infrared light transmittance) is used. Providing the protective film can prevent damages and dirt in the film.

This embodiment can be freely combined with Embodiment 1.

### Embodiment 4

In this embodiment, specific structures of the display region in any one of Embodiments 1 to 3 will be described below.

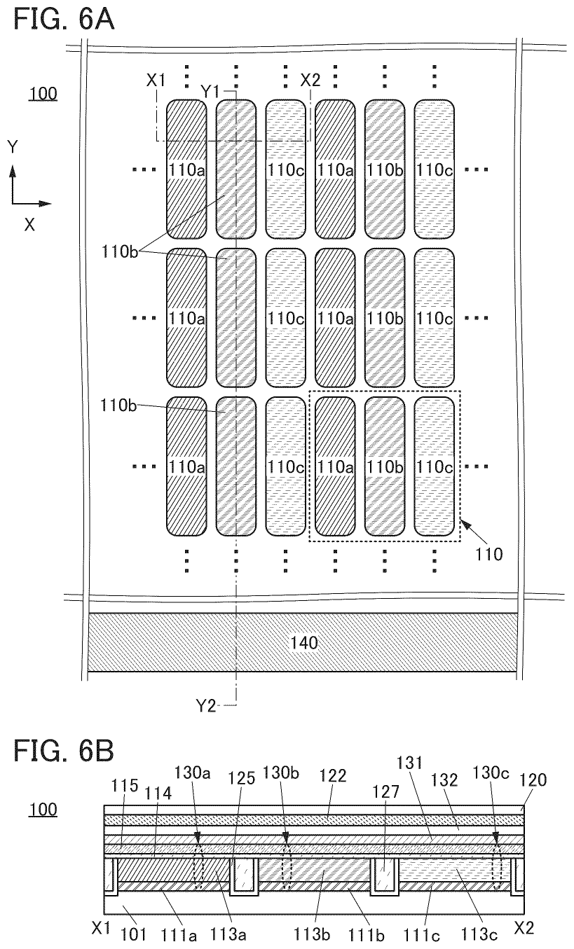

FIG. 6A is a top view of a display region 100. The display region 100 includes a pixel portion in which a plurality of pixels 110 are arranged in a matrix, and a connection portion 140 outside the pixel portion. A region between the pixels and the connection portion 140 do not emit light but are included in the display region 100.

The pixel 110 illustrated in FIG. 6A employs stripe arrangement. The pixel 110 illustrated in FIG. 6A consists of three subpixels 110a, 110b, and 110c. The subpixels 110a, 110b, and 110c include light-emitting apparatuses that emit light of different colors. The subpixels 110a, 110b, and 110c can be of three colors of red (R), green (G), and blue (B) or of three colors of yellow (Y), cyan (C), and magenta (M), for example.

FIG. 6A illustrates an example in which subpixels of different colors are arranged in the X direction and subpixels of the same color are arranged in the Y direction. Note that subpixels of different colors may be arranged in the Y direction and subpixels of the same color may be arranged in the X direction.

Although the top view of FIG. 6A illustrates an example in which the connection portion 140 is positioned on the lower side of the pixel portion, one embodiment of the present invention is not limited thereto. The connection portion 140 may be provided in at least one of the upper side, the right side, the left side, and the lower side of the pixel portion in the top view. The number of connection portions 140 can be one or more.

FIG. 6B is a cross-sectional view taken along the dashed-dotted line X1-X2 in FIG. 6A.

As illustrated in FIG. 6B, in the display region 100, light-emitting apparatuses 130a, 130b, and 130c are provided over a layer 101 including transistors and insulating layers 131 and 132 are provided to cover these light-emitting apparatuses. A substrate 120 is bonded to the insulating layer 132 with a resin layer 122. In a region between adjacent light-emitting apparatuses, an insulating layer 125 and an insulating layer 127 over the insulating layer 125 are provided.

The display region of one embodiment of the present invention can have any of the following structures: a top-emission structure in which light is emitted in a direction opposite to the substrate where the light-emitting apparatus is formed, a bottom-emission structure in which light is emitted toward the substrate where the light-emitting apparatus is formed, and a dual-emission structure in which light is emitted toward both surfaces.

The layer 101 including transistors can employ a stacked-layer structure in which a plurality of transistors are provided over a substrate and an insulating layer is provided to cover these transistors, for example. The layer 101 including transistors may have a depressed portion between adjacent light-emitting apparatuses. For example, an insulating layer positioned on the uppermost surface of the layer 101 including transistors may have a depressed portion. A structure example of the layer 101 including transistors will be described later.

Each of the light-emitting apparatuses 130a, 130b, and 130c emits light of different colors. The light-emitting apparatuses 130a, 130b, and 130c preferably emit light of three colors, red (R), green (G), and blue (B), for example.

As the light-emitting apparatuses 130a, 130b, and 130c, an EL device such as an OLED (Organic Light Emitting Diode) or a QLED (Quantum-dot Light Emitting Diode) is preferably used. Examples of a light-emitting substance contained in the EL device include a substance that exhibits fluorescence (a fluorescent material), a substance that exhibits phosphorescence (a phosphorescent material), an inorganic compound (e.g., a quantum dot material), and a substance that exhibits thermally activated delayed fluorescence (a thermally activated delayed fluorescent (TADF) material). Note that as a TADF material, a material that is in a thermal equilibrium state between a singlet excited state and a triplet excited state may be used. Since such a TADF material has a short emission lifetime (excitation lifetime), an efficiency decrease of the light-emitting apparatus in a high-luminance region can be inhibited. Note that as a light-emitting apparatus, LED such as a micro LED can be used.

The light-emitting apparatus includes an EL layer between a pair of electrodes. In this specification and the like, one of the pair of electrodes may be referred to as a pixel electrode and the other may be referred to as a common electrode.

One electrode of the pair of electrodes included in the light-emitting apparatus functions as an anode, and the other electrode functions as a cathode. The case where the pixel electrode functions as an anode and the common electrode functions as a cathode is described below as an example.

The light-emitting apparatus 130a includes a pixel electrode 111a over the layer 101 including transistors, an island-shaped first material layer 113a over the pixel electrode 111a, a fifth material layer 114 over the island-shaped first material layer 113a, and a common electrode 115 over the fifth material layer 114. In the light-emitting apparatus 130a, the first material layer 113a and the fifth material layer 114 can be collectively referred to as an EL layer.

There is no particular limitation on the structure of the light-emitting apparatus in this embodiment, and either a single structure or a tandem structure can be employed. Note that structure examples of the light-emitting apparatus will be described later in Embodiment 7.

The light-emitting apparatus 130b includes a pixel electrode 111b over the layer 101 including transistors, an island-shaped second material layer 113b over the pixel electrode 111b, the fifth material layer 114 over the island-shaped second material layer 113b, and the common electrode 115 over the fifth material layer 114. In the light-emitting apparatus 130b, the second material layer 113b and the fifth material layer 114 can be collectively referred to as an EL layer.

The light-emitting apparatus 130c includes a pixel electrode 111c over the layer 101 including transistors, an island-shaped third material layer 113c over the pixel electrode 111c, the fifth material layer 114 over the island-shaped third material layer 113c, and the common electrode 115 over the fifth material layer 114. In the light-emitting apparatus 130c, the third material layer 113c and the fifth material layer 114 can be collectively referred to as an EL layer.

The light-emitting apparatuses of different colors share one film as the common electrode. The common electrode shared by the light-emitting apparatuses of different colors is electrically connected to a conductive layer provided in the connection portion 140. Thus, the same potential is supplied to the common electrode included in the light-emitting apparatuses of the respective colors.

A conductive film that transmits visible light is used as the electrode through which light is extracted, which is either the pixel electrode or the common electrode. A conductive film that reflects visible light is preferably used as the electrode through which light is not extracted.

As a material that forms the pair of electrodes (the pixel electrode and the common electrode) of the light-emitting apparatus, a metal, an alloy, an electrically conductive compound, a mixture thereof, and the like can be used as appropriate. Specific examples include an indium tin oxide (also referred to as an In—Sn oxide or ITO), an In—Si—Sn oxide (also referred to as ITSO), an indium zinc oxide (In—Zn oxide), an In—W—Zn oxide, an alloy containing aluminum (an aluminum alloy) such as an alloy of aluminum, nickel, and lanthanum (Al—Ni—La), and an alloy containing silver such as an alloy of silver and magnesium and an alloy of silver, palladium, and copper (Ag—Pd—Cu, also referred to as APC). In addition, it is possible to use a metal such as aluminum (Al), magnesium (Mg), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use a Group 1 element or a Group 2 element in the periodic table, which is not exemplified above (e.g., lithium (Li), cesium (Cs), calcium (Ca), or strontium (Sr)), a rare earth metal such as europium (Eu) or ytterbium (Yb), an alloy containing an appropriate combination of any of these elements, graphene, or the like.

The light-emitting apparatus preferably employs a microcavity structure. Therefore, one of the pair of electrodes of the light-emitting apparatuses is preferably an electrode having properties of transmitting and reflecting visible light (transflective electrode), and the other is preferably an electrode having a property of reflecting visible light (reflective electrode). When the light-emitting apparatuses have a microcavity structure, light obtained from the light-emitting layers can be resonated between the electrodes, whereby light emitted from the light-emitting apparatuses can be intensified.

The transflective electrode can have a stacked-layer structure of a reflective electrode and an electrode having a property of transmitting visible light (also referred to as a transparent electrode).

The transparent electrode has a light transmittance higher than or equal to 40%. For example, an electrode having a visible light (light with wavelengths greater than or equal to 400 nm and less than 750 nm) transmittance higher than or equal to 40% is preferably used in the light-emitting apparatuses. The visible light reflectivity of the transflective electrode is higher than or equal to 10% and lower than or equal to 95%, preferably higher than or equal to 30% and lower than or equal to 80%. The visible light reflectivity of the reflective electrode is higher than or equal to 40% and lower than or equal to 100%, preferably higher than or equal to 70% and lower than or equal to 100%. These electrodes preferably have a resistivity lower than or equal to 1× 10⁻² Ωcm.

The first material layer 113a, the second material layer 113b, and the third material layer 113c are each provided in an island shape. The first material layer 113a, the second material layer 113b, and the third material layer 113c each include a light-emitting layer. The first material layer 113a, the second material layer 113b, and the third material layer 113c preferably include the light-emitting layers that emit light of different colors.

The light-emitting layer is a layer containing a light-emitting substance. The light-emitting layer can include one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton: an organometallic complex (particularly an iridium complex) having a phenylpyridine derivative including an electron-withdrawing group as a ligand: a platinum complex; and a rare earth metal complex.

The light-emitting layer may contain one or more kinds of organic compounds (a host material, an assist material, and the like) in addition to the light-emitting substance (a guest material). As one or more kinds of organic compounds, one or both of the hole-transport material and the electron-transport material can be used. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from an exciplex to a light-emitting substance (a phosphorescent material). When a combination of materials is selected to form an exciplex that exhibits light emission whose wavelength overlaps with the wavelength of a lowest-energy-side absorption band of the light-emitting substance, energy can be transferred smoothly and light emission can be obtained efficiently. With this structure, the high efficiency, low-voltage driving, and long lifetime of the light-emitting apparatus can be achieved at the same time.

In addition to the light-emitting layer, the first material layer 113a, the second material layer 113b, and the third material layer 113c may further include a layer containing any of a substance with a high hole-injection property, a substance with a high hole-transport property, a hole-blocking material, a substance with a high electron-transport property, a substance with a high electron-injection property, an electron-blocking material, or a substance with a bipolar property (a substance with a high electron-transport property and a high hole-transport property), and the like.

Either a low molecular compound or a high molecular compound can be used for the light-emitting apparatus, and an inorganic compound may also be contained. Each of the layers included in the light-emitting apparatus can be formed by an evaporation method (including a vacuum evaporation method), a transfer method, a printing method, an inkjet method, a coating method, or the like.

For example, the first material layer 113a, the second material layer 113b, and the third material layer 113c may each include one or more of a hole-injection layer, a hole-transport layer, a hole-blocking layer, an electron-blocking layer, an electron-transport layer, and an electron-injection layer. A hole-injection layer, a hole-transport layer, a hole-blocking layer, an electron-blocking layer, an electron-transport layer, and an electron-injection layer are referred to as functional layers in some cases.

In the EL layer, one or more of a hole-injection layer, a hole-transport layer, a hole-blocking layer, an electron-blocking layer, an electron-transport layer, and an electron-injection layer can be formed as a layer common to the light-emitting apparatuses of the respective colors. For example, a carrier-injection layer (a hole-injection layer or an electron-injection layer) may be formed as the fifth material layer 114. Note that all the layers in the EL layer may be separately formed for the respective colors. That is, the EL layer does not necessarily include a layer common to the light-emitting apparatuses of the respective colors.

The first material layer 113a, the second material layer 113b, and the third material layer 113c each preferably include a light-emitting layer and a carrier-transport layer (a hole-transport layer or an electron transport layer) over the light-emitting layer. Accordingly, the light-emitting layer is inhibited from being exposed on the outermost surface during the manufacturing process of the display region 100, so that damage to the light-emitting layer can be reduced. As a result, the reliability of the light-emitting apparatus can be increased.

The hole-injection layer is a functional layer injecting holes from an anode to a hole-transport layer and containing a material with a high hole-injection property. Examples of a material with a high hole-injection property include an aromatic amine compound and a composite material containing a hole-transport material and an acceptor material (electron-accepting material).

The hole-transport layer is a functional layer transporting holes, which are injected from the anode by the hole-injection layer, to the light-emitting layer. The hole-transport layer is a layer that contains a hole-transport material. As the hole-transport material, a substance having a hole mobility greater than or equal to 10⁻⁶ cm²/Vs is preferable. Note that other substances can also be used as long as they have a property of transporting more holes than electrons. As the hole-transport material, materials with a high hole-transport property, such as a x-electron rich heteroaromatic compound (e.g., a carbazole derivative, a thiophene derivative, and a furan derivative) and an aromatic amine (a compound having an aromatic amine skeleton) or the like, are preferred.

The electron-transport layer is a functional layer transporting electrons, which are injected from a cathode by the electron-injection layer, to the light-emitting layer. The electron-transport layer is a layer containing an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a x-electron deficient heteroaromatic compound such as a nitrogen-containing heteroaromatic compound.

The electron-injection layer is a functional layer injecting electrons from a cathode to the electron-transport layer and containing a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

For the electron-injection layer, it is possible to use, for example, an alkali metal, an alkaline earth metal, or a compound thereof, such as lithium, cesium, ytterbium, lithium fluoride (LiF), cesium fluoride (CsF), calcium fluoride (CaF_{X}, where X is a given number), 8-(quinolinolato) lithium (abbreviation: Liq), 2-(2-pyridyl) phenolatolithium (abbreviation: LiPP), 2-(2-pyridyl)-3-pyridinolatolithium (abbreviation: LiPPy), 4-phenyl-2-(2-pyridyl) phenolatolithium (abbreviation: LiPPP), lithium oxide (LiO_{X}), or cesium carbonate. In addition, the electron-injection layer may have a stacked-layer structure of two or more layers. In the stacked-layer structure, for example, lithium fluoride can be used for a first layer and ytterbium can be used for a second layer.

Alternatively, for the electron-injection layer, an electron-transport material may be used. For example, a compound having an unshared electron pair and an electron deficient heteroaromatic ring can be used as the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), or 2,4,6-tris[3′-(pyridin-3-yl) biphenyl-3-yl]-1,3,5-triazine (abbreviation: TmPPPyTz) or the like can be used for the organic compound having an unshared electron pair. Note that NBPhen has a higher glass transition temperature (Tg) than BPhen and thus has high heat resistance.

In the case of manufacturing a tandem light-emitting apparatus, an intermediate layer is provided between two light-emitting units. The intermediate layer has a function of injecting electrons into one of the two light-emitting units and injecting holes to the other when voltage is applied between the pair of electrodes.

For example, a material that can be used for the electron-injection layer, such as lithium, can be favorably used for the intermediate layer. As another example, a material that can be used for the hole-injection layer can be favorably used for the intermediate layer. A layer containing a hole-transport material and an acceptor material (electron-accepting material) can be used as the intermediate layer. A layer containing an electron-transport material and a donor material can be used as the intermediate layer. Forming the intermediate layer including such a layer can inhibit an increase in the driving voltage that would be caused by stacking light-emitting units.

The side surfaces of the pixel electrodes 111a, 111b, and 111c, the first material layer 113a, the second material layer 113b, and the third material layer 113c are covered with the insulating layer 125 and the insulating layer 127. Thus, the fifth material layer 114 (or the common electrode 115) can be inhibited from being in contact with the side surface of any of the pixel electrodes 111a, 111b, and 111c, the first material layer 113a, the second material layer 113b, and the third material layer 113c, whereby a short circuit of the light-emitting apparatus can be inhibited.

The insulating layer 125 preferably covers at least the side surfaces of the pixel electrodes 111a, 111b, and 111c. Moreover, the insulating layer 125 preferably covers the side surfaces of the first material layer 113a, the second material layer 113b, and the third material layer 113c. The insulating layer 125 can be in contact with the side surfaces of the pixel electrodes 111a, 111b, and 111c, the first material layer 113a, the second material layer 113b, and the third material layer 113c.

The insulating layer 127 is provided over the insulating layer 125 to fill a recessed portion formed in the insulating layer 125. The insulating layer 127 can overlap with the side surfaces of the pixel electrodes 111a, 111b, and 111c, the first material layer 113a, the second material layer 113b, and the third material layer 113c with the insulating layer 125 therebetween.

Note that one of the insulating layer 125 and the insulating layer 127 is not necessarily provided. For example, in the case where the insulating layer 125 is not provided, the insulating layer 127 can be in contact with the side surfaces of the first material layer 113a, the second material layer 113b, and the third material layer 113c. The insulating layer 127 can be provided over a protective layer 121 to fill gaps between the EL layers included in the light-emitting apparatuses.

The fifth material layer 114 and the common electrode 115 are provided over the first material layer 113a, the second material layer 113b, the third material layer 113c, the insulating layer 125, and the insulating layer 127. Before the insulating layer 125 and the insulating layer 127 are provided, there is a step due to a region where the pixel electrode and the EL layer are provided and a region where neither the pixel electrode nor the EL layer is provided (a region between the light-emitting apparatuses). The display region of one embodiment of the present invention can eliminate the level difference by including the insulating layer 125 and the insulating layer 127, whereby the coverage with the fifth material layer 114 and the common electrode 115 can be improved. Consequently, it is possible to inhibit a connection defect due to disconnection. Alternatively, it is possible to inhibit an increase in electric resistance due to local thinning of the common electrode 115 by the step.

In order to improve the planarity of the formation surfaces of the fifth material layer 114 and the common electrode 115, the height of the top surface of the insulating layer 125 and the height of the top surface of the insulating layer 127 are each preferably equal to or substantially equal to the height of the top surface of at least one of the first material layer 113a, the second material layer 113b, and the third material layer 113c. The top surface of the insulating layer 127 preferably has a flat shape and may have a protruding portion or a recessed portion.

The insulating layer 125 includes regions in contact with the side surfaces of the first material layer 113a, the second material layer 113b, and the third material layer 113c and functions as a protective insulating layer for the first material layer 113a, the second material layer 113b, and the third material layer 113c. Providing the insulating layer 125 can inhibit impurities (e.g., oxygen and moisture) from entering the first material layer 113a, the second material layer 113b, and the third material layer 113c through their side surfaces, resulting in a highly reliable display apparatus.

When the width (thickness) of the insulating layer 125 in the regions in contact with the side surfaces of the first material layer 113a, the second material layer 113b, and the third material layer 113c is large in the cross-sectional view, the intervals between the first material layer 113a, the second material layer 113b, and the third material layer 113c increase, so that the aperture ratio may be reduced. When the width (thickness) of the insulating layer 125 is small, the effect of inhibiting impurities from entering the first material layer 113a, the second material layer 113b, and the third material layer 113c through their side surfaces may be weakened. The width (thickness) of the insulating layer 125 in the regions in contact with the side surfaces of the first material layer 113a, the second material layer 113b, and the third material layer 113c is preferably greater than or equal to 3 nm and less than or equal to 200 nm, further preferably greater than or equal to 3 nm and less than or equal to 150 nm, further preferably greater than or equal to 5 nm and less than or equal to 150 nm, still further preferably greater than or equal to 5 nm and less than or equal to 100 nm, still further preferably greater than or equal to 10 nm and less than or equal to 100 nm, yet further preferably greater than or equal to 10 nm and less than or equal to 50 nm. When the width (thickness) of the insulating layer 125 is within the above range, the display region can have both a high aperture ratio and high reliability.

The insulating layer 125 can be an insulating layer containing an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium 20) oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, aluminum oxide is preferable because it has high selectivity with respect to the EL layer in etching and has a function of protecting the EL layer in forming the insulating layer 127 described later. Specifically, when an inorganic insulating film such as an aluminum oxide film, a hafnium oxide film, or a silicon oxide film formed by an ALD method is used for the insulating layer 125, the insulating layer 125 formed can have a small number of pin holes and excel in a function of protecting the EL layer.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

The insulating layer 125 can be formed by a sputtering method, a CVD method, a PLD method, an ALD method, or the like. The insulating layer 125 is preferably formed by an ALD method achieving good coverage.

The insulating layer 127 provided over the insulating layer 125 has a function of filling a recessed portion of the insulating layer 125, which is formed between the adjacent light-emitting apparatuses. In other words, the insulating layer 127 has an effect of improving the planarity of the formation surface of the common electrode 115. An insulating layer containing an organic material can be suitably used as the insulating layer 127. For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like can be used, for example. For the insulating layer 127, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used. Moreover, for the insulating layer 127, a photosensitive resin can be used. A photoresist may be used for the photosensitive resin. As the photosensitive resin, a positive photosensitive material or a negative photosensitive material can be used.

The difference between the height of the top surface of the insulating layer 127 and the height of the top surface of any of the first material layer 113a, the second material layer 113b, and the third material layer 113c is preferably less than or equal to 0.5 times, further preferably less than or equal to 0.3 times the thickness of the insulating layer 127, for example. As another example, the insulating layer 127 may be provided so that the height of the top surface of any of the first material layer 113a, the second material layer 113b, and the third material layer 113c is greater than the height of the top surface of the insulating layer 127. As another example, the insulating layer 127 may be provided so that the height of the top surface of the insulating layer 127 is greater than the height of the top surface of the light-emitting layer included in the first material layer 113a, the second material layer 113b, or the third material layer 113c.

The insulating layers 131 and 132 are preferably provided over the light-emitting apparatuses 130a, 130b, and 130c. Providing the insulating layers 131 and 132 can improve the reliability of the light-emitting apparatuses.

The insulating layers 131 and 132 including inorganic films can inhibit deterioration of the light-emitting apparatuses by preventing oxidation of the common electrode 115 and inhibiting entry of impurities (e.g., moisture and oxygen) into the light-emitting apparatuses 130a, 130b, and 130c, for example: thus, the reliability of the display region can be improved.

As the insulating layers 131 and 132, an inorganic insulating film such as an oxide insulating film, a nitride insulating film, an oxynitride insulating film, or a nitride oxide insulating film can be used, for example. Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film.

Each of the insulating layers 131 and 132 preferably includes a nitride insulating film or a nitride oxide insulating film, and further preferably includes a nitride insulating film.

As the insulating layers 131 and 132, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

When light emitted from the light-emitting apparatus is extracted through the insulating layers 131 and 132, the insulating layers 131 and 132 preferably have a high property of transmitting visible light. For example, ITO, IGZO, and aluminum oxide are preferable because they are inorganic materials having a high property of transmitting visible light.

The insulating layers 131 and 132 can have, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layer.

Furthermore, the insulating layers 131 and 132 may each include an organic film. For example, the insulating layer 132 may include both an organic film and an inorganic film.

Different deposition methods may be employed for the insulating layer 131 and the insulating layer 132. Specifically, the insulating layer 131 may be formed by an atomic layer deposition (ALD) method and the insulating layer 132 may be formed by a sputtering method.

End portions of the top surfaces of the pixel electrodes 111a, 111b, and 111c are not covered with an insulating layer. This allows the distance between adjacent light-emitting apparatuses to be extremely narrowed. Accordingly, the display region can have high resolution or high definition.

In the display region 100 of this embodiment, the distance between the light-emitting apparatuses can be narrowed. Specifically, the distance between the light-emitting apparatuses, the distance between the EL layers, or the distance between the pixel electrodes can be less than 10 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, a region is provided, in which the distance between the side surface of the first material layer 113a and the side surface of the second material layer 113b or the distance between the side surface of the second material layer 113b and the side surface of the third material layer 113c is less than or equal to 1 μm, preferably less than or equal to 0.5 μm (500 nm), further preferably less than or equal to 100 nm.

A light-blocking layer may be provided on the surface of the substrate 120 on the resin layer 122 side. A variety of optical members can be arranged on the outer surface of the substrate 120. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be arranged on the outer surface of the substrate 120.

For the substrate 120, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for the substrate 120.

In the case where a circularly polarizing plate overlaps with the display region, a highly optically isotropic substrate is preferably used as the substrate included in the display apparatus. A highly optically isotropic substrate has a low birefringence (that can also be referred to as a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of the film having high optical isotropy include a triacetyl cellulose (TAC, also referred to as cellulose triacetate) film, a cycloolefin polymer (COP) film, a cycloolefin copolymer (COC) film, and an acrylic resin film.

When a film is used for the substrate and the film absorbs water, the shape of the display panel might be changed, e.g., creases are generated. Thus, for the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

As the resin layer 122, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-liquid-mixture-type resin may be used. An adhesive sheet or the like may be used.

As materials that can be used for a gate, a source, and a drain of a transistor and conductive layers such as a variety of wirings and electrodes included in a display panel, metals such as aluminum, titanium, chromium, nickel, copper, yttrium, zirconium, molybdenum, silver, tantalum, or tungsten, an alloy containing any of these metals as its main component, and the like can be given. A film containing any of these materials can be used in a single layer or as a stacked-layer structure.

As a light-transmitting conductive material, a conductive oxide such as indium oxide, indium tin oxide, indium zinc oxide, zinc oxide, or zinc oxide containing gallium, or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. A nitride of the metal material (e.g., titanium nitride) or the like may also be used. Note that in the case of using the metal material or the alloy material (or the nitride thereof), the material is made thin enough to have a light-transmitting property. Furthermore, a stacked-layer film of the above materials can be used for a conductive layer. For example, a stacked film of indium tin oxide and an alloy of silver and magnesium is preferably used because conductivity can be increased. These materials can also be used for the conductive layers such as a variety of wirings and electrodes included in the display panel, and conductive layers (conductive layers functioning as a pixel electrode or a common electrode) included in the light-emitting apparatus.

Examples of insulating materials that can be used for the insulating layers include a resin such as an acrylic resin or an epoxy resin, and an inorganic insulating material such as silicon oxide, silicon oxynitride, silicon nitride oxide, silicon nitride, or aluminum oxide.

### [Pixel Layout]

Next, pixel layouts different from that in FIG. 6A will be described. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and PenTile arrangement.

Examples of a top surface shape of the subpixel include polygons such as a triangle, a tetragon (including a rectangle and a square), and a pentagon: polygons with rounded corners: an ellipse: or a circle. Furthermore, the top surface shape of the subpixel corresponds to the top surface shape of a light-emitting region of the light-emitting apparatus.

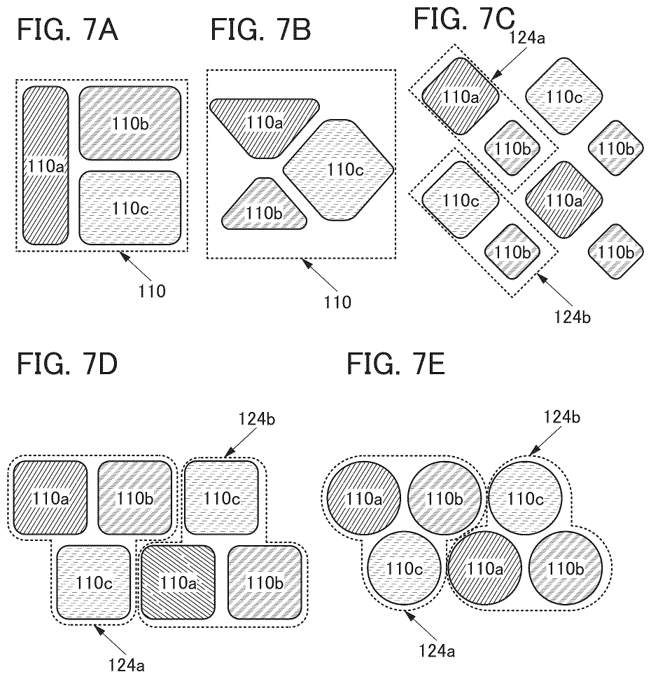

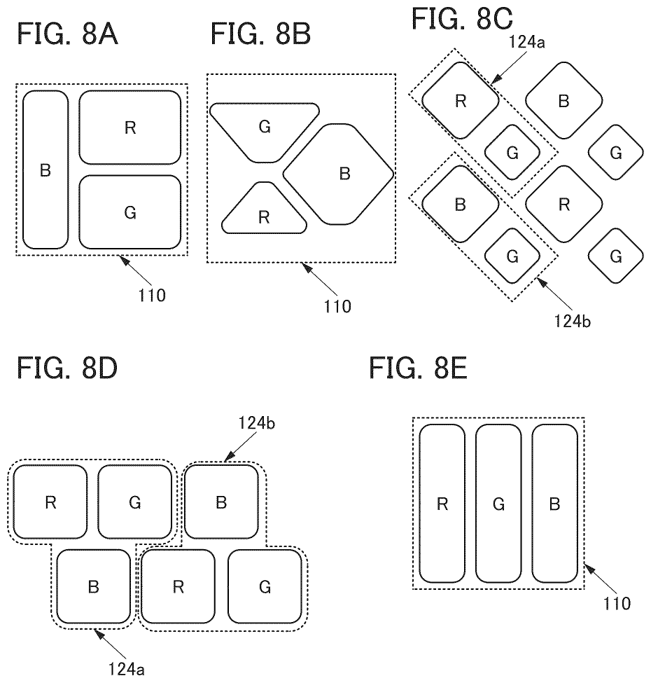

The pixel 110 illustrated in FIG. 7A employs S-stripe arrangement. The pixel 110 illustrated in FIG. 7A consists of three subpixels 110a, 110b, and 110c. For example, as illustrated in FIG. 8A, the subpixel 110a may be a blue subpixel B, the subpixel 110b may be a red subpixel R, and the subpixel 110c may be a green subpixel G.

The pixel 110 illustrated in FIG. 7B includes the subpixel 110a whose top surface has a rough trapezoidal shape with rounded corners, the subpixel 110b whose top surface has a rough triangle shape with rounded corners, and the subpixel 110c whose top surface has a rough tetragonal or rough hexagonal shape with rounded corners. The subpixel 110a has a larger light-emitting area than the subpixel 110b. In this manner, the shapes and sizes of the subpixels can be determined independently. For example, the size of a subpixel including a light-emitting apparatus with higher reliability can be smaller. For example, as illustrated in FIG. 8B, the subpixel 110a may be the green subpixel G, the subpixel 110b may be the red subpixel R, and the subpixel 110c may be the blue subpixel B.

Pixels 124a and 124b illustrated in FIG. 7C employ PenTile arrangement. FIG. 7C illustrates an example in which the pixels 124a, each of which includes the subpixel 110a and the subpixel 110b, and the pixels 124b, each of which includes the subpixel 110b and the subpixel 110c, are alternately arranged. For example, as illustrated in FIG. 8C, the subpixel 110a may be the red subpixel R, the subpixel 110b may be the green subpixel G, and the subpixel 110c may be the blue subpixel B.

The pixels 124a and 124b illustrated in FIG. 7D and FIG. 7E employ delta arrangement. The pixel 124a includes two subpixels (the subpixels 110a and 110b) in the upper row (first row) and one subpixel (the subpixel 110c) in the lower row (second row). The pixel 124b includes one subpixel (the subpixel 110c) in the upper row (first row) and two subpixels (the subpixels 110a and 110b) in the lower row (second row). For example, as illustrated in FIG. 8D, the subpixel 110a may be the red subpixel R, the subpixel 110b may be the green subpixel G, and the subpixel 110c may be the blue subpixel B.

FIG. 7D illustrates an example in which the top surface of each subpixel has a rough tetragonal shape with rounded corners, and FIG. 7E illustrates an example in which the top surface of each subpixel is circular.

In a photolithography method, as a pattern to be formed by processing becomes finer, the influence of light diffraction becomes more difficult to ignore: accordingly, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel may have a polygonal shape with rounded corners, an elliptical shape, a circular shape, or the like.

Furthermore, in the method for manufacturing the display region of one embodiment of the present invention, the EL layer is processed into an island shape with the use of a resist mask. A resist film formed over the EL layer needs to be cured at a temperature lower than the upper temperature limit of the EL layer. Thus, the resist film is insufficiently cured in some cases depending on the upper temperature limit of the material of the EL layer and the curing temperature of the resist material. An insufficiently cured resist film may have a shape different from a desired shape by processing. As a result, the top surface of the EL layer may have a polygonal shape with rounded corners, an elliptical shape, a circular shape, or the like. For example, when a resist mask with a square top surface is intended to be formed, a resist mask with a circular top surface may be formed, and the top surface of the EL layer may be circular.

Note that to obtain a desired top surface shape of the EL layer, a technique of correcting a mask pattern in advance so that a transferred pattern agrees with a design pattern (an OPC (Optical Proximity Correction technique) may be used. Specifically, with the OPC technique, a pattern for correction is added to a corner portion or the like of a figure on a mask pattern.

Also in the pixel 110 illustrated in FIG. 6A, which employs stripe arrangement, the subpixel 110a may be a red subpixel R, the subpixel 110b may be a green subpixel G, and the subpixel 110c may be a blue subpixel B as illustrated in FIG. 8E, for example.

In one embodiment of the present invention, an organic EL device is used as a light-emitting apparatus.

In the display region 100 of one embodiment of the present invention, light-emitting apparatuses are arranged in a matrix in a pixel portion, and an image can be displayed on the pixel portion.

The refresh rate of the display region 100 of one embodiment of the present invention can be variable. For example, the refresh rate is adjusted (in the range from 0.1 Hz to 240 Hz, for example) in accordance with contents displayed on the display region 100, whereby power consumption can be reduced.

### Embodiment 5

In this embodiment, structure examples and application examples of a stacked-layer panel that is one embodiment of a display panel that can easily have a larger size are described with reference to drawings.

One embodiment of the present invention is a display panel capable of increasing its size by arranging a plurality of display panels to partly overlap one another. In two of the overlapping display panels, at least a display panel positioned on the display surface side (upper side) includes a region transmitting visible light that is adjacent to a display portion. A pixel of a display panel positioned on the lower side and the region transmitting visible light of the display panel positioned on the upper side are provided to overlap with each other. Thus, the two of the overlapping display panels can display a seamless and contiguous image when seen from the display surface side (in a plan view).

For example, one embodiment of the present invention is a stacked-layer panel including a first display panel and a second display panel. The first display panel includes a first region, and the first region includes a first pixel and a second pixel. The second display panel includes a second region, a third region, and a fourth region. The second region includes a third pixel. The third region has a function of transmitting visible light. The fourth region has a function of blocking visible light. The second pixel of the first display panel and the third region of the second display panel have a region where they overlap with each other. The aperture ratio of the second pixel is preferably higher than the aperture ratio of the first pixel.

For one or both of the first display panel and the second display panel, the display apparatus described above as an example, which includes a light-emitting apparatus and a light-receiving apparatus (also referred to as a light-receiving element), can be used. In other words, at least one of the first pixel, the second pixel, and the third pixel includes a light-emitting apparatus and a light-receiving apparatus.

More details of the structure of one embodiment of the present invention are as follows.

### Structure Example 1

### [Display Panel]

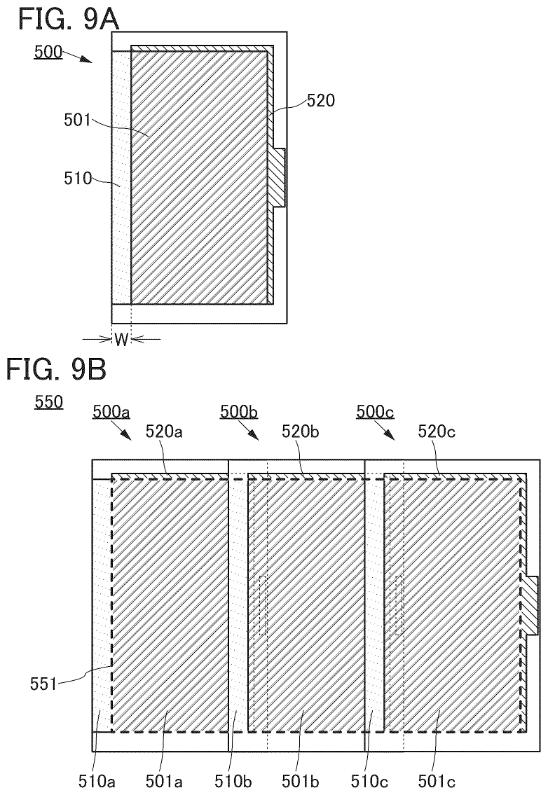

FIG. 9A is a schematic top view of a display panel 500 included in a display apparatus of one embodiment of the present invention.

The display panel 500 includes a display region 501, and a region 510 transmitting visible light and a region 520 having a portion blocking visible light that are adjacent to the display region 501.

Here, an image can be displayed on the display region 501 even when the display panel 500 is used independently. Moreover, an image can be captured by the display region 501 even when the display panel 500 is used independently.

In the region 510, for example, a pair of substrates included in the display panel 500, a sealant for sealing the light-emitting apparatus interposed between the pair of substrates, and the like may be provided. Here, for a member provided in the region 510, a material with a property of transmitting visible light is used.

In the region 520, for example, a wiring electrically connected to pixels included in the display region 501 is provided. In addition to such wiring, driver circuits (such as a scan line driver circuit and a signal line driver circuit) for driving the pixels or a circuit such as a protective circuit may be provided. Furthermore, the region 520 includes a region where a terminal electrically connected to an external terminal or a wiring layer (also referred to as a connection terminal), a wiring electrically connected to the terminal, or the like is provided.

For specific description of a cross-sectional structure example of the display panel or the like, the other embodiments can be referred to.

### [Stacked-Layer Panel]

A stacked-layer panel 550 of one embodiment of the present invention includes a plurality of display panels 500 described above. FIG. 9B illustrates a schematic top view of the stacked-layer panel 550 including three display panels.

Hereinafter, to distinguish the display panels from each other, the same components included in the display panels from each other, or the same components relating to the display panels from each other, letters are added to reference numerals of them. Unless otherwise specified, in a plurality of display panels partly overlapping with each other, “a” is added to reference numerals for a display panel placed on the lowest side (the side opposite to the display surface side), components thereof, and the like, and to one or more display panels placed on the upper side of the display panel, components thereof, and the like, “b” or letters after “b” in alphabetical order are added from the lower side. Furthermore, unless otherwise specified, in describing a structure in which a plurality of display panels are included, letters are not added when a common part of the display panels, the components, or the like is described.

The stacked-layer panel 550 illustrated in FIG. 9B includes a display panel 500a, a display panel 500b, and a display panel 500c.

The display panel 500b is placed so that part of the display panel 500b is stacked over an upper side (a display surface side) of the display panel 500a. Specifically, the display panel 500b is placed so that a display region 501a of the display panel 500a and a region 510b transmitting visible light of the display panel 500b overlap with each other and the display region 501a of the display panel 500a and a region 520b blocking visible light of the display panel 500b do not overlap each other.

Similarly, the display panel 500c is placed so as to partly overlap with an upper side (display surface side) of the display panel 500b. Specifically, the display panel 500c is placed so that a display region 501b of the display panel 500b and a region 510c transmitting visible light of the display panel 500c overlap with each other and the display region 501b of the display panel 500b and a region 520c blocking visible light of the display panel 500c do not overlap each other.

The region 510b transmitting visible light overlaps with the display region 501a: thus, the whole display region 501a can be visually recognized from the display surface side. Similarly, the whole display region 501b can also be visually recognized from the display surface side when the region 510c overlaps with the display region 501b. Therefore, a region where the display region 501a, the display region 501b, and a display region 501c are placed seamlessly can serve as a display region 551 of the stacked-layer panel 550.

The display region 551 of the stacked-layer panel 550 can be enlarged by the number of display panels 500. Here, by using display panels each having an image capturing function (i.e., display panels each including a light-emitting apparatus and a light-receiving apparatus) as all the display panels 500, the entire display region 551 can serve as an imaging region.

Note that without limitation to the above, a display panel having an image capturing function and a display panel not having an image capturing function (e.g., a display panel having no light-receiving element) may be combined. For example, a display panel having an image capturing function can be used where needed, and a display panel not having an image capturing function can be used in other portions.

### Structure Example 2

In FIG. 9B, the plurality of display panels 500 overlap each other in one direction; however, the plurality of display panels 500 may overlap each other in two directions of the vertical and horizontal directions.

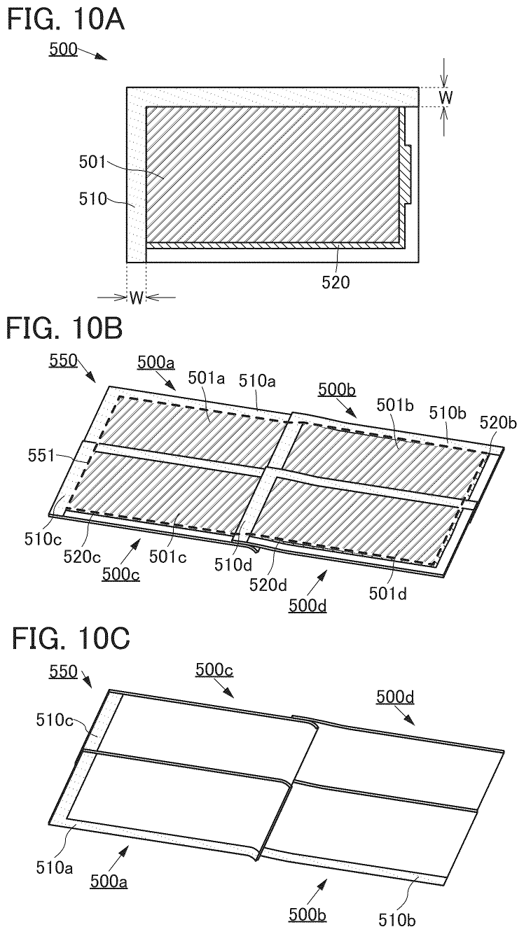

FIG. 10A illustrates an example of the display panel 500 that differs from that in FIG. 9A in the shape of the region 510. In the display panel 500 in FIG. 10A, the region 510 transmitting visible light is placed along two sides of the display region 501.

FIG. 10B is a schematic perspective view of the stacked-layer panel 550 in which the display panels 500 in FIG. 10A are arranged two by two in both vertical and horizontal directions. FIG. 10C is a schematic perspective view of the stacked-layer panel 550 when seen from a side opposite to the display surface side.

In FIG. 10B and FIG. 10C, a region along a short side of the display region 501a of the display panel 500a overlaps with part of the region 510b of the display panel 500b. In addition, a region along a long side of the display region 501a of the display panel 500a overlaps with part of the region 510c of the display panel 500c. Moreover, a region 510d of a display panel 500d overlaps with a region along a long side of the display region 501b of the display panel 500b and a region along a short side of the display region 501c of the display panel 500c.

Therefore, as illustrated in FIG. 10B, a region where the display region 501a, the display region 501b, the display region 501c, and the display region 501d are placed seamlessly can serve as the display region 551 of the stacked-layer panel 550.

Here, it is preferable that a flexible material be used for the pair of substrates included in the display panel 500 and the display panel 500 have flexibility. Thus, as is the case of the display panel 500a in FIG. 10B and FIG. 10C, part of the display panel 500a is curved, whereby the part of the display panel 500a is placed under the display region 501b of the adjacent display panel 500b so as to overlap with the display region 501b, for example.

Moreover, each display panel 500 is made flexible, in which case the display panel 500b can be curved gently so that the height of the top surface of the display region 501b of the display panel 500b is the same as the height of the top surface of the display region 501a of the display panel 500a. Thus, the display regions can have uniform height except in the vicinity of a region where the display panel 500a and the display panel 500b overlap with each other, and the display quality of an image displayed on the display region 551 of the stacked-layer panel 550 can be improved.

Although the relation between the display panel 500a and the display panel 500b is taken as an example in the above description, the same applies to the relation between any other two adjacent display panels.

To reduce the step between two adjacent display panels 500, the thickness of the display panel 500 is preferably small. For example, the thickness of the display panel 500 is preferably less than or equal to 1 mm, further preferably less than or equal to 300 μm, still further preferably less than or equal to 100 μm.

A substrate for protecting the display region 551 of the stacked-layer panel 550 may be provided. The substrate may be provided for each display panel, or one substrate may be provided for a plurality of display panels.

Note that although the structure where the four rectangular display panels 500 are stacked is described here, an extremely large stacked-layer panel can be obtained by increasing the number of display panels 500. By changing a method for arranging the plurality of display panels 500, the shape of the contour of the display region of the stacked-layer panel can be a non-rectangular shape, for example, a circular shape, an elliptical shape, or a polygonal shape. By arranging the display panels 500 three-dimensionally, a stacked-layer panel including display regions with a three-dimensional shape, various shapes such as a circular cylindrical shape, a spherical shape, or a hemispherical shape can be obtained.

At least part of this embodiment can be implemented in combination with the other embodiments described in this specification as appropriate.

### Embodiment 6

In this embodiment, electronic devices each including a light-emitting and light-receiving apparatus of one embodiment of the present invention will be described.

A light-emitting and light-receiving portion of the light-emitting and light-receiving apparatus of one embodiment of the present invention includes a light-receiving apparatus (also referred to as a light-receiving element or a light-receiving device) and a light-emitting apparatus (also referred to as a light-emitting element). The light-emitting and light-receiving portion has a function of displaying an image with the use of the light-emitting apparatus. Furthermore, the light-emitting and light-receiving portion has one or both of a function of capturing an image with the use of the light-receiving apparatuses and a detection function. Thus, the light-emitting and light-receiving apparatus of one embodiment of the present invention can be expressed as a display apparatus, and the light-emitting and light-receiving portion can be expressed as a display portion.

Alternatively, the electronic device of one embodiment of the present invention may have a structure including light-emitting and light-receiving apparatuses (also referred to as light-emitting and light-receiving devices) and light-emitting apparatuses.

First, the light-emitting and light-receiving apparatus that includes a light-receiving apparatus and a light-emitting apparatus is described.

The light-emitting and light-receiving apparatus of one embodiment of the present invention includes a light-receiving apparatus and a light-emitting apparatus in a light-emitting and light-receiving portion. In the light-emitting and light-receiving apparatus of one embodiment of the present invention, the light-emitting apparatuses are arranged in a matrix in the light-emitting and light-receiving portion, and an image can be displayed on the light-emitting and light-receiving portion. Furthermore, the light-receiving apparatuses are arranged in a matrix in the light-emitting and light-receiving portion, and the light-emitting and light-receiving portion has one or both of an image capturing function and a detecting function. The light-emitting and light-receiving portion can be used as an image sensor, a touch sensor, or the like. That is, by detecting light with the light-emitting and light-receiving portion, an image can be captured and touch operation of an object (e.g., a finger or a stylus) can be detected. Furthermore, in the light-emitting and light-receiving apparatus of one embodiment of the present invention, the light-emitting apparatuses can be used as a light source of the sensor. Accordingly, a light-receiving portion and a light source do not need to be provided separately from the light-emitting and light-receiving apparatus: hence, the number of components of an electronic device can be reduced.

In other words, the electronic device of one embodiment of the present invention includes both the light-emitting apparatus and the sensor device, so that, for example, a fingerprint authentication device, a capacitive touch panel device for scrolling, or the like is not necessarily provided separately from the electronic device. Thus, one embodiment of the present invention can provide an electronic device with reduced manufacturing cost.

In the light-emitting and light-receiving apparatus of one embodiment of the present invention, when an object reflects (or scatters) light emitted from the light-emitting apparatus included in the light-emitting and light-receiving portion, the light-receiving apparatus can detect the reflected light (or the scattered light): thus, image capturing and touch operation detection are possible even in a dark place.

The light-emitting apparatus included in the light-emitting and light-receiving apparatus of one embodiment of the present invention functions as a display element (also referred to as a display device).

As the light-emitting apparatus, an EL apparatus (also referred to as an EL element or an EL device) such as an OLED or a QLED is preferably used. Examples of a light-emitting substance contained in the EL apparatus include a substance emitting fluorescent light (a fluorescent material), a substance emitting phosphorescent light (a phosphorescent material), an inorganic compound (such as a quantum dot material), and a substance exhibiting thermally activated delayed fluorescence (a thermally activated delayed fluorescent (TADF) material). An LED such as a micro-LED can also be used as the light-emitting apparatus.

The light-emitting and light-receiving apparatus of one embodiment of the present invention has a function of detecting light with the use of the light-receiving apparatus.

When the light-receiving apparatus is used as an image sensor, the light-emitting and light-receiving apparatus can capture an image using the light-receiving apparatus. For example, the light-emitting and light-receiving apparatus can be used as a scanner.

An electronic device including the light-emitting and light-receiving apparatus of one embodiment of the present invention can obtain data related to biological information such as a fingerprint or a palm print by using a function of an image sensor. That is, a biometric authentication sensor can be incorporated in the light-emitting and light-receiving apparatus. When the light-emitting and light-receiving apparatus incorporates a biometric authentication sensor, the number of components of an electronic device can be reduced as compared to the case where a biometric authentication sensor is provided separately from the light-emitting and light-receiving apparatus: thus, the size and weight of the electronic device can be reduced.

When the light-receiving apparatus is used as the touch sensor, the light-emitting and light-receiving apparatus can detect touch operation of an object with the use of the light-receiving apparatus.

As the light-receiving apparatus, a pn photodiode or a pin photodiode can be used, for example. The light-receiving apparatus functions as a photoelectric conversion apparatus (also referred to as a photoelectric conversion element or a photoelectric conversion device) that detects light entering the light-receiving apparatus and generates electric charge. The amount of electric charge generated from the light-receiving apparatus is determined depending on the amount of light entering the light-receiving apparatus.

It is particularly preferable to use an organic photodiode including a layer containing an organic compound as the light-receiving apparatus. An organic photodiode, which is easily made thin, lightweight, and large in area and has a high degree of freedom for shape and design, can be used in a variety of devices.

In one embodiment of the present invention, an organic EL apparatuses (also referred to as organic EL devices) are used as the light-emitting apparatuses, and an organic photodiode is used as the light-receiving apparatuses. The organic EL apparatuses and the organic photodiodes can be formed over one substrate. Thus, the organic photodiode can be incorporated in a display apparatus including the organic EL apparatuses.

In the case where all the layers of the organic EL apparatuses and the organic photodiodes are formed separately, the number of deposition steps becomes extremely large. However, a large number of layers of the organic photodiodes can have a structure in common with layers of the organic EL apparatuses: thus, concurrently depositing the layers that can have a common structure can inhibit an increase in the number of deposition steps.

For example, one of a pair of electrodes (a common electrode) can be a layer shared by the light-receiving apparatus and the light-emitting apparatus. For example, at least one of a hole-injection layer, a hole-transport layer, an electron-transport layer, and an electron-injection layer may be a layer shared by the light-receiving apparatus and the light-emitting apparatus. When the light-receiving apparatus and the light-emitting apparatus include a common layer in such a manner, the number of deposition steps and the number of masks can be reduced, whereby the number of manufacturing steps and the manufacturing cost of the light-emitting and light-receiving apparatus can be reduced. Furthermore, the light-emitting and light-receiving apparatus including the light-receiving apparatus can be manufactured using an existing apparatus and an existing method for manufacturing a display apparatus.

Next, an electronic device including a light-emitting and light-receiving apparatus and a light-emitting apparatus will be described. Note that functions, behavior, effects, and the like similar to those described in the above are not described in some cases.

In the electronic device of one embodiment of the present invention, a subpixel exhibiting one color includes a light-emitting and light-receiving apparatus instead of a light-emitting apparatus, and subpixels exhibiting the other colors each include a light-emitting apparatus. The light-emitting and light-receiving apparatus has both a function of emitting light (a light-emitting function) and a function of receiving light (a light-receiving function). For example, in the case where a pixel includes three subpixels of a red subpixel, a green subpixel, and a blue subpixel, at least one of the subpixels includes a light-emitting and light-receiving apparatus, and the other subpixels each include a light-emitting apparatus. Thus, the light-emitting and light-receiving portion of the electronic device of one embodiment of the present invention has a function of displaying an image using both a light-emitting and light-receiving apparatus and a light-emitting apparatus.

The light-emitting and light-receiving apparatus functions as both a light-emitting apparatus and a light-receiving apparatus, whereby the pixel can have a light-receiving function without an increase in the number of subpixels included in the pixel. Thus, the light-emitting and light-receiving portion of the light-emitting and light-receiving apparatus can have one or both of an image capturing function and a detecting function while the light-emitting and light-receiving apparatus keeps the aperture ratio of the pixel (aperture ratio of each subpixel) and the resolution of the light-emitting and light-receiving apparatus. Accordingly, the light-emitting and light-receiving apparatus of one embodiment of the present invention can increase more the aperture ratio of the pixel and increase the resolution more easily than in the case of including a subpixel including a light-receiving apparatus separately from a subpixel including a light-emitting apparatus.

In the electronic device of one embodiment of the present invention, the light-emitting and light-receiving apparatuses and the light-emitting apparatuses are arranged in a matrix in the light-emitting and light-receiving portion, and an image can be displayed on the light-emitting and light-receiving portion. The light-emitting and light-receiving portion can be used as an image sensor, a touch sensor, or the like. In the light-emitting and light-receiving apparatus of one embodiment of the present invention, the light-emitting apparatuses can be used as a light source of the sensor. Thus, image capturing, touch operation detection, or the like is possible even in a dark place.

The light-emitting and light-receiving apparatus can be manufactured by combining an organic EL apparatus and an organic photodiode. For example, by adding an active layer of an organic photodiode to a stacked-layer structure of an organic EL apparatus, the light-emitting and light-receiving apparatus can be manufactured. Furthermore, in the light-emitting and light-receiving apparatus manufactured by combining an organic EL apparatus and an organic photodiode, concurrently forming layers that can have a structure in common with layers of the organic EL apparatus can inhibit an increase in the number of deposition steps.

For example, one of a pair of electrodes (a common electrode) can have a structure in common with the layers of the light-emitting and light-receiving apparatus and the light-emitting apparatus. For example, at least one of a hole-injection layer, a hole-transport layer, an electron-transport layer, and an electron-injection layer may be a layer shared with the light-emitting and light-receiving apparatus and the light-emitting apparatus.

Note that a layer included in the light-emitting and light-receiving apparatus may have a different function between the case where the light-emitting and light-receiving apparatus functions as a light-receiving apparatus and the case where the light-emitting and light-receiving apparatus functions as a light-emitting apparatus. In this specification, the name of a component is based on its function in the case where the light-emitting and light-receiving apparatus functions as a light-emitting apparatus.

The electronic device of this embodiment has a function of displaying an image by using the light-emitting apparatus and the light-emitting and light-receiving apparatus. That is, the light-emitting apparatus and the light-emitting and light-receiving apparatus function as a display apparatus.

The electronic device of this embodiment has a function of detecting light by using the light-emitting and light-receiving apparatus. The light-emitting and light-receiving apparatus can detect light having a shorter wavelength than light emitted from the light-emitting and light-receiving apparatus itself.

When the light-emitting and light-receiving apparatus is used as an image sensor, the electronic device of this embodiment can capture an image by using the light-emitting and light-receiving apparatus. When the light-emitting and light-receiving apparatus is used as a touch sensor, the electronic device of this embodiment can detect touch operation of an object with the use of the light-emitting and light-receiving apparatus.

The light-emitting and light-receiving apparatus functions as a photoelectric conversion apparatus. The light-emitting and light-receiving apparatus can be manufactured by adding an active layer of the light-receiving apparatus to the above-described structure of the light-emitting apparatus. For the light-emitting and light-receiving apparatus, an active layer of a pn photodiode or a pin photodiode can be used, for example.

It is particularly preferable to use, for the light-emitting and light-receiving apparatus, an active layer of an organic photodiode including a layer containing an organic compound. An organic photodiode, which is easily made thin, lightweight, and large in area and has a high degree of freedom for shape and design, can be used in a variety of devices.

The display apparatus that is an example of the electronic device of one embodiment of the present invention is specifically described below with reference to drawings.

### Structure Example 1 of Display Apparatus

### Structure Example 1-1

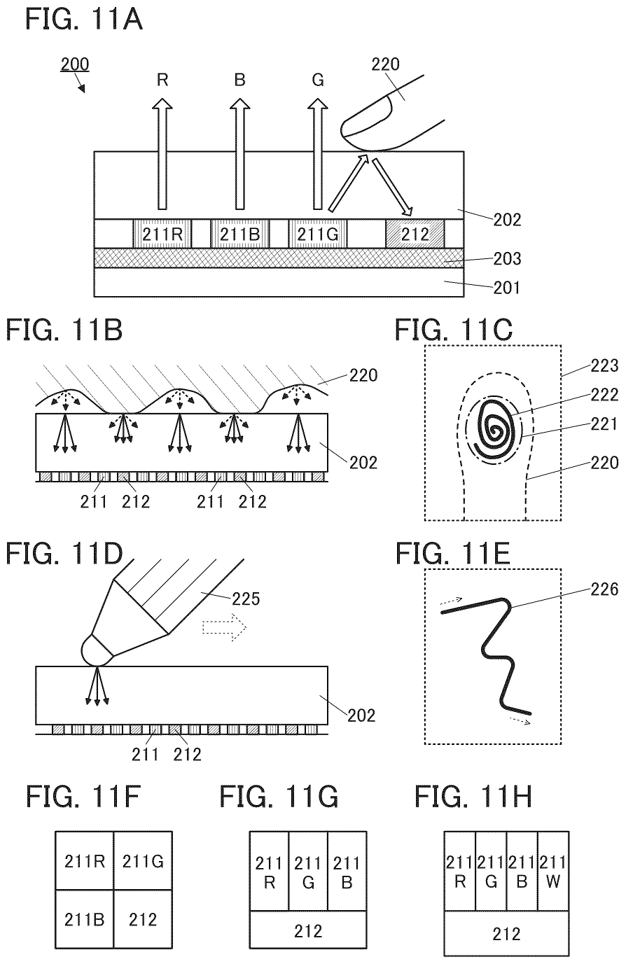

FIG. 11A is a schematic view of a display panel 200. The display panel 200 includes a substrate 201, a substrate 202, a light-receiving apparatus 212, a light-emitting apparatus 211R, a light-emitting apparatus 211G, a light-emitting apparatus 211B, a functional circuit layer 203, and the like.

The light-emitting apparatus 211R, the light-emitting apparatus 211G, the light-emitting apparatus 211B, and the light-receiving apparatus 212 are provided between the substrate 201 and the substrate 202. The light-emitting apparatus 211R, the light-emitting apparatus 211G, and the light-emitting apparatus 211B emit red (R) light, green (G) light, and blue (B) light, respectively. Note that in the following description, the term “light-emitting apparatus 211” may be used when the light-emitting apparatus 211R, the light-emitting apparatus 211G, and the light-emitting apparatus 211B are not distinguished from each other.

The display panel 200 includes a plurality of pixels arranged in a matrix. One pixel includes one or more subpixels. One subpixel includes one light-emitting apparatus. For example, the pixel can have a structure including three subpixels (e.g., three colors of R, G, and B or three colors of yellow (Y), cyan (C), and magenta (M)) or four subpixels (e.g., four colors of R, G, B, and white (W) or four colors of R, G, B, and Y). The pixel further includes the light-receiving apparatus 212. The light-receiving apparatus 212 may be provided in all the pixels or may be provided in some of the pixels. In addition, one pixel may include a plurality of light-receiving apparatuses 212.

FIG. 11A illustrates a finger 220 touching a surface of the substrate 202. Part of light emitted from the light-emitting apparatus 211G is reflected at a contact portion between the substrate 202 and the finger 220. In the case where part of the reflected light is incident on the light-receiving apparatus 212, the contact of the finger 220 with the substrate 202 can be detected. That is, the display panel 200 can function as a touch panel.

The functional circuit layer 203 includes a circuit for driving the light-emitting apparatus 211R, the light-emitting apparatus 211G, and the light-emitting apparatus 211B and a circuit for driving the light-receiving apparatus 212. The functional circuit layer 203 is provided with a switch, a transistor, a capacitor, a wiring, and the like. Note that in the case where the light-emitting apparatus 211R, the light-emitting apparatus 211G, the light-emitting apparatus 211B, and the light-receiving apparatus 212 are driven by a passive-matrix method, a structure not provided with a switch, a transistor, or the like may be employed.

The display panel 200 preferably has a function of detecting a fingerprint of the finger 220. FIG. 11B schematically illustrates an enlarged view of the contact portion in a state where the finger 220 touches the substrate 202. FIG. 11B illustrates the light-emitting apparatuses 211 and the light-receiving apparatuses 212 that are alternately arranged.

The fingerprint of the finger 220 is formed of depressions and projections. Accordingly, as illustrated in FIG. 11B, the projections of the fingerprint touch the substrate 202.

Reflection of light from a surface, an interface, or the like is categorized into regular reflection and diffuse reflection. Regularly reflected light is highly directional light with an angle of reflection equal to the angle of incidence. Diffusely reflected light has low directionality and low angular dependence of intensity. As for regular reflection and diffuse reflection, diffuse reflection components are dominant in the light reflected from the surface of the finger 220. Meanwhile, regular reflection components are dominant in the light reflected from the interface between the substrate 202 and the air.

The intensity of light that is reflected from contact surfaces or non-contact surfaces between the finger 220 and the substrate 202 and is incident on the light-receiving apparatuses 212 positioned directly below the contact surfaces or the non-contact surfaces is the sum of intensities of regularly reflected light and diffusely reflected light. As described above, regularly reflected light (indicated by solid arrows) is dominant near the depressions of the finger 220, where the finger 220 is not in contact with the substrate 202: whereas diffusely reflected light (indicated by dashed arrows) from the finger 220 is dominant near the projections of the finger 220, where the finger 220 is in contact with the substrate 202. Thus, the intensity of light received by the light-receiving apparatus 212 positioned directly below the depression is higher than the intensity of light received by the light-receiving apparatus 212 positioned directly below the projection. Accordingly, a fingerprint image of the finger 220 can be captured.

In the case where an arrangement interval between the light-receiving apparatuses 212 is smaller than a distance between two projections of a fingerprint, preferably a distance between a depression and a projection adjacent to each other, a clear fingerprint image can be obtained. The distance between a depression and a projection of a human's fingerprint is approximately 200 μm; thus, the arrangement interval between the light-receiving apparatuses 212 is, for example, less than or equal to 400 μm, preferably less than or equal to 200 μm, further preferably less than or equal to 150 μm, still further preferably less than or equal to 100 μm, even still further preferably less than or equal to 50 μm and greater than or equal to 1 μm, preferably greater than or equal to 10 μm, further preferably greater than or equal to 20 μm.

FIG. 11C illustrates an example of a fingerprint image captured by the display panel 200. In an image-capturing range 223 in FIG. 11C, the outline of the finger 220 is indicated by a dashed line and the outline of a contact portion 221 is indicated by a dashed-dotted line. In the contact portion 221, a high-contrast image of a fingerprint 222 can be captured owing to a difference in the amount of light incident on the light-receiving apparatuses 212.

The display panel 200 can also function as a touch panel or a pen tablet. FIG. 11D illustrates a state where a tip of a stylus 225 slides in a direction indicated with a dashed arrow while the tip of the stylus 225 touches the substrate 202.

As illustrated in FIG. 11D, when diffusely reflected light that is diffused at the contact surface of the tip of the stylus 225 and the substrate 202 is incident on the light-receiving apparatus 212 that overlaps with the contact surface, the position of the tip of the stylus 225 can be detected with high accuracy.

FIG. 11E illustrates an example of a path 226 of the stylus 225 that is detected by the display panel 200. The display panel 200 can detect the position of a detection target, such as the stylus 225, with high position accuracy, so that high-resolution drawing can be performed using a drawing application or the like. Unlike the case of using a capacitive touch sensor, an electromagnetic induction touch pen, or the like, the display panel 200 can detect even the position of a highly insulating object to be detected, the material of a tip portion of the stylus 225 is not limited, and a variety of writing materials (e.g., a brush, a glass pen, and a quill pen) can be used.

Here, FIG. 11F to FIG. 11H illustrate examples of a pixel that can be used in the display panel 200.

The pixels illustrated in FIG. 11F and FIG. 11G each include the light-emitting apparatus 211R for red (R), the light-emitting apparatus 211G for green (G), the light-emitting apparatus 211B for blue (B), and the light-receiving apparatus 212. The pixels each include a pixel circuit for driving the light-emitting apparatus 211R, the light-emitting apparatus 211G, the light-emitting apparatus 211B, and the light-receiving apparatus 212.

FIG. 11F illustrates an example in which three light-emitting apparatuses and one light-receiving apparatus are arranged in a matrix of 2×2. FIG. 11G illustrates an example in which three light-emitting apparatuses are arranged in one line and one laterally long light-receiving apparatus 212 is provided below the three light-emitting apparatuses.

The pixel illustrated in FIG. 11H is an example including a light-emitting apparatus 211W for white (W). Here, four light-emitting apparatuses are arranged in one line and the light-receiving apparatus 212 is provided below the four light-emitting apparatuses.

Note that the pixel structure is not limited to the above structure, and a variety of arrangement methods can be employed.

### Structure Example 1-2

An example of a structure including a light-emitting apparatus emitting visible light, a light-emitting apparatus emitting infrared light, and a light-receiving apparatus is described below.

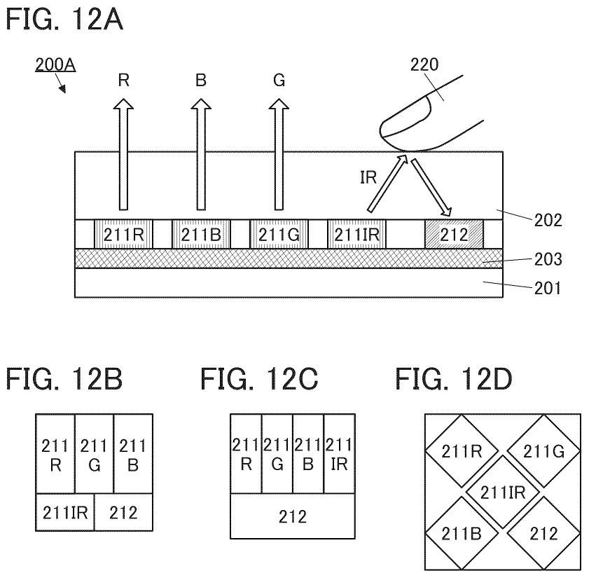

A display panel 200A illustrated in FIG. 12A includes a light-emitting apparatus 211IR in addition to the components illustrated in FIG. 11A as an example. The light-emitting apparatus 211IR is a light-emitting apparatus emitting infrared light IR. Moreover, in that case, a light-receiving apparatus capable of receiving at least the infrared light IR emitted from the light-emitting apparatus 211IR is preferably used as the light-receiving apparatus 212. As the light-receiving apparatus 212, an apparatus capable of receiving visible light and infrared light is further preferably used.

As illustrated in FIG. 12A, when the finger 220 touches the substrate 202, the infrared light IR emitted from the light-emitting apparatus 211IR is reflected by the finger 220 and part of reflected light is incident on the light-receiving apparatus 212, so that the positional information of the finger 220 can be obtained.

FIG. 12B to FIG. 12D illustrate examples of a pixel that can be used in the display panel 200A.

FIG. 12B illustrates an example in which three light-emitting apparatuses are arranged in one line and the light-emitting apparatus 211IR and the light-receiving apparatus 212 are arranged below the three light-emitting apparatuses in a horizontal direction. In the display apparatus of one embodiment of the present invention, the pixel has a light-receiving function, so that the contact or approach of an object can be detected while an image is displayed. Moreover, the display apparatus of one embodiment of the present invention includes a subpixel emitting infrared light: thus, with the use of the subpixels included in the display apparatus, an image can be displayed while infrared light is emitted as a light source. In other words, the display apparatus of one embodiment of the present invention has a structure with high affinity for a function other than a display function (here, a light-receiving function). The light-receiving apparatus 212 may be used for a touch sensor, a non-contact sensor, or the like.

FIG. 12C illustrates an example in which four light-emitting apparatuses including the light-emitting apparatus 211IR are arranged in one line and the light-receiving apparatus 212 is provided below the four light-emitting apparatuses.

FIG. 12D illustrates an example in which three light-emitting apparatuses and the light-receiving apparatus 212 are arranged in all directions with the light-emitting apparatus 211IR as the center.

Note that in the pixels illustrated in FIG. 12B to FIG. 12D, the positions of the light-emitting apparatuses can be interchangeable, or the positions of the light-emitting apparatus and the light-receiving apparatus can be interchangeable.

### Structure Example 1-3

An example of a structure including a light-emitting apparatus emitting visible light and a light-emitting and light-receiving apparatus emitting and receiving visible light is described below.

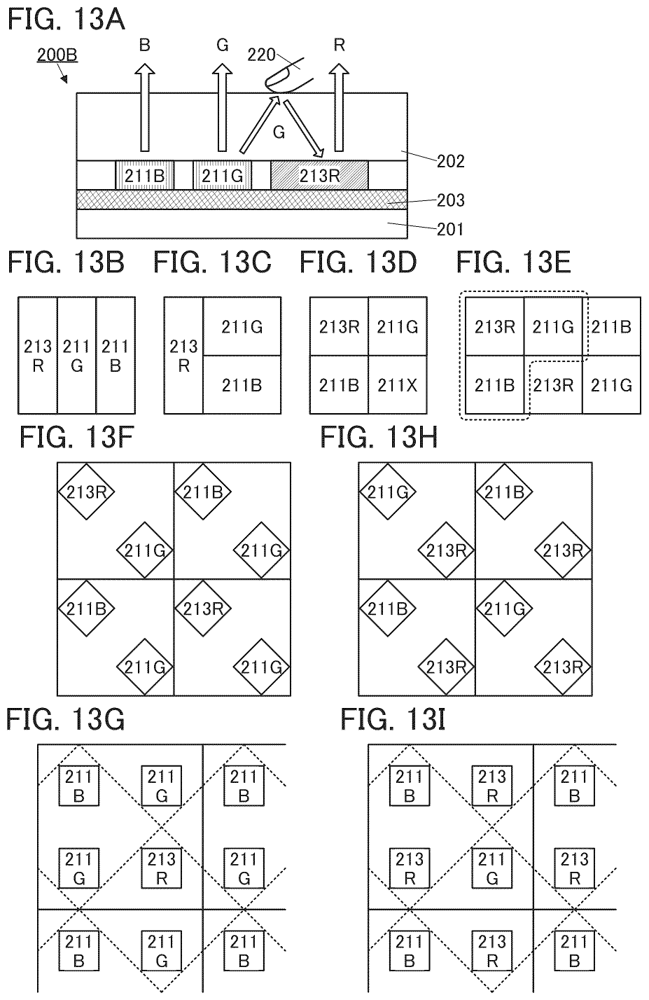

A display panel 200B illustrated in FIG. 13A includes the light-emitting apparatus 211B, the light-emitting apparatus 211G, and a light-emitting and light-receiving apparatus 213R. The light-emitting and light-receiving apparatus 213R has a function of a light-emitting apparatus that emits red (R) light and a function of a photoelectric conversion apparatus that receives visible light. FIG. 13A illustrates an example in which the light-emitting and light-receiving apparatus 213R receives green (G) light emitted from the light-emitting apparatus 211G. Note that the light-emitting and light-receiving apparatus 213R may receive blue (B) light emitted from the light-emitting apparatus 211B. Alternatively, the light-emitting and light-receiving apparatus 213R may receive both green light and blue light.

For example, the light-emitting and light-receiving apparatus 213R may receive light (e.g., infrared light) with a shorter wavelength or a longer wavelength than light emitted from itself. The light-emitting and light-receiving apparatus 213R may receive light having approximately the same wavelength as light emitted from itself: however, in that case, the light-emitting and light-receiving apparatus 213R also receives light emitted from itself, whereby its emission efficiency might be decreased. Therefore, it is preferable that the light-emitting and light-receiving apparatus 213R have the structure in which the peak of the emission spectrum of light emitted from itself and the peak of the absorption spectrum of the light received overlap as little as possible.

Here, light emitted from the light-emitting and light-receiving apparatus is not limited to red light. Furthermore, the light emitted from the light-emitting apparatuses is not limited to the combination of green light and blue light. For example, the light-emitting and light-receiving apparatus can be an apparatus that emits green or blue light and receives light having a different wavelength from light emitted from itself.

The light-emitting and light-receiving apparatus 213R serves as both a light-emitting apparatus and a light-receiving apparatus as described above, whereby the number of devices provided in one pixel can be reduced. Thus, higher definition, a higher aperture ratio, higher resolution, and the like can be easily achieved.

FIG. 13B to FIG. 13I illustrate examples of a pixel that can be used in the display panel 200B.

FIG. 13B illustrates an example in which the light-emitting and light-receiving apparatus 213R, the light-emitting apparatus 211G, and the light-emitting apparatus 211B are arranged in one line. FIG. 13C illustrates an example in which the light-emitting apparatus 211G and the light-emitting apparatus 211B are alternately arranged in the vertical direction and the light-emitting and light-receiving apparatus 213R is provided alongside the light-emitting apparatuses.

FIG. 13D illustrates an example in which three light-emitting apparatuses (the light-emitting apparatus 211G, the light-emitting apparatus 211B, and a light-emitting apparatus 211X) and one light-emitting and light-receiving apparatus 213R are arranged in matrix of 2×2. The light-emitting apparatus 211X is a light-emitting apparatus that emits light of a color other than R. G, and B. The light of a color other than R, G, and B can be white (W) light, yellow (Y) light, cyan (C) light, magenta (M) light, infrared light (IR), ultraviolet light (UV), or the like. In the case where the light-emitting apparatus 211X emits infrared light, the light-emitting and light-receiving apparatus 213R preferably has a function of detecting infrared light or a function of detecting both visible light and infrared light. The wavelength of light detected by the light-emitting and light-receiving apparatus can be determined depending on the application of a sensor.

FIG. 13E illustrates two pixels. A region that includes three light-emitting apparatuses and is enclosed by a dotted line corresponds to one pixel. Each of the pixels includes the light-emitting apparatus 211G, the light-emitting apparatus 211B, and the light-emitting and light-receiving apparatus 213R. In the left pixel in FIG. 13E, the light-emitting apparatus 211G is provided in the same row as the light-emitting and light-receiving apparatus 213R, and the light-emitting apparatus 211B is provided in the same column as the light-emitting and light-receiving apparatus 213R. In the right pixel in FIG. 13E, the light-emitting apparatus 211G is provided in the same row as the light-emitting and light-receiving apparatus 213R, and the light-emitting apparatus 211B is provided in the same column as the light-emitting apparatus 211G. In the pixel layout in FIG. 13E, the light-emitting and light-receiving apparatus 213R, the light-emitting apparatus 211G, and the light-emitting apparatus 211B are repeatedly arranged in both the odd-numbered row and the even-numbered row, and in each column, the light-emitting apparatuses or the light-emitting apparatus and the light-emitting and the receiving apparatuses arranged in the odd-numbered row and the even-numbered row emit light of different colors.

FIG. 13F illustrates four pixels which employ PenTile arrangement: adjacent two pixels have different combinations of light-emitting apparatuses or light-emitting and light-receiving apparatuses that emit light of two different colors. FIG. 13F illustrates the top-surface shapes of the light-emitting apparatuses or light-emitting and light-receiving apparatuses.

The upper left pixel and the lower right pixel in FIG. 13F each include the light-emitting and light-receiving apparatus 213R and the light-emitting apparatus 211G. The upper right pixel and the lower left pixel each include the light-emitting apparatus 211G and the light-emitting apparatus 211B. That is, in the example illustrated in FIG. 13F, the light-emitting apparatus 211G is provided in each pixel.

The top surface shapes of the light-emitting apparatuses and the light-emitting and light-receiving apparatuses are not particularly limited and can be a circular shape, an elliptical shape, a polygonal shape, a polygonal shape with rounded corners, or the like. FIG. 13F and the like illustrate examples in which the top surface shapes of the light-emitting apparatuses and the light-emitting and light-receiving apparatuses are each a square tilted at approximately 45° (a diamond shape). Note that the top surface shapes of the light-emitting apparatuses and the light-emitting and light-receiving apparatuses may vary depending on the color thereof, or the light-emitting apparatuses and the light-emitting and light-receiving apparatuses of some colors or every color may have the same top surface shapes.

The sizes of light-emitting regions (or light-emitting and light-receiving regions) of the light-emitting apparatuses and the light-emitting and light-receiving apparatuses may vary depending on the color thereof, or the light-emitting apparatuses and the light-emitting and light-receiving apparatuses of some colors or every color may have light-emitting regions of the same size. For example, in FIG. 13F, the light-emitting region of the light-emitting apparatus 211G provided in each pixel may have a smaller area than the light-emitting region (or the light-emitting and light-receiving region) of the other apparatuses.

FIG. 13G is a modification example of the pixel arrangement of FIG. 13F. Specifically, the structure in FIG. 13G is obtained by rotating the structure in FIG. 13F by 45°. Although FIG. 13F illustrates the structure in which two light-emitting apparatuses (or two light-emitting and light-receiving apparatuses) are included in one pixel, one pixel can be regarded as being formed with four light-emitting apparatuses (or four light-emitting and light-receiving apparatuses) as illustrated in FIG. 13G.

FIG. 13H is a modification example of the pixel arrangement illustrated in FIG. 13F. The upper left pixel and the lower right pixel in FIG. 13H each include the light-emitting and light-receiving apparatus 213R and the light-emitting apparatus 211G. The upper right pixel and the lower left pixel each include the light-emitting and light-receiving apparatus 213R and the light-emitting apparatus 211B. That is, in the example illustrated in FIG. 13H, the light-emitting and light-receiving apparatus 213R is provided in each pixel. The structure illustrated in FIG. 13H achieves higher-resolution image capturing than the structure illustrated in FIG. 13F because of including the light-emitting and light-receiving apparatus 213R in each pixel. Thus, the accuracy of biometric authentication can be increased, for example.

FIG. 13I illustrates a modification example of the pixel arrangement in FIG. 13H, which is obtained by rotating the pixel arrangement in FIG. 13H by 45°.

In FIG. 13I, one pixel is described as being formed of four devices (two light-emitting apparatuses and two light-emitting and light-receiving apparatuses). One pixel including a plurality of light-emitting and light-receiving apparatuses having a light-receiving function allows high-resolution image capturing. Accordingly, the accuracy of biometric authentication can be increased. For example, the resolution of image capturing can be the square root of 2 times the resolution of display.

A display apparatus that employs the structure illustrated in FIG. 13H or FIG. 13I includes p (p is an integer greater than or equal to 2) first light-emitting apparatuses, q (q is an integer greater than or equal to 2) second light-emitting apparatuses, and r (r is an integer greater than p and q) light-emitting and light-receiving apparatuses. As for p and r, r=2p is satisfied. As for p, q, and r, r=p+q is satisfied. Either the first light-emitting apparatuses or the second light-emitting apparatuses emit green light, and the other light-emitting apparatuses emit blue light. The light-emitting and light-receiving apparatuses emit red light and have a light-receiving function.

In the case where touch operation is detected with the light-emitting and light-receiving apparatuses, for example, it is preferable that light emitted from a light source be hard for a user to recognize. Since blue light has lower visibility than green light, light-emitting apparatuses that emit blue light are preferably used as a light source. Accordingly, the light-emitting and light-receiving apparatuses preferably have a function of receiving blue light. Note that without limitation to the above, light-emitting apparatuses used as a light source can be selected as appropriate depending on the sensitivity of the light-emitting and light-receiving apparatuses.

As described above, the display apparatus of this embodiment can employ various types of pixel arrangements.

At least part of this embodiment can be implemented in combination with the other embodiments described in this specification as appropriate.

### Embodiment 7

In this embodiment, a light-emitting apparatus (also referred to as a light-emitting device) and a light-receiving apparatus (also referred to as a light-receiving device) that can be used in the light-receiving and light-emitting apparatus of one embodiment of the present invention will be described.

### [Light-Emitting Apparatus]

The light-emitting apparatuses can be roughly classified into a single structure and a tandem structure. A device having a single structure includes one light-emitting unit between a pair of electrodes, and the light-emitting unit preferably includes one or more light-emitting layers. To obtain white light emission in a single structure, two or more light-emitting layers are selected such that emission colors of the light-emitting layers are complementary colors. For example, when an emission color of a first light-emitting layer and an emission color of a second light-emitting layer are complementary colors, the light-emitting apparatus can be configured to emit white light as a whole. The same applies to a light-emitting apparatus including three or more light-emitting layers.

A light-emitting apparatus having a tandem structure includes two or more light-emitting units between a pair of electrodes, and each light-emitting unit preferably includes one or more light-emitting layers. When light-emitting layers that emit light of the same color are used in each light-emitting unit, luminance per predetermined current can be increased, and the light-emitting apparatus can have higher reliability than that with a single structure. To obtain white light emission in a tandem structure, the structure in which white light emission can be obtained by combining light from light-emitting layers of a plurality of light-emitting units is employed. Note that a combination of emission colors for obtaining white light emission is similar to that in the case of a single structure. In the device having a tandem structure, it is suitable that an intermediate layer such as a charge-generation layer is provided between a plurality of light-emitting units.

Furthermore, when the above white light-emitting apparatus (having a single structure or a tandem structure) and a light-emitting apparatus having an SBS structure are compared, the light-emitting apparatus having an SBS structure can have lower power consumption than the white light-emitting apparatus. To reduce power consumption, the light-emitting apparatus having an SBS structure is suitably used. By contrast, the white light-emitting apparatus is suitable in terms of lower manufacturing cost or higher manufacturing yield because the manufacturing process of the white light-emitting apparatus is simpler than that of the light-emitting apparatus having an SBS structure.

### <Structure Example of Light-Emitting Apparatus>

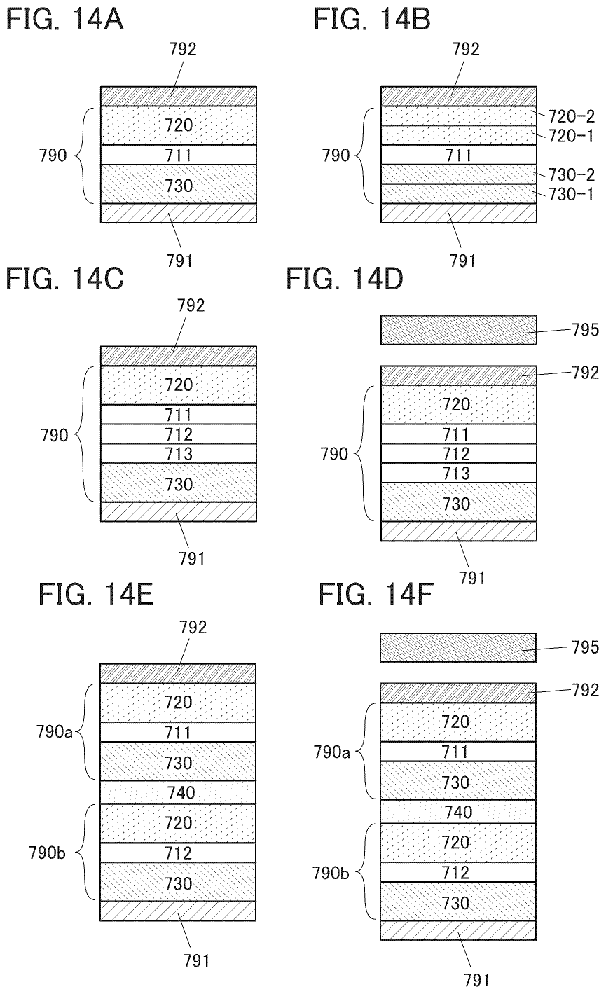

As illustrated in FIG. 14A, the light-emitting apparatus includes an EL layer 790 between a pair of electrodes (a lower electrode 791 and an upper electrode 792). The EL layer 790 can be formed of a plurality of layers such as a layer 720, a light-emitting layer 711, and a layer 730. The layer 720 can include, for example, a layer containing a substance with a high electron-injection property (an electron-injection layer), a layer containing a substance with a high electron-transport property (an electron-transport layer), and the like. The light-emitting layer 711 contains a light-emitting compound, for example. The layer 730 can include a layer containing a substance having a high hole-injection property (a hole-injection layer) and a layer containing a substance having a high hole-transport property (a hole-transport layer), for example.

The structure including the layer 720, the light-emitting layer 711, and the layer 730, which are provided between a pair of electrodes, can serve as a single light-emitting unit, and the structure in FIG. 14A is referred to as a single structure in this specification.

FIG. 14B is a modification example of the EL layer 790 included in the light-emitting apparatus illustrated in FIG. 14A. Specifically, the light-emitting apparatus illustrated in FIG. 14B includes a layer 730-1 over the lower electrode 791, a layer 730-2 over the layer 730-1, the light-emitting layer 711 over the layer 730-2, a layer 720-1 over the light-emitting layer 711, a layer 720-2 over the layer 720-1, and the upper electrode 792 over the layer 720-2. For example, when the lower electrode 791 functions as an anode and the upper electrode 792 functions as a cathode, the layer 730-1 functions as a hole-injection layer, the layer 730-2 functions as a hole-transport layer, the layer 720-1 functions as an electron-transport layer, and the layer 720-2 functions as an electron-injection layer. Alternatively, when the lower electrode 791 functions as a cathode and the upper electrode 792 functions as an anode, the layer 730-1 functions as an electron-injection layer, the layer 730-2 functions as an electron-transport layer, the layer 720-1 functions as a hole-transport layer, and the layer 720-2 functions as a hole-injection layer. With such a layer structure, carriers can be efficiently injected to the light-emitting layer 711, and the efficiency of the recombination of carriers in the light-emitting layer 711 can be enhanced.

Note that the structures in which a plurality of light-emitting layers (light-emitting layers 711, 712, and 713) are provided between the layer 720 and the layer 730 as illustrated in FIG. 14C and FIG. 14D are variations of the single structure. The number of light-emitting layers in a light-emitting device having a single structure may be two or four or more. In addition, the light-emitting device having a single structure may include a buffer layer between two light-emitting layers. The buffer layer can be formed using a material that can be used for the hole-transport layer or the electron-transport layer, for example.

A structure in which a plurality of light-emitting units (an EL layer 790a and an EL layer 790b) are connected in series with an intermediate layer (a charge-generation layer) 740 therebetween as illustrated in FIG. 14E and FIG. 14F is referred to as a tandem structure in this specification. In this specification and the like, the structure illustrated in FIG. 14E and FIG. 14F is referred to as a tandem structure: however, without being limited to this, a tandem structure may be referred to as a stack structure, for example. Note that the tandem structure enables a light-emitting apparatus to emit light at high luminance.

In FIG. 14C, light-emitting materials that emit the same light may be used for the light-emitting layer 711, the light-emitting layer 712, and the light-emitting layer 713.

Alternatively, different light-emitting materials may be used for the light-emitting layer 711, the light-emitting layer 712, and the light-emitting layer 713. White light can be obtained when the light-emitting layer 711, the light-emitting layer 712, and the light-emitting layer 713 emit light of complementary colors. FIG. 14D illustrates an example in which a coloring layer 795 functioning as a color filter is provided. When white light passes through a color filter, light of a desired color can be obtained.

In FIG. 14E, the same light-emitting material may be used for the light-emitting layer 711 and the light-emitting layer 712. Alternatively, light-emitting materials that emit light of different colors may be used for the light-emitting layer 711 and the light-emitting layer 712. White light can be obtained when the light-emitting layer 711 and the light-emitting layer 712 emit light of complementary colors. FIG. 14F illustrates an example in which the coloring layer 795 is further provided.

In FIG. 14C, FIG. 14D, FIG. 14E, and FIG. 14F, the layer 720 and the layer 730 may each have a stacked-layer structure of two or more layers as in FIG. 14B.

In FIG. 14D, the same light-emitting material may be used for the light-emitting layer 711, the light-emitting layer 712, and the light-emitting layer 713. Similarly, in FIG. 14F, the same light-emitting material may be used for the light-emitting layer 711 and the light-emitting layer 712. Here, when a color conversion layer is used instead of the coloring layer 795, light of a desired color different from the emission color of the light-emitting material can be obtained. For example, a blue-light-emitting material is used for each light-emitting layer and blue light passes through the color conversion layer, whereby light with a wavelength longer than that of blue light (e.g., red light or green light) can be obtained. For the color conversion layer, a fluorescent material, a phosphorescent material, quantum dots, or the like can be used.

A structure in which light-emitting apparatuses that emit light of different colors (here, blue (B), green (G), and red (R)) are separately formed is referred to as an SBS (Side By Side) structure in some cases.

The emission color of the light-emitting apparatus can be red, green, blue, cyan, magenta, yellow, white, or the like depending on the material that constitutes the EL layer 790. Furthermore, the color purity can be further increased when the light-emitting apparatus has a microcavity structure.

The light-emitting apparatus that emits white light preferably contains two or more kinds of light-emitting substances in the light-emitting layer. To obtain white light emission, two or more light-emitting substances are selected such that their emission colors are complementary colors. For example, when the emission color of a first light-emitting layer and the emission color of a second light-emitting layer have a relation of complementary colors, it is possible to obtain a light-emitting apparatus which emits white light as a whole. The same applies to a light-emitting apparatus including three or more light-emitting layers.

The light-emitting layer preferably contains two or more light-emitting substances that emit light of R (red), G (green), B (blue), Y (yellow), O (orange), and the like. Alternatively, the light-emitting layer preferably contains two or more light-emitting substances each of which emits light containing two or more of spectral components of R, G, and B.

### [Light-Receiving Apparatus]

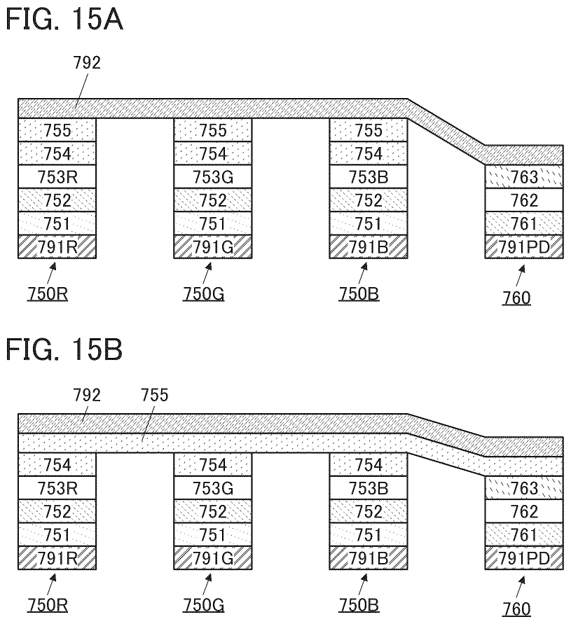

FIG. 15A is a schematic cross-sectional view of a light-emitting apparatus 750R, a light-emitting apparatus 750G, a light-emitting apparatus 750B, and a light-receiving apparatus 760. The light-emitting apparatus 750R, the light-emitting apparatus 750G, the light-emitting apparatus 750B, and the light-receiving apparatus 760 include an upper electrode 792 as a common layer.

The light-emitting apparatus 750R includes a pixel electrode 791R, a layer 751, a layer 752, a light-emitting layer 753R, a layer 754, a layer 755, and the upper electrode 792. The light-emitting apparatus 750G includes the pixel electrode 791G and a light-emitting layer 753G. The light-emitting apparatus 750B includes a pixel electrode 791B and a light-emitting layer 753B.

The layer 751 includes, for example, a layer containing a substance with a high hole-injection property (a hole-injection layer). The layer 752 includes, for example, a layer containing a substance with a high hole-transport property (a hole-transport layer). The layer 754 includes, for example, a layer containing a substance with a high electron-transport property (an electron-transport layer). A layer 755 includes, for example, a layer containing a substance with a high electron-injection property (an electron-injection layer).

Alternatively, the layer 751 may include an electron-injection layer, the layer 752 may include an electron-transport layer, the layer 754 may include a hole-transport layer, and the layer 755 may include a hole-injection layer.

FIG. 15A illustrates the layer 751 and the layer 752 separately: however, one embodiment of the present invention is not limited thereto. For example, the layer 752 may be omitted when the layer 751 has functions of both a hole-injection layer and a hole-transport layer or the layer 751 has functions of both an electron-injection layer and an electron-transport layer.

Note that the light-emitting layer 753R included in the light-emitting apparatus 750R includes a light-emitting substance that emits red light, the light-emitting layer 753G included in the light-emitting apparatus 750G includes a light-emitting substance that emits green light, and the light-emitting layer 753B included in the light-emitting apparatus 750B includes a light-emitting substance that emits blue light. Note that the light-emitting apparatus 750G and the light-emitting apparatus 750B have a structure in which the light-emitting layer 753R included in the light-emitting apparatus 750R is replaced with the light-emitting layer 753G and the light-emitting layer 753B, respectively, and the other components are similar to those of the light-emitting apparatus 750R.

The structure (e.g., material and thickness) of the layer 751, the layer 752, the layer 754, and the layer 755 may be the same or different from each other among the light-emitting apparatuses of different colors.

The light-receiving apparatus 760 includes a pixel electrode 791PD, a layer 761, a layer 762, a layer 763, and the upper electrode 792. The light-receiving apparatus 760 can be configured not to include a hole-injection layer and an electron-injection layer.

The layer 762 includes an active layer (also referred to as a photoelectric conversion layer). The layer 762 has a function of absorbing light in a specific wavelength range and generating carriers (electrons and holes).

Each of the layer 761 and the layer 763 includes, for example, a hole-transport layer and an electron-transport layer. In the case where the layer 761 includes a hole-transport layer, the layer 763 includes an electron-transport layer. In the case where the layer 761 includes an electron-transport layer, the layer 763 includes a hole-transport layer.

In the light-receiving apparatus 760, the pixel electrode 791PD may be an anode and the upper electrode 792 may be a cathode, or the pixel electrode 791PD may be a cathode and the upper electrode 792 may be an anode.

FIG. 15B is a modification example of FIG. 15A. FIG. 15B shows an example in which the light-emitting apparatuses and the light-receiving apparatuses share the layer 755 as well as the upper electrode 792. In this case, the layer 755 can be referred to as a common layer. By providing one or more common layers for the light-emitting apparatuses and the light-receiving apparatuses in this manner, the manufacturing process can be simplified, which results in a reduction in manufacturing cost.

Here, the layer 755 functions as an electron-injection layer or a hole-injection layer of the light-emitting apparatus 750. At this time, the layer 755 functions as an electron-transport layer or a hole-transport layer of the light-receiving apparatus 760. Thus, the light-receiving apparatus 760 illustrated in FIG. 15B is not necessarily provided with the layer 763 functioning as an electron-transport layer or a hole-transport layer.

### [Light-Emitting Apparatus]

Here, a specific structure example of a light-emitting apparatus is described.

The light-emitting apparatus includes at least the light-emitting layer. The light-emitting apparatus may further include, as a layer other than the light-emitting layer, a layer containing a substance with a high hole-injection property, a substance with a high hole-transport property, a hole-blocking material, a substance with a high electron-transport property, an electron-blocking material, a substance with a high electron-injection property, a substance with a bipolar property (a substance with a high electron-transport property and a high hole-transport property), or the like.

Either a low molecular compound or a high molecular compound can be used for the light-emitting apparatus, and an inorganic compound may also be contained. Each of the layers included in the light-emitting apparatus can be formed by an evaporation method (including a vacuum evaporation method), a transfer method, a printing method, an inkjet method, a coating method, or the like.

For example, the light-emitting apparatus can include one or more of a hole-injection layer, a hole-transport layer, a hole-blocking layer, an electron-blocking layer, an electron-transport layer, and an electron-injection layer.

The hole-injection layer is a layer injecting holes from an anode to a hole-transport layer and containing a material with a high hole-injection property. Examples of the material with a high hole-injection property include an aromatic amine compound and a composite material containing a hole-transport material and an acceptor material (electron-accepting material).

The hole-transport layer is a layer transporting holes, which are injected from the anode by the hole-injection layer, to the light-emitting layer. The hole-transport layer is a layer containing a hole-transport material. As the hole-transport material, a substance having a hole mobility greater than or equal to 10⁻⁶ cm²/Vs is preferable. Note that other substances can also be used as long as they have a property of transporting more holes than electrons. As the hole-transport material, materials with a high hole-transport property, such as a T-electron rich heteroaromatic compound (e.g., a carbazole derivative, a thiophene derivative, and a furan derivative) and an aromatic amine (a compound having an aromatic amine skeleton), are preferred.

The electron-transport layer is a layer transporting electrons, which are injected from a cathode by the electron-injection layer, to the light-emitting layer. The electron-transport layer is a layer containing an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material having a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or π-electron deficient heteroaromatic compound including a nitrogen-containing heteroaromatic compound.

The electron-injection layer is a layer injecting electrons from a cathode to the electron-transport layer and containing a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

For the electron-injection layer, it is possible to use, for example, an alkali metal, an alkaline earth metal, or a compound thereof, such as lithium, cesium, ytterbium, lithium fluoride (LiF), cesium fluoride (CsF), calcium fluoride (CaF₂), 8-(quinolinolato) lithium (abbreviation: Liq), 2-(2-pyridyl) phenolatolithium (abbreviation: LiPP), 2-(2-pyridyl)-3-pyridinolatolithium (abbreviation: LiPPy), 4-phenyl-2-(2-pyridyl) phenolatolithium (abbreviation: LiPPP), lithium oxide (LiO_{X}), or cesium carbonate. In addition, the electron-injection layer may have a stacked-layer structure of two or more layers. In the stacked-layer structure, for example, lithium fluoride can be used for a first layer and ytterbium can be used for a second layer.

Alternatively, an electron-transport material may be used for the electron-injection layer. For example, a compound having an unshared electron pair and having an electron deficient heteroaromatic ring can be used as the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) of the organic compound having an unshared electron pair is preferably greater than or equal to −3.6 eV and less than or equal to −2.3 eV. In addition, in general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl) biphenyl-3-yl]-1,3,5-triazine (abbreviation: TmPPPyTz), or the like can be used as the organic compound having an unshared electron pair. Note that NBPhen has a higher glass transition temperature (Tg) than BPhen and thus has high heat resistance.

The light-emitting layer is a layer containing a light-emitting substance. The light-emitting layer can include one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton: an organometallic complex (particularly an iridium complex) having a phenylpyridine derivative including an electron-withdrawing group as a ligand: a platinum complex; and a rare earth metal complex.

The light-emitting layer may contain one or more kinds of organic compounds (a host material, an assist material, and the like) in addition to the light-emitting substance (a guest material). As one or more kinds of organic compounds, one or both of the hole-transport material and the electron-transport material can be used. Alternatively, as one or more kinds of organic compounds, a bipolar material, or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from an exciplex to a light-emitting substance (a phosphorescent material). When a combination of materials is selected to form an exciplex that exhibits light emission whose wavelength overlaps with the wavelength of a lowest-energy-side absorption band of the light-emitting substance, energy can be transferred smoothly and light emission can be obtained efficiently. With this structure, the high efficiency, low-voltage driving, and long lifetime of the light-emitting apparatus can be achieved at the same time.

### [Light-Receiving Apparatus]

The active layer included in the light-receiving apparatus contains a semiconductor. Examples of the semiconductor include an inorganic semiconductor such as silicon and an organic semiconductor including an organic compound. This embodiment describes an example in which an organic semiconductor is used as the semiconductor contained in the active layer. The use of an organic semiconductor is preferable because the light-emitting layer and the active layer can be formed by the same method (e.g., a vacuum evaporation method) and thus the same manufacturing apparatus can be used.

Examples of an n-type semiconductor material included in the active layer include electron-accepting organic semiconductor materials such as fullerene (e.g., C₆₀ and C₇₀) and fullerene derivatives. Fullerene has a soccer ball-like shape, which is energetically stable. Both the HOMO level and the LUMO level of fullerene are deep (low). Having a deep LUMO level, fullerene has an extremely high electron-accepting property (acceptor property). When T-electron conjugation (resonance) spreads on a plane as in benzene, an electron-donating property (donor property) usually increases: however, fullerene has a spherical shape, and thus has a high electron-accepting property although x-electron conjugation widely spread therein. The high electron-accepting property efficiently causes rapid charge separation and is useful for a light-receiving device. Both C₆₀ and C₇₀ have a wide absorption band in the visible light region, and C₇₀ is especially preferable because of having a larger π-electron conjugation system and a wider absorption band in the long wavelength region than C₆₀. Other examples of fullerene derivatives include [6,6]-phenyl-C71-butyric acid methyl ester (abbreviation: PC70BM), [6,6]-phenyl-C61-butyric acid methyl ester (abbreviation: PC60BM), and l′,1″,4′,4″-tetrahydro-di[1,4]methanonaphthaleno[1,2:2′,3′,56,60:2″,3″][5,6]fullerene-C60 (abbreviation: ICBA).

Other examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of the p-type semiconductor material included in the active layer include electron-donating organic semiconductor materials such as copper (II) phthalocyanine (CuPc), tetraphenyldibenzoperiflanthene (DBP), zinc phthalocyanine (ZnPc), tin phthalocyanine (SnPc), and quinacridone.

Examples of the p-type semiconductor material include a carbazole derivative, a thiophene derivative, a furan derivative, and a compound having an aromatic amine skeleton. Other examples of the p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules having similar shapes tend to aggregate, and aggregated molecules of the same kind, which have molecular orbital energy levels close to each other, can increase the carrier-transport property.

For example, the active layer is preferably formed by co-evaporation of an n-type semiconductor and a p-type semiconductor. Alternatively, the active layer may be formed by stacking an n-type semiconductor and a p-type semiconductor.

In addition to the active layer, the light-receiving device may further include a layer containing a substance with a high hole-transport property, a substance with a high electron-transport property, a substance with a bipolar property (a substance with a high electron-transport property and a high hole-transport property), or the like. Without limitation to the above, a layer containing a substance with a high hole-injection property, a hole-blocking material, a material with a high electron-injection property, an electron-blocking material, or the like may be further included.

Either a low molecular compound or a high molecular compound can be used in the light-receiving device, and an inorganic compound may also be included. Each layer included in the light-receiving device can be formed by an evaporation method (including a vacuum evaporation method), a transfer method, a printing method, an inkjet method, a coating method, or the like.

As the hole-transport material or the electron-blocking material, a high molecular compound such as poly(3,4-ethylenedioxythiophene)/poly(styrenesulfonic acid) (PEDOT/PSS), or an inorganic compound such as a molybdenum oxide or copper iodide (CuI) can be used, for As the electron-transport material or the hole-blocking material, an inorganic example, compound such as zinc oxide (ZnO) or an organic compound such as polyethylenimine ethoxylate (PEIE) can be used. The light-receiving device may include a mixed film of PEIE and ZnO, for example.

For the active layer, a high molecular compound such as poly[[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

The active layer may contain a mixture of three or more kinds of materials. For example, a third material may be mixed with an n-type semiconductor material and a p-type semiconductor material in order to extend the wavelength range. The third material may be a low molecular compound or a high molecular compound.

The above is the description of the light-receiving device.

At least part of this embodiment can be implemented in combination with the other embodiments described in this specification as appropriate.

### Embodiment 8

In this embodiment, a structure example of a light-emitting apparatus or a display apparatus that can be used as the light-emitting and light-receiving apparatus of one embodiment of the present invention will be described.

One embodiment of the present invention is a display apparatus including a light-emitting apparatus (also referred to as a light-emitting device) and a light-receiving apparatus (also referred to as a light-receiving device). For example, three kinds of light-emitting apparatuses emitting light of red (R), green (G), and blue (B) are included, whereby a full-color display apparatus can be achieved.

In one embodiment of the present invention, patterning of EL layers and an EL layer and an active layer is performed by a photolithography method without a shadow mask such as a metal mask. This can achieve a display apparatus with high resolution and a high aperture ratio, which has been difficult to achieve. Moreover, EL layers can be separately formed, enabling the display apparatus to perform extremely clear display with high contrast and high display quality.

It is difficult to set the distance between EL layers for different colors or between an EL layer and an active layer to be less than 10 μm with a formation method using a metal mask, for example. By contrast, with use of the above method, the distance can be decreased to less than or equal to 3 μm, less than or equal to 2 μm, or less than or equal to 1 μm. For example, with use of an exposure apparatus for LSI, the distance can be decreased to be less than or equal to 500 nm, less than or equal to 200 nm, less than or equal to 100 nm, or less than or equal to 50 nm. Accordingly, the area of a non-light-emitting region that may exist between two light-emitting apparatuses or between a light-emitting apparatus and a light-receiving apparatus can be significantly reduced, and the aperture ratio can be close to 100%. For example, the aperture ratio higher than or equal to 50%, higher than or equal to 60%, higher than or equal to 70%, higher than or equal to 80%, or higher than or equal to 90% and lower than 100% can be achieved.

Furthermore, patterns of the EL layer and the active layer themselves can be made extremely smaller than those in the case of using a metal mask. For example, in the case of using a metal mask for forming EL layers separately, a variation in the thickness of the pattern occurs between the center and the edge of the pattern, causing a reduction in effective area that can be used for a light-emitting region with respect to the entire pattern area. In contrast, in the above manufacturing method, a pattern is formed by processing a film deposited to have a uniform thickness, which enables a uniform thickness in the pattern: thus, even with a fine pattern, almost the entire area can be used for a light-emitting region. Therefore, the above manufacturing method makes it possible to achieve both high resolution and a high aperture ratio.

In many cases, an organic film formed using an FMM (Fine Metal Mask) has an extremely small taper angle (e.g., a taper angle greater than 0° and less than 30°) so that the thickness of the film becomes smaller in a portion closer to an end portion. Therefore, it is difficult to clearly observe a side surface of an organic film formed using an FMM because the side surface and a top surface are continuously connected. In contrast, an EL layer included in one embodiment of the present invention is processed without using an FMM, and has a clear side surface. In particular, in one embodiment of the present invention, part of the EL layer preferably has a taper angle greater than or equal to 30° and less than or equal to 120°, further preferably greater than or equal to 60° and less than or equal to 120°.

Note that in this specification and the like, an end portion of an object having a tapered shape indicates that the end portion of the object has a cross-sectional shape in which the angle between a side surface (a surface) of the object and a surface on which the object is formed (a bottom surface) is greater than 0° and less than 90° in a region of the end portion, and the thickness continuously increases from the end portion. A taper angle refers to an angle between a bottom surface (a surface on which an object is formed) and a side surface (a surface) at an end portion of the object.

More specific examples are described below.

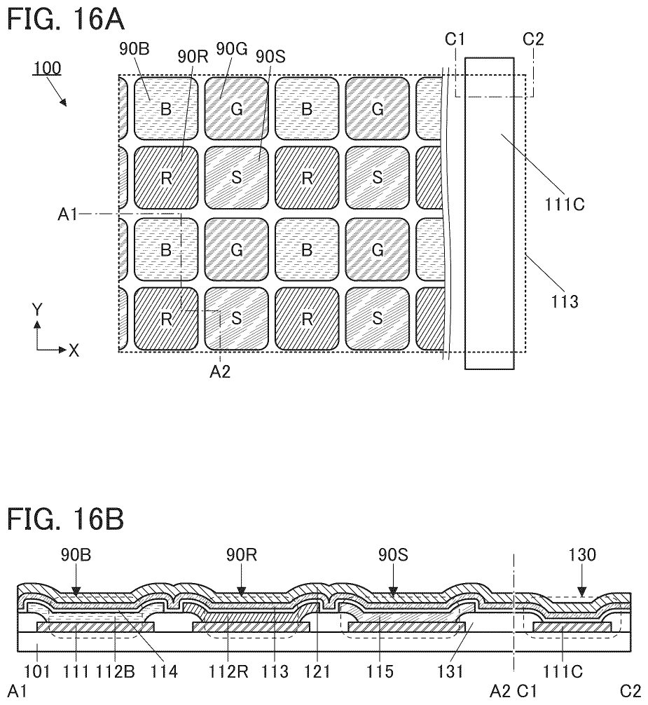

FIG. 16A is a schematic top view of the display region 100. The display region 100 includes a plurality of light-emitting apparatuses 90R emitting red light, a plurality of light-emitting apparatuses 90G emitting green light, a plurality of light-emitting apparatuses 90B emitting blue light, and a plurality of light-receiving apparatuses 90S. In FIG. 4A, light-emitting regions of the light-emitting apparatuses (and light-receiving regions of the light-receiving elements) are denoted by R, G, B, and S to easily differentiate the light-emitting apparatuses.

The light-emitting apparatuses 90R, the light-emitting apparatuses 90G, the light-emitting apparatuses 90B, and the light-receiving apparatuses 90S are arranged in a matrix. In FIG. 16A, two light-emitting apparatuses are alternately arranged in one direction. Note that the arrangement method of the light-emitting apparatuses is not limited thereto; another method such as a stripe, S stripe, delta, Bayer, zigzag, PenTile, or diamond arrangement may also be used.

FIG. 16A illustrates a connection electrode 111C that is electrically connected to a common electrode 113. The connection electrode 111C is supplied with a potential (e.g., an anode potential or a cathode potential) that is to be supplied to the common electrode 113. The connection electrode 111C is provided outside of a display region where the light-emitting apparatuses 90R and the like are arranged. In FIG. 16A, the common electrode 113 is illustrated by a dashed line.

The connection electrode 111C can be provided along the outer periphery of the display region. For example, the connection electrode 111C may be provided along one side of the outer periphery of the display region or two or more sides of the outer periphery of the display region. That is, in the case where the display region has a rectangular top surface, the top surface of the connection electrode 111C can have a band-like shape, an L shape, a square bracket shape, a quadrangular shape, or the like.

FIG. 16B is a schematic cross-sectional view taken along the dashed-dotted line A1-A2 and dashed-dotted line C1-C2 in FIG. 16A. FIG. 16B is a schematic cross-sectional view of the light-emitting apparatus 90B, the light-emitting apparatus 90R, the light-receiving apparatus 90S, and the connection electrode 111C.

Note that the light-emitting apparatus 90G that is not illustrated in the schematic cross-sectional view can have a structure similar to that of the light-emitting apparatus 90B or the light-emitting apparatus 90R. Hereinafter, the description of the light-emitting apparatus 90B or the light-emitting apparatus 90R can be referred to for the description of the light-emitting apparatus 90G.

The light-emitting apparatus 90B includes a pixel electrode 111, a material layer 112B, the material layer 114, and the common electrode 113. The light-emitting apparatus 90R includes a pixel electrode 111, a material layer 112R, a material layer 114, and a common electrode 113.

The light-receiving apparatus 90S includes the pixel electrode 111, a common electrode 115, the material layer 114, and the common electrode 113. The material layer 114 and the common electrode 113 are shared by the light-emitting apparatus 90B, the light-emitting apparatus 90R, and the light-receiving apparatus 90S. The material layer 114 can also be referred to as a common layer.

The material layer 112R contains at least a light-emitting organic compound that emits light with intensity in the red wavelength range. The material layer 112B contains at least a light-emitting organic compound that emits light with intensity in the blue wavelength range. The common electrode 115 includes a photoelectric conversion material that has sensitivity in the visible light or infrared light wavelength range. The material layer 112R and the material layer 112B can each be called an EL layer.

The material layer 112R, the material layer 112B, and the common electrode 115 may each include one or more of an electron-injection layer, an electron-transport layer, a hole-injection layer, and a hole-transport layer. The material layer 114 does not necessarily include the light-emitting layer. For example, the material layer 114 includes one or more of an electron-injection layer, an electron-transport layer, a hole-injection layer, and a hole-transport layer.

Here, the uppermost layer in the stacked-layer structure of each of the material layer 112R, the material layer 112B, and the common electrode 115, i.e., the layer in contact with the material layer 114, is preferably a layer other than the light-emitting layer. For example, a structure is preferable in which an electron-injection layer, an electron-transport layer, a hole-injection layer, a hole-transport layer, or a layer other than those is provided to cover the light-emitting layer so as to be in contact with the material layer 114. When the top surface of the light-emitting layer is protected by another layer in fabricating each light-emitting apparatus, the reliability of the light-emitting apparatus can be improved.

The pixel electrode 111 is provided in each of the light-emitting apparatuses. The common electrode 113 and the material layer 114 are each provided as a continuous layer shared by the light-emitting apparatuses. A conductive film having a transmitting property with respect to visible light is used for either the pixel electrodes or the common electrode 113, and a conductive film having a reflective property is used for the other. When the pixel electrodes have light-transmitting properties and the common electrode 113 has a reflective property, a bottom-emission display apparatus can be obtained: in contrast, when the pixel electrodes have reflective properties and the common electrode 113 has a light-transmitting property, a top-emission display apparatus can be obtained. Note that when both the pixel electrodes and the common electrode 113 have light-transmitting properties, a dual-emission display apparatus can be obtained.

An insulating layer 131 is provided to cover end portions of the pixel electrode 111. The end portions of the insulating layer 131 are preferably tapered. Note that in this specification and the like, an end portion of an object having a tapered shape indicates that the end portion of the object has a cross-sectional shape in which the angle between a surface of the object and a surface on which the object is formed is greater than 0° and less than 90° in a region of the end portion, and the thickness continuously increases from the end portion.

When an organic resin is used for the insulating layer 131, the surface can have a moderate curve. Thus, coverage with a film formed over the insulating layer 131 can be improved.

Examples of materials that can be used for the insulating layer 131 include an acrylic resin, a polyimide resin, an epoxy resin, a polyamide resin, a polyimide-amide resin, a siloxane resin, a benzocyclobutene-based resin, a phenol resin, and precursors and the like of these resins.

Note that for the insulating layer 131, an inorganic insulating material may be used. Examples of inorganic insulating materials that can be used for the insulating layer 131 include films of oxides and nitrides such as silicon oxide, silicon oxynitride, silicon nitride oxide, silicon nitride, aluminum oxide, aluminum oxynitride, and hafnium oxide. In addition, yttrium oxide, zirconium oxide, gallium oxide, tantalum oxide, magnesium oxide, lanthanum oxide, cerium oxide, neodymium oxide, or the like may be used.

As illustrated in FIG. 16B, a space is provided between the two material layers (also referred to as organic material layers) in the light-emitting apparatuses of different colors and the light-emitting apparatus and the light-receiving apparatus. In this manner, the material layers 112R, the material layers 112B, and the common electrode 115 are preferably provided so as not to be in contact with one another. This can suitably prevent unintentional light emission due to current flow through two adjacent material layers. As a result, the contrast can be increased to achieve a display apparatus with high display quality.

The material layers 112R, 112B, and the common electrode 115 each preferably have a taper angle of greater than or equal to 30°. In an end portion of each of the material layer 112R, the material layer 112G, and the material layer 112B, the angle between a side surface (a surface) and a bottom surface (a surface on which the layer is formed) is preferably greater than or equal to 30° and less than or equal to 120°, further preferably greater than or equal to 45° and less than or equal to 120°, still further preferably greater than or equal to 60° and less than or equal to 120°. Alternatively, the material layers 112R, 112G, and 112B each preferably have a taper angle of 90° or a neighborhood thereof (greater than or equal to 80° and less than or equal to 100°, for example).

A protective layer 121 is provided over the common electrode 113. The protective layer 121 has a function of inhibiting diffusion of impurities such as water into the light-emitting apparatuses from above.

The protective layer 121 can have, for example, a single-layer structure or a stacked-layer structure at least including an inorganic insulating film. For the inorganic insulating film, for example, an oxide film or a nitride film such as a silicon oxide film, a silicon oxynitride film, a silicon nitride oxide film, a silicon nitride film, an aluminum oxide film, an aluminum oxynitride film, or a hafnium oxide film can be given. Alternatively, a semiconductor material such as indium gallium oxide or indium gallium zinc oxide may be used for the protective layer 121.

As the protective layer 121, a stacked-layer film of an inorganic insulating film and an organic insulating film can be used. For example, a structure in which an organic insulating film is sandwiched between a pair of inorganic insulating films is preferable. Furthermore, the organic insulating film preferably functions as a planarization film. This enables the top surface of the organic insulating film to be flat, and accordingly, coverage with the inorganic insulating film thereover is improved, which leads to an improvement in barrier properties. Moreover, the top surface of the protective layer 121 is flat, which is preferable because the influence of an unevenness shape due to a lower structure can be reduced in the case where a component (e.g., a color filter, an electrode of a touch sensor, a lens array, or the like) is provided above the protective layer 121.

In the connection portion 130, the common electrode 113 is provided over and in contact with the connection electrode 111C and the protective layer 121 is provided to cover the common electrode 113. In addition, the insulating layer 131 is provided to cover end portions of the connection electrode 111C.

A structure example of a display apparatus whose structure is partly different from that of FIG. 16B is described below. Specifically, an example in which the insulating layer 131 is not provided is described.

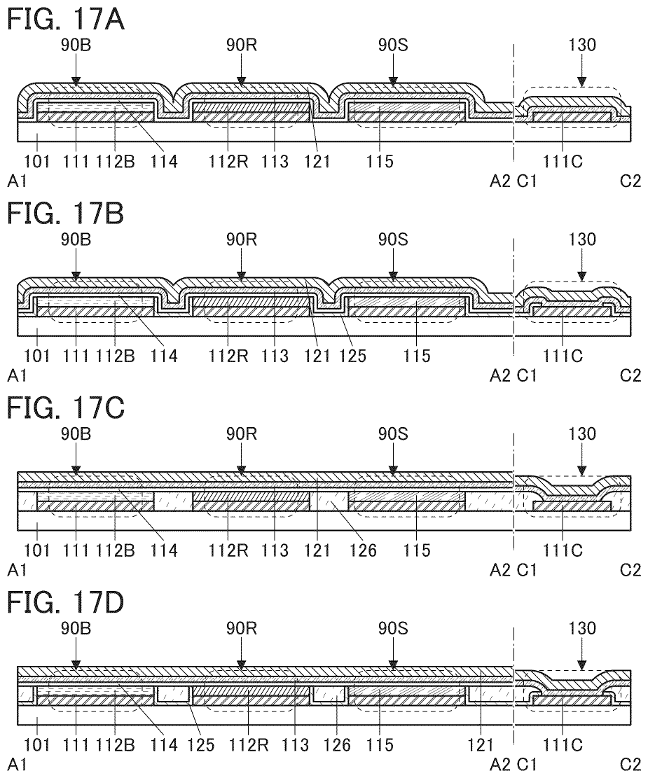

FIG. 17A to 17C illustrate the case where the side surfaces of the pixel electrode 111 are substantially aligned with the side surfaces of the material layer 112R, the material layer 112B, and the common electrode 115.

In FIG. 17A, the organic layer 114 is provided to cover top surfaces and side surfaces of the organic layer 112R, the organic layer 112B, and the common electrode 115. The material layer 114 can prevent the pixel electrode 111 and the common electrode 113 from being in contact with each other and being electrically short-circuited.

FIG. 17B illustrates an example in which an insulating layer 125 is provided to be in contact with the side surfaces of the material layer 112R, the material layer 112G, and the material layer 112B and side surfaces of the pixel electrode 111. The insulating layer 125 can prevent the pixel electrode 111 and the common electrode 113 from being electrically short-circuited and effectively inhibit leakage current therebetween.

The insulating layer 125 can be an insulating layer containing an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. Specifically, when an inorganic insulating film such as an aluminum oxide film, a hafnium oxide film, or a silicon oxide film formed by an ALD method is used for the insulating layer 125, the insulating layer 125 formed can have a small number of pin holes and excel in a function of protecting the organic material layer.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

The insulating layer 125 can be formed by a sputtering method, a CVD method, a PLD method, an ALD method, or the like. The insulating layer 125 is preferably formed by an ALD method achieving good coverage.

In FIG. 17C, a resin layer 126 is provided between two adjacent light-emitting apparatuses or between the light-emitting apparatus and the light-receiving apparatus so as to fill the space between two facing pixel electrodes and two facing material layers. The resin layer 126 can planarize the surface on which the material layer 114, the common electrode 113, and the like are formed, which prevents disconnection of the common electrode 113 due to poor coverage in a step between adjacent light-emitting apparatuses.

An insulating layer containing an organic material can be suitably used as the resin layer 126. As the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like can be used, for example. For the resin layer 126, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used. A photosensitive resin can also be used for the resin layer 126. A photoresist may be used for the photosensitive resin. As the photosensitive resin, a positive photosensitive material or a negative photosensitive material can be used. A colored material (e.g., a material containing a black pigment) may be used for the resin layer 126 to add the function of blocking stray light from an adjacent pixel and inhibiting color mixture.

In FIG. 17D, the insulating layer 125 and the resin layer 126 over the insulating layer 125 are provided. Since the insulating layer 125 prevents the material layer 112R or the like from being in contact with the resin layer 126, impurities such as moisture included in the resin layer 126 can be prevented from being diffused into the material layer 112R or the like, whereby a highly reliable display apparatus can be provided.

A reflective film (e.g., a metal film containing one or more of silver, palladium, copper, titanium, aluminum, and the like) may be provided between the insulating layer 125 and the resin layer 126 so that light emitted from the light-emitting layer can be reflected by the reflective film to increase light extraction efficiency.

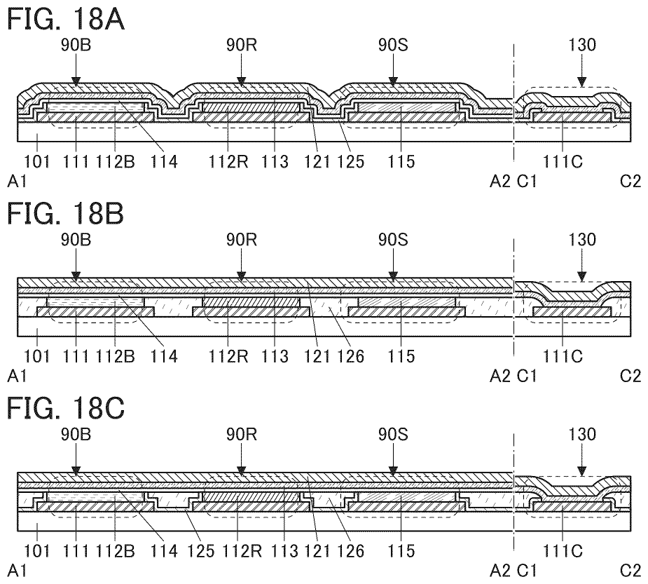

FIG. 18A to FIG. 18C each illustrate an example in which the width of the pixel electrode 111 is larger than the width of the material layer 112R, the material layer 112B, or the common electrode 115. The material layer 112R or the like is positioned inward from end portions of the pixel electrode 111.

FIG. 18A illustrates an example in which the insulating layer 125 is provided. The insulating layer 125 is provided to cover the side surfaces of the material layers included in the light-emitting apparatus and the light-receiving apparatus and part of a top surface and the side surfaces of the pixel electrode 111.

FIG. 18B illustrates an example in which the resin layer 126 is provided. The resin layer 126 is positioned between two adjacent light-emitting apparatuses or between the light-emitting apparatus and the light-receiving apparatus, and covers the side surfaces of the material layers and the top and side surfaces of the pixel electrode 111.

FIG. 18C illustrates an example in which both the insulating layer 125 and the resin layer 126 are provided. The insulating layer 125 is provided between the material layer 112R or the like and the resin layer 126.

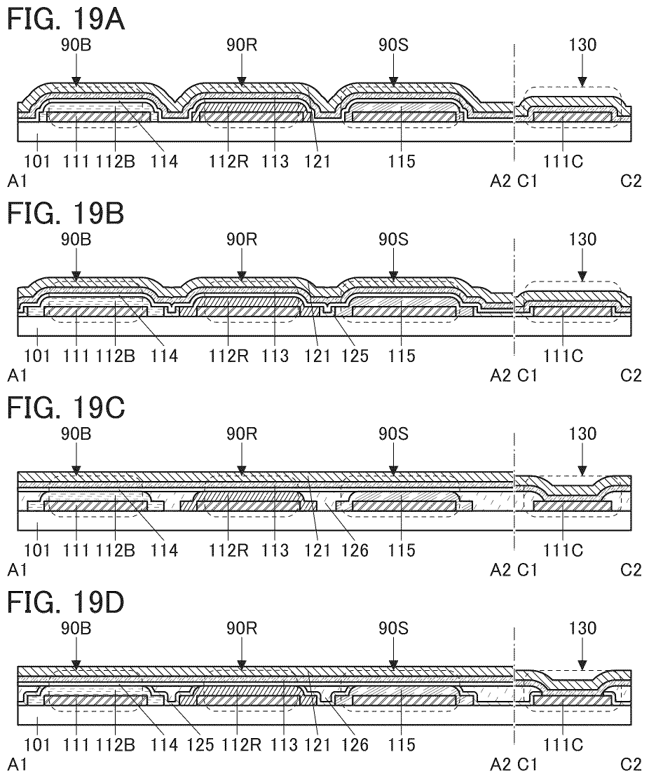

FIG. 19A to FIG. 19D each illustrate an example in which the width of the pixel electrode 111 is smaller than the width of the material layer 112R, the material layer 112B, or the common electrode 115. The material layer 112R or the like extends to an outer side beyond the end portions of the pixel electrode 111.

FIG. 19B illustrates an example in which the insulating layer 125 is provided. The insulating layer 125 is provided in contact with the side surfaces of the material layers of two adjacent light-emitting apparatuses. The insulating layer 125 may be provided to cover not only the side surface but also part of a top surface of the material layer 112R or the like.

FIG. 19C illustrates an example in which the resin layer 126 is provided. The resin layer 126 is positioned between two adjacent light-emitting apparatuses and covers the side surface and part of the top surface of the material layer 112R or the like. The resin layer 126 may be formed to be in contact with the side surface of the material layer 112R or the like and not to cover the top surface thereof.

FIG. 19D illustrates an example in which both the insulating layer 125 and the resin layer 126 are provided. The insulating layer 125 is provided between the material layer 112R or the like and the resin layer 126.

Here, a structure example of the resin layer 126 is described.

A top surface of the resin layer 126 is preferably as flat as possible: however, the surface of the resin layer 126 may be concave or convex depending on an uneven shape of a surface on which the resin layer 126 is formed, the formation conditions of the resin layer 126, or the like.

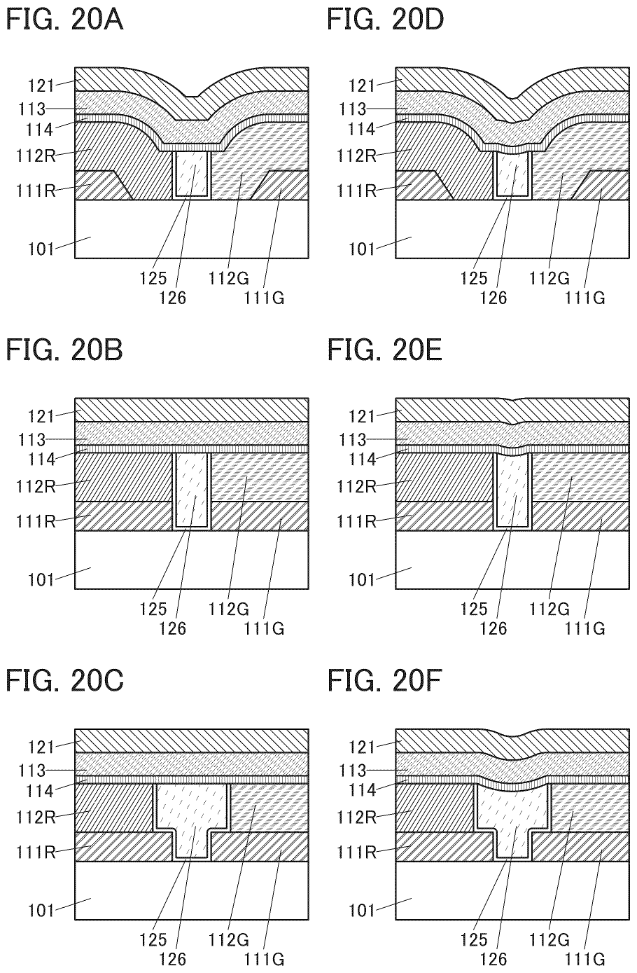

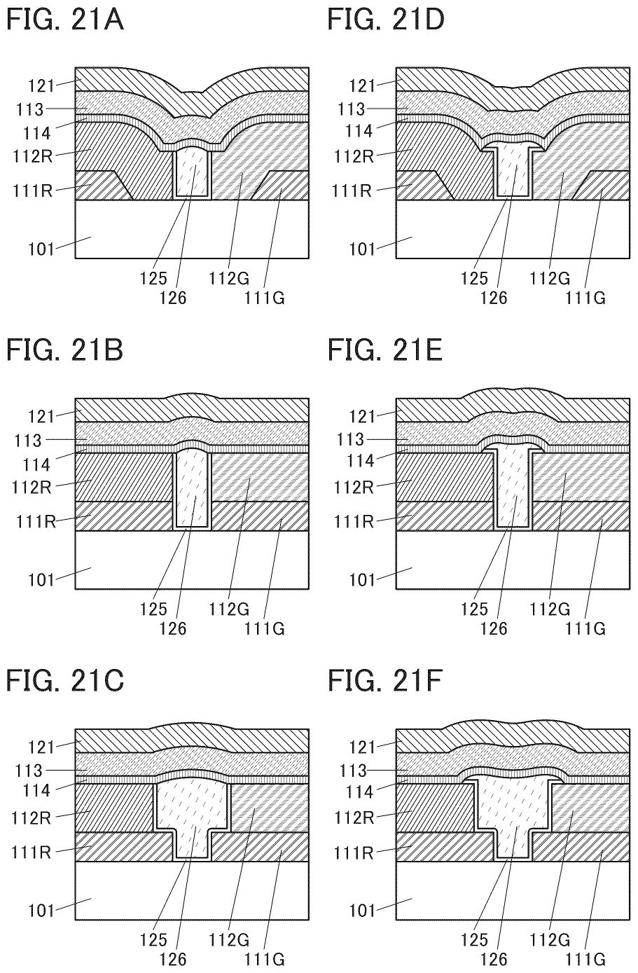

FIG. 20A to FIG. 21F are each an enlarged view of an end portion of the pixel electrode 111R included in the light-emitting apparatus 90R, an end portion of the pixel electrode 111G included in the light-emitting apparatus 90G, and the vicinity thereof. The material layer 112G is provided over the pixel electrode 111G.

FIG. 20A, FIG. 20B, and FIG. 20C are each an enlarged view of the resin layer 126 having a flat top surface and the vicinity thereof. FIG. 20A illustrates an example of the case where the width of the material layer 112R or the like is larger than the width of the pixel electrode 111. FIG. 20B illustrates an example in which the widths are substantially the same. FIG. 20C illustrates an example of the case where the width of the material layer 112R or the like is smaller than the width of the pixel electrode 111.

The material layer 112R is provided to cover the end portions of the pixel electrode 111 as illustrated in FIG. 20A, so that the end portion of the pixel electrode 111 is preferably tapered. Accordingly, the step coverage with the material layer 112R is improved and a highly reliable display apparatus can be provided.

FIG. 20D, FIG. 20E, and FIG. 20F each illustrate an example of the case where a top surface of the resin layer 126 is concave. In this case, a concave portion that reflects the concave top surface of the resin layer 126 is formed on each of top surfaces of the material layer 114, the common electrode 113, and the protective layer 121.

FIG. 21A, FIG. 21B, and FIG. 21C each illustrate an example of the case where a top surface of the resin layer 126 is convex. In this case, a convex portion that reflects the convex top surface of the resin layer 126 is formed on each of top surfaces of the material layer 114, the common electrode 113, and the protective layer 121.

FIG. 21D, FIG. 21E, and FIG. 21F each illustrate an example of the case where part of the resin layer 126 covers an upper end portion and part of a top surface of the material layer 112R and an upper end portion and part of a top surface of the material layer 112G. In this case, an insulating layer 125 is provided between the resin layer 126 and the top surface of the material layer 112R or the material layer 112G.

FIG. 21D, FIG. 21E, and FIG. 21F each illustrate an example of the case where a top surface of the resin layer 126 is partly concave. In this case, an unevenness shape that reflects the shape of the resin layer 126 is formed on each of top surfaces of the material layer 114, the common electrode 113, and the protective layer 121.

The above is the description of the structure examples of the resin layer.

At least part of this embodiment can be implemented in combination with the other embodiments described in this specification as appropriate.

### Embodiment 9

In this embodiment, a structure example of a display apparatus that can be used as a light-emitting and light-receiving apparatus of one embodiment of the present invention will be described. Although the display apparatus is described here as a display apparatus capable of displaying an image, the display apparatus can be used as a light-emitting and light-receiving apparatus by using a light-emitting apparatus as a light source.

The display apparatus in this embodiment can be a high-definition display apparatus or a large-sized display apparatus. Accordingly, the display apparatus of this embodiment can be used in, for example, display portions of a digital camera, a digital video camera, a digital photo frame, a mobile phone, a portable game console, a smart phone, a wristwatch terminal, a tablet terminal, a portable information terminal, and an audio reproducing device, in addition to display portions of electronic devices with a relatively large screen, such as a television device, a desktop or notebook personal computer, a monitor of a computer or the like, digital signage, and a large game machine such as a pachinko machine.

### [Display Apparatus 400]

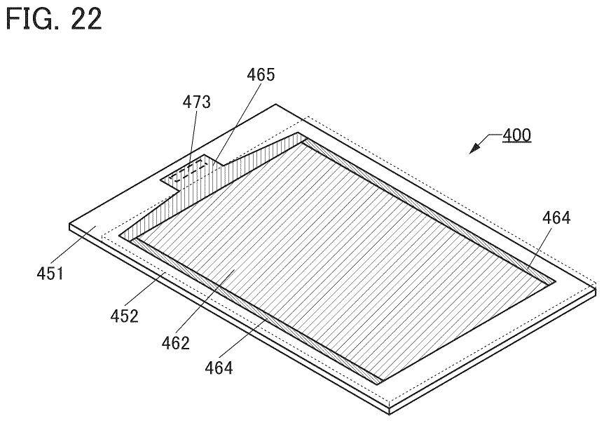

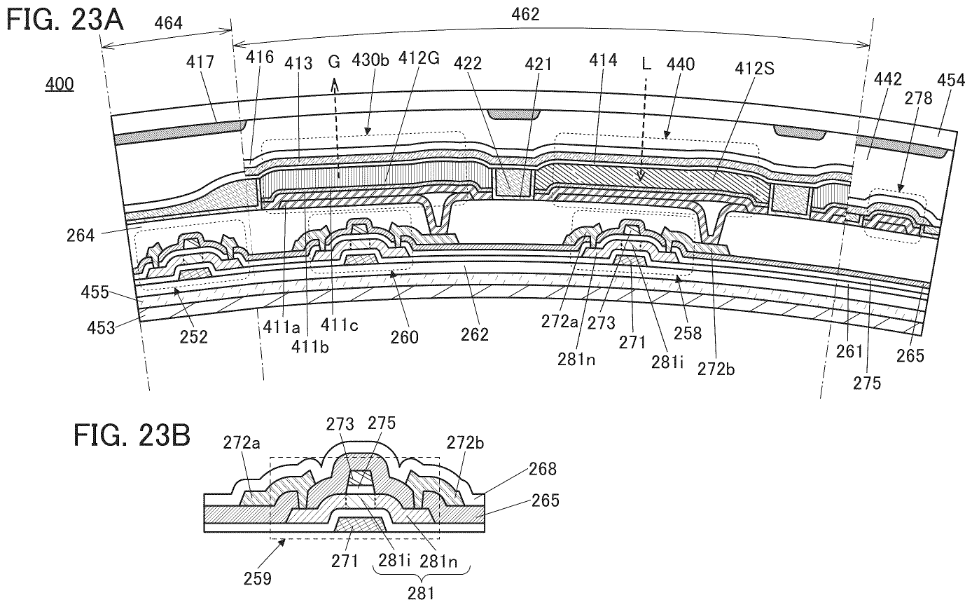

FIG. 22 is a perspective view of a display apparatus 400, and FIG. 23A is a cross-sectional view of the display apparatus 400.

The display apparatus 400 has a structure in which a substrate 452 and a substrate 451 are bonded to each other. In FIG. 22, the substrate 452 is denoted by a dashed line.

The display apparatus 400 includes a display portion 462, a circuit 464, a wiring 465, and the like. FIG. 22 shows an example in which the display apparatus 400 is provided with an electrode 473. Thus, the structure illustrated in FIG. 23 can be regarded as a display module including the display apparatus 400. The electrode 473 can also be referred to as a through electrode that is connected through an opening formed in the substrate 451 to a wiring layer over a support body. In addition, an integrated circuit (IC) such as a driver circuit may be connected to the electrode 473.

As the circuit 464, a scan line driver circuit can be used, for example.

In the case where a signal and power are supplied to the display portion 462 and the circuit 464, the signal and power are input to various wirings from the outside through the wiring layer or the electrode formed over the support body in Embodiment 1.

FIG. 23A illustrates an example of cross sections of part of the circuit 464, part of the display portion 462, and part of a region including a connection portion of the display apparatus 400. FIG. 23A specifically illustrates an example of a cross section of a region including a light-emitting apparatus 430b emitting green light (G) and a light-receiving apparatus 440 receiving reflected light (L) in the display portion 462.

The display apparatus 400 illustrated in FIG. 23A includes a transistor 252, a transistor 260, a transistor 258, the light-emitting apparatus 430b, the light-emitting apparatus 440, and the like between a substrate 453 and a substrate 454.

The light-emitting apparatus and the light-receiving apparatus that are described above as examples can be applied to the light-emitting apparatus 430b and the light-receiving apparatus 440, respectively.

Here, in the case where the pixel of the display apparatus includes three kinds of subpixels including light-emitting apparatuses that emit light of different colors, as the three subpixels, subpixels of three colors of red (R), green (G), and blue (B), subpixels of three colors of yellow (Y), cyan (C), and magenta (M), and the like can be given. In the case where four subpixels are included, the four subpixels can be subpixels of four colors of R, G, B, and white (W) or subpixels of four colors of R, G, B, and Y, for example. Alternatively, the subpixel may include a light-emitting apparatus emitting infrared light.

As the light-receiving apparatus 440, a photoelectric conversion element having sensitivity to light in a red, green, or blue wavelength range or a photoelectric conversion element having sensitivity to light in an infrared wavelength range can be used.

The substrate 454 and the protective layer 416 are bonded to each other with the adhesive layer 442. The adhesive layer 442 is provided to overlap with the light-emitting apparatus 430b and the light-receiving apparatus 440, and the display apparatus 400 employs a solid sealing structure. The substrate 454 is provided with a light-blocking layer 417.

The light-emitting apparatus 430b and the light-receiving apparatus 440 each include a conductive layer 411a, a conductive layer 411b, and a conductive layer 411c as pixel electrodes. The conductive layer 411b has a property of reflecting visible light and functions as a reflective electrode. The conductive layer 411c has a property of transmitting visible light and functions as an optical adjustment layer.

The conductive layer 411a included in the light-emitting apparatus 430b is connected to a conductive layer 272b included in the transistor 260 through an opening provided in an insulating layer 264. The transistor 260 has a function of controlling the driving of the light-emitting apparatus. The conductive layer 41 la included in the light-receiving apparatus 440 is electrically connected to the conductive layer 272b included in the transistor 258. The transistor 258 has a function of controlling, for example, the timing of light exposure using the light-receiving apparatus 440.

An EL layer 412G or a photoelectric conversion layer 412S is provided to cover the pixel electrode. An insulating layer 421 is provided in contact with a side surface of the EL layer 412G and a side surface of the photoelectric conversion layer 412S, and a resin layer 422 is provided to fill a concave portion of the insulating layer 421. An organic material layer 414, a common electrode 413, and the protective layer 416 are provided to cover the EL layer 412G and the photoelectric conversion layer 412S. Providing the protective layer 416 that covers the light-emitting apparatus can inhibit entry of impurities such as water into the light-emitting apparatus, thereby increasing the reliability of the light-emitting apparatus.

Light G emitted from the light-emitting apparatus 430b is emitted toward the substrate 454. The light-receiving apparatus 440 receives light L incident through the substrate 454 and converts the light L into an electric signal. For the substrate 454, a material having a high property of transmitting visible light is preferably used.

The transistor 252, the transistor 260, and the transistor 258 are all formed over the substrate 453. These transistors can be formed using the same material in the same step.

Note that the transistor 252, the transistor 260, and the transistor 258 may be separately formed to have different structures. For example, a transistor having a back gate and a transistor not having a back gate may be formed separately, or transistors whose semiconductors, gate electrodes, gate insulating layers, source electrodes, and drain electrodes are formed of different materials and/or have different thicknesses may be formed separately.

The substrate 453 and an insulating layer 262 are bonded to each other with an adhesive layer 455.

In a manufacturing method of the display apparatus 400, first, a formation substrate provided with the insulating layer 262, the transistors, the light-emitting apparatuses, and the light-receiving apparatuses is bonded to the substrate 454 provided with the light-blocking layer 417 with the adhesive layer 442. Then, the substrate 453 is bonded to a surface exposed by separation of the formation substrate, whereby the components formed over the formation substrate are transferred to the substrate 453. The substrate 453 and the substrate 454 are preferably flexible. This can increase the flexibility of the display apparatus 400.

The transistor 252, the transistor 260, and the transistor 258 each include a conductive layer 271 functioning as a gate, an insulating layer 261 functioning as a gate insulating layer, a semiconductor layer 281 including a channel formation region 281i and a pair of low-resistance regions 281n, a conductive layer 272a connected to one of the pair of low-resistance regions 281n, the conductive layer 272b connected to the other of the pair of low-resistance regions 281n, an insulating layer 275 functioning as a gate insulating layer, a conductive layer 273 functioning as a gate, and an insulating layer 265 covering the conductive layer 273. The insulating layer 261 is positioned between the conductive layer 271 and the channel formation region 281i. The insulating layer 275 is positioned between the conductive layer 273 and the channel formation region 281i.

The conductive layer 272a and the conductive layer 272b are connected to the corresponding low-resistance regions 281n through openings provided in the insulating layer 265. One of the conductive layer 272a and the conductive layer 272b functions as a source, and the other functions as a drain.

FIG. 23A illustrates an example in which the insulating layer 275 covers a top surface and a side surface of the semiconductor layer. The conductive layer 272a and the conductive layer 272b are connected to the corresponding low-resistance regions 281n through openings provided in the insulating layer 275 and the insulating layer 265.

In a transistor 259 illustrated in FIG. 23B, the insulating layer 275 overlaps with the channel formation region 281i of the semiconductor layer 281 and does not overlap with the low-resistance regions 281n. The structure illustrated in FIG. 23B can be obtained by processing the insulating layer 275 using the conductive layer 273 as a mask, for example. In FIG. 23B, the insulating layer 265 is provided to cover the insulating layer 275 and the conductive layer 273, and the conductive layer 272a and the conductive layer 272b are connected to the low-resistance regions 281n through the openings in the insulating layer 265. Furthermore, an insulating layer 268 covering the transistor may be provided.

There is no particular limitation on the structures of the transistors included in the display apparatus of this embodiment. For example, a planar transistor, a staggered transistor, or an inverted staggered transistor can be used. In addition, the transistor structure may be either a top-gate structure or a bottom-gate structure. Alternatively, gates may be provided above and below a semiconductor layer in which a channel is formed.

The structure in which the semiconductor layer where a channel is formed is provided between two gates is used for the transistor 252, the transistor 260, and the transistor 258. The two gates may be connected to each other and supplied with the same signal to drive the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor material used for the semiconductor layer of the transistor, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case deterioration of the transistor characteristics can be inhibited.

The semiconductor layer of the transistor preferably includes a metal oxide (also referred to as an oxide semiconductor). That is, a transistor including a metal oxide in its channel formation region (hereinafter, also referred to as an OS transistor) is preferably used for the display apparatus of this embodiment.

The band gap of a metal oxide used for the semiconductor layer of the transistor is preferably 2 eV or more, further preferably 2.5 eV or more. With the use of a metal oxide having a wide bandgap, the off-state current of the OS transistor can be reduced.

Alternatively, the semiconductor layer of the transistor may contain silicon. Examples of silicon include amorphous silicon and crystalline silicon (e.g., low-temperature polysilicon or single crystal silicon).

In particular, low-temperature polysilicon has relatively high mobility and can be formed over a glass substrate, and thus can be suitably used in a display apparatus. For example, a transistor in which low-temperature polysilicon is used in a semiconductor layer can be used as the transistor 252 or the like included in the driver circuit, and a transistor in which an oxide semiconductor is used in a semiconductor layer can be used as the transistor 260, the transistor 258, or the like provided for the pixel.

Alternatively, a semiconductor layer of a transistor may include a layered substance that functions as a semiconductor. The layered substance is a general term of a group of materials having a layered crystal structure. In the layered crystal structure, layers formed by covalent bonding or ionic bonding are stacked with bonding such as the Van der Waals force, which is weaker than covalent bonding or ionic bonding. The layered substance has high electrical conductivity in a monolayer, that is, high two-dimensional electrical conductivity. When a material functioning as a semiconductor and having high two-dimensional electrical conductivity is used for a channel formation region, a transistor having a high on-state current can be provided.

Examples of the layered substances include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

The transistor included in the circuit 464 and the transistor included in the display portion 462 may have the same structure or different structures. A plurality of transistors included in the circuit 464 may have the same structure or two or more kinds of structures. Similarly, a plurality of transistors included in the display portion 462 may have the same structure or two or more kinds of structures.

A material through which impurities such as water and hydrogen do not easily diffuse is preferably used for at least one of the insulating layers covering the transistors. Thus, such an insulating layer can function as a barrier layer. Such a structure can effectively inhibit diffusion of impurities into the transistors from the outside and increase the reliability of the display apparatus.

An inorganic insulating film is preferably used as each of the insulating layer 261, the insulating layer 262, the insulating layer 265, the insulating layer 268, and the insulating layer 275. As the inorganic insulating film, a silicon nitride film, a silicon oxynitride film, a silicon oxide film, a silicon nitride oxide film, an aluminum oxide film, an aluminum nitride film, or the like can be used, for example. Alternatively, a hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above inorganic insulating films may also be used.

Here, an organic insulating film often has a lower barrier property than an inorganic insulating film. Therefore, the organic insulating film preferably has an opening in the vicinity of an end portion of the display apparatus 400. This can inhibit entry of impurities from the end portion of the display apparatus 400 through the organic insulating film. Alternatively, the organic insulating film may be formed so that an end portion of the organic insulating film is positioned on the inner side compared to the end portion of the display apparatus 400, to prevent the organic insulating film from being exposed at the end portion of the display apparatus 400.

An organic insulating film is suitable for the insulating layer 264 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins.

A light-blocking layer 417 is preferably provided on a surface of the substrate 454 on the substrate 453 side. A variety of optical members can be arranged on the outer side of the substrate 454. Examples of the optical members include a polarizing plate, a retardation plate, a light diffusion layer (a diffusion film or the like), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided on the outer side of the substrate 454.

FIG. 23A illustrates a connection portion 278. In the connection portion 278, the common electrode 413 is electrically connected to a wiring. FIG. 23A illustrates an example in which the wiring has the same stacked-layer structure as the pixel electrode.

For each of the substrate 453 and the substrate 454, glass, quartz, ceramics, sapphire, a resin, a metal, an alloy, a semiconductor, or the like can be used. The substrate on the side where light from the light-emitting apparatus is extracted is formed using a material that transmits the light. When the substrate 453 and the substrate 454 are formed using a flexible material, the flexibility of the display apparatus can be increased. Furthermore, a polarizing plate may be used as the substrate 453 or the substrate 454.

For each of the substrate 453 and the substrate 454, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example. Glass that is thin enough to have flexibility may be used for one or both of the substrate 453 and the substrate 454.

In the case where a circularly polarizing plate overlaps with the display apparatus, a highly optically isotropic substrate is preferably used as the substrate included in the display apparatus. A highly optically isotropic substrate has a low birefringence (that can also be referred to as a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of the film having high optical isotropy include a triacetyl cellulose (TAC, also referred to as cellulose triacetate) film, a cycloolefin polymer (COP) film, a cycloolefin copolymer (COC) film, and an acrylic resin film.

When a film is used for the substrate and the film absorbs water, the shape of the display panel might be changed, e.g., creases are generated. Thus, for the substrate, a film with a low water absorption rate is preferably used. For example, a film with a water absorption rate lower than or equal to 1% is preferably used, a film with a water absorption rate lower than or equal to 0.1% is further preferably used, or a film with a water absorption rate lower than or equal to 0.01% is still further preferably used.

As the adhesive layer, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-liquid-mixture-type resin may be used. An adhesive sheet or the like may be used.

As the connection layer, an anisotropic conductive film (ACF), an anisotropic conductive paste (ACP), or the like can be used.

As materials for the gates, the source, and the drain of a transistor and conductive layers such as a variety of wirings and electrodes included in the display apparatus, any of metals such as aluminum, titanium, chromium, nickel, copper, yttrium, zirconium, molybdenum, silver, tantalum, and tungsten, or an alloy containing any of these metals as its main component can be used, for example. A film containing any of these materials can be used in a single layer or as a stacked-layer structure.

As a light-transmitting conductive material, a conductive oxide such as indium oxide, indium tin oxide, indium zinc oxide, zinc oxide, or zinc oxide containing gallium, or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. A nitride of the metal material (e.g., titanium nitride) or the like may also be used. Note that in the case of using the metal material or the alloy material (or the nitride thereof), the material is made thin enough to have a light-transmitting property. Furthermore, a stacked-layer film of the above materials can be used for a conductive layer.

Examples of insulating materials that can be used for the insulating layers include a resin such as an acrylic resin or an epoxy resin, and an inorganic insulating material such as silicon oxide, silicon oxynitride, silicon nitride oxide, silicon nitride, or aluminum oxide.

At least part of the structure examples, the drawings corresponding thereto, and the like illustrated in this embodiment can be combined with the other structure examples, the other drawings, and the like as appropriate.

At least part of this embodiment can be implemented in combination with the other embodiments described in this specification as appropriate.

### Embodiment 10

In this embodiment, an example of a display apparatus including a light-receiving device or the like of one embodiment of the present invention will be described.

In the display apparatus of this embodiment, a pixel can include a plurality of types of subpixels including light-emitting apparatuses that emit light of different colors. For example, the pixel can include three kinds of subpixels. As the three subpixels, subpixels of three colors of red (R), green (G), and blue (B) and subpixels of three colors of yellow (Y), cyan (C), and magenta (M) can be given, for example. Alternatively, the pixel can include four kinds of subpixels. As the four subpixels, subpixels of four colors of R, G, B, and white (W) and subpixels of four colors of R, G, B, and Y can be given, for example.

There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and PenTile arrangement.

Examples of a top surface shape of the subpixel include polygons such as a triangle, a tetragon (including a rectangle and a square), and a pentagon: polygons with rounded corners; an ellipse: or a circle. The top surface shape of a subpixel herein refers to a top surface shape of a light-emitting region of a light-emitting apparatus.

In the display apparatus including the light-emitting apparatus and the light-receiving device in the pixel, the pixel has a light-receiving function, which enables detection of touch or approach of an object while an image is displayed. For example, all the subpixels included in the display apparatus can display an image: alternatively, some subpixels can emit light as a light source and the other subpixels can display an image.

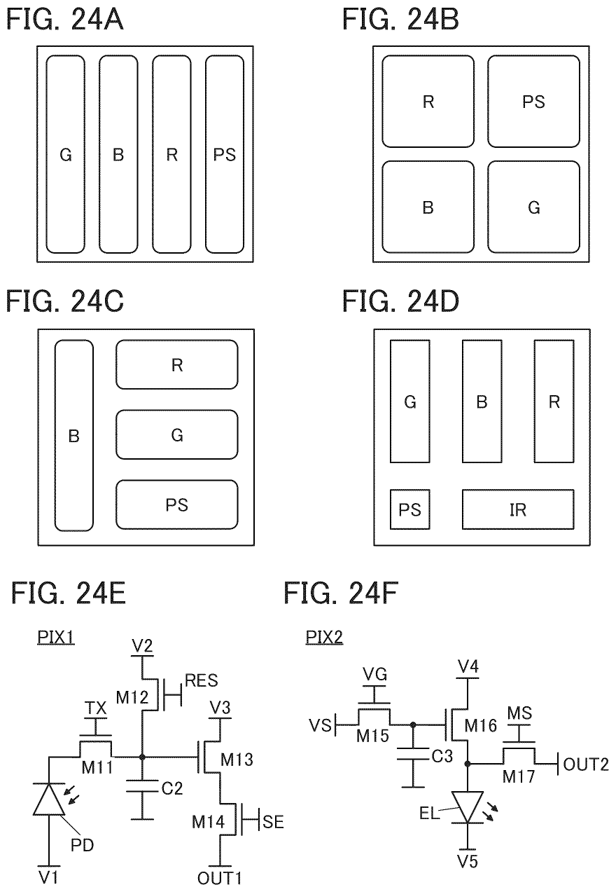

Pixels illustrated in FIG. 24A, FIG. 24B, and FIG. 24C each include a subpixel G, a subpixel B, a subpixel R, and a subpixel PS.

The pixel illustrated in FIG. 24A employs stripe arrangement. The pixel illustrated in FIG. 24B employs matrix arrangement.

The pixel arrangement illustrated in FIG. 24C has a structure in which three subpixels (the subpixel R, the subpixel G, and the subpixel PS) are vertically arranged next to one subpixel (the subpixel B).

The pixel illustrated in FIG. 24D includes the subpixel G, the subpixel B, the subpixel R, a subpixel IR, and the subpixel PS.

FIG. 24D illustrates an example in which one pixel is provided in two rows. Three subpixels (the subpixel G, the subpixel B, and the subpixel R) are provided in the upper row (first row), and two subpixels (one subpixel PS and one subpixel IR) are provided in the lower row (second row).

Note that the layout of the subpixels is not limited to the structures illustrated in FIG. 24A to FIG. 24D.

The subpixel R includes a light-emitting apparatus that emits red light. The subpixel G includes a light-emitting apparatus that emits green light. The subpixel B includes a light-emitting apparatus that emits blue light. The subpixel IR includes a light-emitting apparatus that emits infrared light. The subpixel PS includes a light-receiving device. Although the wavelength of light detected by the subpixel PS is not particularly limited, the light-receiving apparatus included in the subpixel PS preferably has sensitivity to light emitted from the light-emitting apparatus included in the subpixel R, the subpixel G, the subpixel B, or the subpixel IR. The light-receiving device preferably detects one or more of light in blue, violet, bluish violet, green, yellow green, yellow, orange, red, and infrared wavelength ranges, for example.

The light-receiving area of the subpixel PS is smaller than the light-emitting area of each of the other subpixels. A smaller light-receiving area leads to a narrower image-capturing range, inhibits a blur in a captured image, and improves the definition. Thus, the use of the subpixel PS enables high-resolution or high-definition image capturing. For example, image capturing for personal authentication with the use of a fingerprint, a palm print, the iris, the shape of a blood vessel (including the shape of a vein and the shape of an artery), or a face is possible by using the subpixel PS.

Moreover, the subpixel PS can be used in a touch sensor (also referred to as a direct touch sensor) or a near touch sensor (also referred to as a hover sensor, a hover touch sensor, a contactless sensor, a touchless sensor, or the like). For example, the subpixel PS preferably detects infrared light. Thus, a touch can be detected even in a dark place.

Here, a touch sensor or a near touch sensor can detect an approach or contact of an object (e.g., a finger, a hand, or a pen). The touch sensor can detect the object when the display apparatus and the object come in direct contact with each other. Furthermore, even when an object is not in contact with the display apparatus, the near touch sensor can detect the object. For example, the display apparatus is preferably capable of detecting an object positioned in the range of 0.1 mm to 300 mm inclusive, further preferably 3 mm to 50 mm inclusive from the display apparatus. This structure enables the display apparatus to be operated without direct contact of an object. With the above-described structure, the display apparatus can have a reduced risk of being dirty or damaged, or can be operated without the object directly touching a dirt (e.g., dust or a virus) attached to the display apparatus.

Note that the non-contact sensor function can also be referred to as a hover sensor function, a hover touch sensor function, a near-touch sensor function, a touchless sensor function, or the like. The touch sensor function can also be referred to as a direct touch sensor function or the like.

The refresh rate of the display apparatus of one embodiment of the present invention can be variable. For example, the refresh rate is adjusted (adjusted in the range from 0.01 Hz to 240 Hz, for example) in accordance with contents displayed on the display apparatus, whereby power consumption can be reduced. Moreover, driving with a lowered refresh rate that reduces the power consumption of the display apparatus may be referred to as idling stop (IDS) driving.

The driving frequency of the touch sensor or the near touch sensor may be changed in accordance with the above refresh rate. In the case where the refresh rate of the display apparatus is 120 Hz, for example, the driving frequency of the touch sensor or the near touch sensor can be higher than 120 Hz (typically 240 Hz). With this structure, low power consumption can be achieved, and the response speed of the touch sensor or the near touch sensor can be increased.

For high-resolution image capturing, the subpixels PS are preferably provided in all pixels included in the display apparatus. Meanwhile, in the case where the subpixels PS are used in a touch sensor, a near touch sensor, or the like, high accuracy is not required as compared to the case of capturing an image of a fingerprint or the like: accordingly, the subpixels PS are provided in some of the pixels in the display apparatus. When the number of subpixels PS included in the display apparatus is smaller than the number of subpixels R or the like, higher detection speed can be achieved.

FIG. 24E illustrates an example of the pixel circuit of the subpixel including a light-receiving device. FIG. 24F illustrates an example of the pixel circuit of the subpixel including a light-emitting apparatus.

A pixel circuit PIX1 illustrated in FIG. 24E includes a light-receiving device PD, a transistor M11, a transistor M12, a transistor M13, a transistor M14, and a capacitor C2. Here, an example in which a photodiode is used as the light-receiving device PD is illustrated.

An anode of the light-receiving device PD is electrically connected to a wiring V1 and a cathode of the light-receiving device PD is electrically connected to one of a source and a drain of the transistor M11. A gate of the transistor M11 is electrically connected to a wiring TX, and the other of the source and the drain of the transistor M11 is electrically connected to one electrode of the capacitor C2, one of a source and a drain of the transistor M12, and a gate of the transistor M13. A gate of the transistor M12 is electrically connected to a wiring RES, and the other of the source and the drain thereof is electrically connected to a wiring V2. One of a source and a drain of the transistor M13 is electrically connected to a wiring V3, and the other of the source and the drain thereof is electrically connected to one of a source and a drain of the transistor M14. A gate of the transistor M14 is electrically connected to a wiring SE, and the other of the source and the drain thereof is electrically connected to a wiring OUT1.

A constant potential is supplied to the wiring V1, the wiring V2, and the wiring V3. When the light-receiving device PD is driven with a reverse bias, a potential higher than the potential of the wiring V1 is supplied to the wiring V2. The transistor M12 is controlled by a signal supplied to the wiring RES and has a function of resetting the potential of a node connected to the gate of the transistor M13 to a potential supplied to the wiring V2. The transistor M11 is controlled by a signal supplied to the wiring TX and has a function of controlling the timing at which the potential of the node changes, in accordance with a current flowing through the light-receiving device PD. The transistor M13 functions as an amplifier transistor performing an output corresponding to the potential of the node. The transistor M14 is controlled by a signal supplied to the wiring SE and functions as a selection transistor for reading an output corresponding to the potential of the node by an external circuit connected to the wiring OUT1.

A pixel circuit PIX2 illustrated in FIG. 24F includes a light-emitting apparatus EL, a transistor M15, a transistor M16, a transistor M17, and a capacitor C3. Here, an example in which a light-emitting diode is used as the light-emitting apparatus EL is illustrated. In particular, an organic EL apparatus is preferably used as the light-emitting apparatus EL.

A gate of the transistor M15 is electrically connected to a wiring VG, one of a source and a drain thereof is electrically connected to a wiring VS, and the other of the source and the drain thereof is electrically connected to one electrode of the capacitor C3 and a gate of the transistor M16. One of a source and a drain of the transistor M16 is electrically connected to a wiring V4, and the other of the source and the drain thereof is electrically connected to an anode of the light-emitting apparatus EL and one of a source and a drain of the transistor M17. A gate of the transistor M17 is electrically connected to a wiring MS, and the other of the source and the drain thereof is electrically connected to a wiring OUT2. A cathode of the light-emitting apparatus EL is electrically connected to a wiring V5.

A constant potential is supplied to the wiring V4 and the wiring V5. In the light-emitting apparatus EL, an anode side can have a high potential and a cathode side can have a lower potential than the anode side. The transistor M15 is controlled by a signal supplied to the wiring VG and functions as a selection transistor for controlling a selection state of the pixel circuit PIX2. The transistor M16 functions as a driving transistor that controls current flowing through the light-emitting apparatus EL, in accordance with a potential supplied to the gate. When the transistor M15 is in a conduction state, a potential supplied to the wiring VS is supplied to the gate of the transistor M16, and the emission luminance of the light-emitting apparatus EL can be controlled in accordance with the potential. The transistor M17 is controlled by a signal supplied to the wiring MS and has a function of outputting a potential between the transistor M16 and the light-emitting apparatus EL to the outside through the wiring OUT2.

Here, a transistor in which a metal oxide (an oxide semiconductor) is used in a semiconductor layer where a channel is formed is preferably used as each of the transistor M11, the transistor M12, the transistor M13, and the transistor M14 included in the pixel circuit PIX1 and the transistor M15, the transistor M16, and the transistor M17 included in the pixel circuit PIX2.

A transistor using a metal oxide having a wider band gap and a lower carrier density than silicon can achieve extremely low off-state current. Thus, such a low off-state current enables retention of charge accumulated in a capacitor that is connected in series with the transistor for a long time. For that reason, a transistor using an oxide semiconductor is preferably used particularly as the transistor M11, the transistor M12, and the transistor M15 each of which is connected in series with the capacitor C2 or the capacitor C3. Moreover, the use of transistors using an oxide semiconductor as the other transistors can reduce the manufacturing cost. However, one embodiment of the present invention is not limited thereto. A transistor in which silicon is used in a semiconductor layer (hereinafter, also referred to as a Si transistor) may be used.

Note that the off-state current per micrometer of channel width of an OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of the OS transistor is lower than that of the Si transistor by approximately ten orders of magnitude.

Note that the display apparatus of one embodiment of the present invention has a structure including the OS transistor and the light-emitting apparatus having an MML (metal maskless) structure. This structure can significantly reduce the leakage current that might flow through the transistor and the leakage current that might flow between adjacent light-emitting apparatuses (also referred to as a lateral leakage current, side leakage current, or the like). In addition, with this structure, a viewer can notice any one or more of image crispness, image sharpness, and a high contrast ratio in an image displayed on the display apparatus. With the structure where the leakage current that might flow through the transistor and the lateral leakage current that might flow between light-emitting apparatuses are extremely low, display with little leakage of light or the like at the time of black display (such display is also referred to as completely black display) can be achieved.

To increase the emission luminance of the light-emitting apparatus included in the pixel circuit, the amount of current flowing through the light-emitting apparatus needs to be increased. For that purpose, the source-drain voltage of the driving transistor included in the pixel circuit needs to be increased. Since an OS transistor has a higher withstand voltage between the source and the drain than a Si transistor, a high voltage can be applied between the source and the drain of the OS transistor. Thus, with use of an OS transistor as the driving transistor included in the pixel circuit, a high voltage can be applied between a source and a drain of the OS transistor, so that the amount of current flowing through the light-emitting apparatus can be increased and the emission luminance of the light-emitting apparatus can be increased.

When transistors operate in a saturation region, a change in source-drain current due to a change in gate-source voltage can be smaller in an OS transistor than in a Si transistor. Accordingly, when an OS transistor is used as the driving transistor in the pixel circuit, the amount of current flowing between the source and the drain can be set minutely by a change in gate-source voltage: hence, the amount of current flowing through the light-emitting apparatus can be controlled minutely. Therefore, the emission luminance of the light-emitting apparatus can be controlled minutely (the number of gray levels in the pixel circuit can be increased).

Regarding saturation characteristics of current flowing when transistors operate in a saturation region, even in the case where the source-drain voltage of an OS transistor increases gradually, a more stable constant current (saturation current) can be fed through the OS transistor than through a Si transistor. Thus, by using an OS transistor as the driving transistor, a stable constant current can be fed through light-emitting apparatuses that contain an EL material even when the current-voltage characteristics of the light-emitting apparatuses vary, for example. In other words, when the OS transistor operates in the saturation region, the source-drain current hardly changes with an increase in the source-drain voltage: hence, the emission luminance of the light-emitting apparatus can be stable.

As described above, by using OS transistors as the driving transistors included in the pixel circuits, it is possible to “inhibit black-level degradation”, “increase the luminance”, “increase the number of gray levels”, “suppress variations”, or the like in light-emitting apparatuses. Therefore, a display apparatus including the pixel circuit can display a clear and smooth image: as a result, any one or more of the image clearness, the image sharpness, and a high contrast ratio can be observed. When the driving transistor included in the pixel circuit has an extremely low off-state current, the display apparatus can perform black display with as little light leakage as possible (completely black display).

Alternatively, transistors using silicon as a semiconductor layer where a channel is formed can be used as the transistor M11 to the transistor M17. In particular, the use of silicon with high crystallinity, such as single crystal silicon or polycrystalline silicon, is preferable because high field-effect mobility is achieved and a higher-speed operation is possible.

Alternatively, a transistor containing an oxide semiconductor (an OS transistor) may be used as one or more of the transistor M11 to the transistor M17, and transistors containing silicon (Si transistors) may be used as the other transistors. Note that as the Si transistor, a transistor containing low-temperature polysilicon (LTPS) (hereinafter, referred to as an LTPS transistor) can be used. A structure in which an OS transistor and an LTPS transistor are combined is referred to as LTPO in some cases. By employing LTPO in which an LTPS transistor with a high mobility and an OS transistor with a low off-state current are used, a display panel with high display quality can be provided.

Note that although n-channel transistors are illustrated as the transistors in FIG. 24E and FIG. 24F, p-channel transistors can be used.

The transistors included in the pixel circuit PIX1 and the transistors included in the pixel circuit PIX2 are preferably formed side by side over the same substrate. It is particularly preferable that the transistors included in the pixel circuit PIX1 and the transistors included in the pixel circuit PIX2 be periodically arranged in one region.

One or more layers including one or both of the transistor and the capacitor are preferably provided in positions overlapping with the light-receiving device PD or the light-emitting apparatus EL. Thus, the effective occupation area of each pixel circuit can be reduced, and a high-resolution light-receiving portion or display portion can be achieved.

At least part of this embodiment can be implemented in combination with the other embodiments described in this specification as appropriate.

### Embodiment 11

In this embodiment, a metal oxide (also referred to as an oxide semiconductor) that can be used in the OS transistor described in the above embodiment will be described.

A metal oxide used in the OS transistor preferably contains at least indium or zinc, and further preferably contains indium and zinc. The metal oxide preferably contains indium, M (M is one or more of gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. In particular, M is preferably one or more kinds selected from gallium, aluminum, yttrium, and tin, and is further preferably gallium.

It is particularly preferable to use an oxide containing indium (In), gallium (Ga), and zinc (Zn) (also referred to as IGZO) as the metal oxide used for the OS transistor. Alternatively, an oxide containing indium (In), aluminum (Al), and zinc (Zn) (also referred to as IAZO) may be used as the metal oxide used for the OS transistor. Alternatively, an oxide containing indium (In), aluminum (Al), gallium (Ga), and zinc (Zn) (also referred to as IAGZO) may be used as the metal oxide used for the OS transistor.

The metal oxide can be formed by a sputtering method, a chemical vapor deposition (CVD) method such as a metal organic chemical vapor deposition (MOCVD) method, an atomic layer deposition (ALD) method, or the like.

Hereinafter, an oxide containing indium (In), gallium (Ga), and zinc (Zn) is described as an example of the metal oxide. Note that an oxide containing indium (In), gallium (Ga), and zinc (Zn) may be referred to as an In—Ga—Zn oxide.

### <Classification of Crystal Structure>

Amorphous (including a completely amorphous structure), CAAC (c-axis-aligned crystalline), nc (nanocrystalline), CAC (cloud-aligned composite), single-crystal, polycrystalline (poly crystal) structures, and the like can be given as examples of a crystal structure of an oxide semiconductor.

Note that the crystal structure of a film or a substrate can be evaluated with an X-ray diffraction (XRD) spectrum. For example, evaluation is possible using an XRD spectrum that is obtained by GIXD (Grazing-Incidence XRD) measurement. Note that a GIXD method is also referred to as a thin film method or a Seemann-Bohlin method. Hereinafter, an XRD spectrum obtained from GIXD measurement is simply referred to as an XRD spectrum in some cases.

For example, the XRD spectrum of a quartz glass substrate shows a peak with a substantially bilaterally symmetrical shape. On the other hand, the peak of the XRD spectrum of the In—Ga—Zn oxide film having a crystal structure has a bilaterally asymmetrical shape. The bilaterally asymmetrical peak of the XRD spectrum clearly shows the existence of crystal in the film or the substrate. In other words, the film or the substrate cannot be regarded as being in an amorphous state unless it has a bilaterally symmetrical peak in the XRD spectrum.

In addition, the crystal structure of a film or a substrate can also be evaluated with a diffraction pattern observed by a nanobeam electron diffraction method (NBED) (such a pattern is also referred to as a nanobeam electron diffraction pattern). For example, a halo pattern is observed in the diffraction pattern of the quartz glass substrate, which indicates that the quartz glass substrate is in an amorphous state. Furthermore, not a halo pattern but a spot-like pattern is observed in the diffraction pattern of the In—Ga—Zn oxide film formed at room temperature. Thus, it is presumed that the In—Ga—Zn oxide film formed at room temperature is in an intermediate state, which is neither a single crystal nor polycrystalline state nor an amorphous state, and that it cannot be concluded that the In—Ga—Zn oxide film is in an amorphous state.

### <<Structure of Oxide Semiconductor>>

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductors include the above-described CAAC-OS and nc-OS. Other examples of the non-single-crystal oxide semiconductor include a polycrystalline oxide semiconductor, an amorphous-like oxide semiconductor (a-like OS), an amorphous oxide semiconductor, and the like.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of a surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the orientation of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more minute crystals (crystals each of which has a maximum diameter of less than 10 nm). In the case where the crystal region is formed of one minute crystal, the maximum diameter of the crystal region is less than 10 nm. In the case where the crystal region is formed of a large number of minute crystals, the size of the crystal region may be approximately several tens of nanometers.

In the case of an In—Ga—Zn oxide, the CAAC-OS tends to have a layered crystal structure (also referred to as a layered structure) in which a layer containing indium (In) and oxygen (hereinafter, an In layer) and a layer containing gallium (Ga), zinc (Zn), and oxygen (hereinafter, a (Ga,Zn) layer) are stacked. Indium and gallium can be replaced with each other. Therefore, indium may be contained in the (Ga,Zn) layer. In addition, gallium may be contained in the In layer. Note that zinc may be contained in the In layer. Such a layered structure is observed as a lattice image in a high-resolution TEM (Transmission Electron Microscope) image, for example.

When the CAAC-OS film is subjected to structural analysis by out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of an incident electron beam passing through a sample (also referred to as a direct spot) as a symmetric center.

When the crystal region is observed from the particular direction, a lattice arrangement in the crystal region is basically a hexagonal lattice arrangement: however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (also referred to as grain boundary) cannot be observed even in the vicinity of the distortion in the CAAC-OS. That is, it is found that formation of a crystal grain boundary is inhibited by the distortion of a lattice arrangement. This is probably because the CAAC-OS can tolerate distortion owing to a low density of arrangement of oxygen atoms in the a-b plane direction, an interatomic bond distance changed by substitution of a metal atom, and the like.

Note that a crystal structure in which a clear crystal grain boundary is observed is what is called polycrystal. It is highly probable that the grain boundary becomes a recombination center and traps carriers and thus decreases the on-state current and field-effect mobility of a transistor. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, it can be said that a reduction in electron mobility due to the crystal grain boundary is unlikely to occur. Moreover, since the crystallinity of an oxide semiconductor might be decreased by entry of impurities, formation of defects, or the like, the CAAC-OS can be regarded as an oxide semiconductor that has small amounts of impurities and defects (e.g., oxygen vacancies). Thus, an oxide semiconductor including the CAAC-OS is physically stable. Accordingly, the oxide semiconductor including the CAAC-OS is resistant to heat and has high reliability. In addition, the CAAC-OS is also stable with respect to high temperatures in the manufacturing process (what is called thermal budget). Accordingly, the use of the CAAC-OS for the OS transistor can extend the degree of freedom of the manufacturing process. [nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm: thus, the minute crystal is also referred to as a nanocrystal. Furthermore, there is no regularity of crystal orientation between different nanocrystals in the nc-OS. Thus, the orientation in the whole film is not observed. Accordingly, in some cases, the nc-OS cannot be distinguished from an a-like OS or an amorphous oxide semiconductor, depending on the analysis method. For example, when an nc-OS film is subjected to structural analysis by out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., larger than or equal to 1 nm and smaller than or equal to 30 nm).

[a-Like OS]

The a-like OS is an oxide semiconductor having a structure between those of the nc-OS and the amorphous oxide semiconductor. The a-like OS contains a void or a low-density region. That is, the a-like OS has low crystallinity than the nc-OS and the CAAC-OS. Moreover, the a-like OS has a higher hydrogen concentration in the film than the nc-OS and the CAAC-OS.

### <<Structure of Oxide Semiconductor>>

Next, the above-described CAC-OS will be described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide is a region having [In] higher than [In] in the composition of the CAC-OS film. Moreover, the second region is a region having [Ga] higher than [Ga] in the composition of the CAC-OS film. Alternatively, for example, the first region is a region having [In] higher than [In] in the second region and [Ga] lower than [Ga] in the second region. Moreover, the second region is a region having [Ga] higher than [Ga] in the first region and [In] lower than [In] in the first region.

Specifically, the first region includes indium oxide or indium zinc oxide as its main component. The second region includes gallium oxide or gallium zinc oxide as its main component. That is, the first region can be rephrased as a region containing In as its main component. The second region can be rephrased as a region containing Ga as its main component.

Note that a clear boundary between the first region and the second region cannot be observed in some cases.

In addition, in a material composition of a CAC-OS in an In—Ga—Zn oxide that contains In, Ga, Zn, and O, there are regions containing Ga as a main component in part of the CAC-OS and regions containing In as a main component in another part of the CAC-OS. These regions each form a mosaic pattern and are randomly present. Thus, it is suggested that the CAC-OS has a structure in which metal elements are unevenly distributed.

The CAC-OS can be formed by a sputtering method under a condition where a substrate is not heated intentionally, for example. Furthermore, in the case where the CAC-OS is formed by a sputtering method, any one or more selected from an inert gas (typically, argon), an oxygen gas, and a nitrogen gas is used as a deposition gas. The proportion of the flow rate of an oxygen gas in the total flow rate of the deposition gas during deposition is preferably as low as possible. For example, the proportion of the flow rate of an oxygen gas in the total flow rate of the deposition gas during deposition is preferably higher than or equal to 0% and lower than 30%, further preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has higher conductivity than the second region. In other words, when carriers flow through the first region, the conductivity of a metal oxide is exhibited. Accordingly, when the first regions are distributed in a metal oxide like a cloud, high field-effect mobility (u) can be achieved.

The second region has a higher insulating property than the first region. In other words, when the second regions are distributed in a metal oxide, leakage current can be inhibited.

Thus, in the case where a CAC-OS is used for a transistor, by the complementary action of the conductivity due to the first region and the insulating property due to the second region, the CAC-OS can have a switching function (On/Off function). That is, the CAC-OS has a conducting function in part of the material and has an insulating function in another part of the material: as a whole, the CAC-OS has a function of a semiconductor. Separation of the conducting function and the insulating function can maximize each function. Accordingly, when the CAC-OS is used for a transistor, high on-state current (Ion), high field-effect mobility (u), and excellent switching operation can be achieved.

A transistor using the CAC-OS has high reliability. Thus, the CAC-OS is most suitable for a variety of semiconductor devices such as typified by a display apparatus.

An oxide semiconductor has various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### <Transistor Containing Oxide Semiconductor>

Next, the case where the above oxide semiconductor is used for a transistor will be described.

When the above oxide semiconductor is used for a transistor, a transistor with high field-effect mobility can be achieved. In addition, a transistor having high reliability can be achieved.

An oxide semiconductor having a low carrier concentration is preferably used for a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration is sometimes referred to as a highly purified intrinsic or substantially highly purified intrinsic oxide semiconductor.

A highly purified intrinsic or substantially highly purified intrinsic oxide semiconductor film has a low density of defect states and thus also has a low density of trap states in some cases.

In addition, electric charge captured by the trap states in an oxide semiconductor takes a long time to disappear and might behave like fixed electric charge. Thus, a transistor whose channel formation region is formed in an oxide semiconductor having a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, silicon, and the like. Note that an impurity in an oxide semiconductor refers to, for example, elements other than the main components of the oxide semiconductor. For example, an element with a concentration lower than 0.1 atomic % can be regarded as an impurity.

### <Impurity>

Here, the influence of each impurity in the oxide semiconductor will be described.

When silicon or carbon, which is a Group 14 element, is contained in an oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are each set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained by SIMS, is set lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. Alternatively, when nitrogen is contained in the oxide semiconductor, a trap state is sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. For this reason, hydrogen in the oxide semiconductor is preferably reduced as much as possible. Specifically, the concentration of hydrogen in the oxide semiconductor, which is obtained by SIMS, is lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

At least part of this embodiment can be implemented in combination with the other embodiments described in this specification as appropriate.

### Embodiment 12

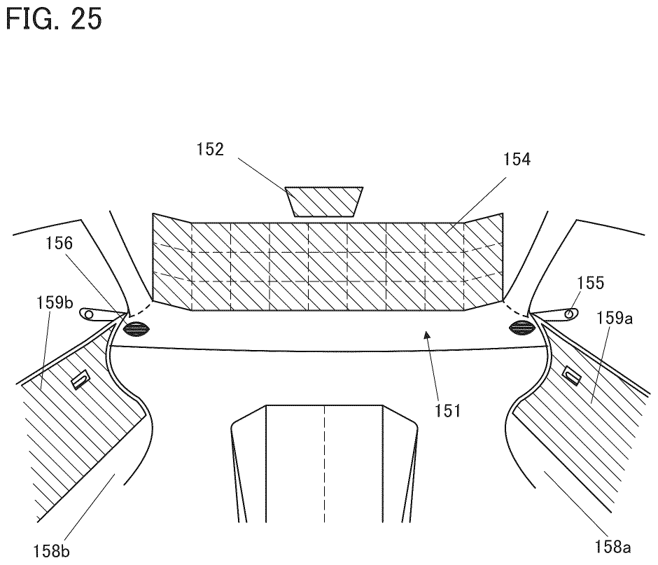

In this embodiment, electronic devices that use the display apparatus of one embodiment of the present invention will be described with reference to FIG. 25.

In this embodiment, an example in which the display apparatus described in any one of Embodiments 1 to 3 is installed inside the vehicle will be described.

FIG. 25 is a diagram illustrating a configuration example of a vehicle. FIG. 25 illustrates a dashboard 151 placed around a driver's seat, a display apparatus 154 fixed in front of the driver's seat, a camera 155, an outlet 156, a door 158a on the right side of the driver's seat, a door 158b on the left side of the driver's seat, and the like. The display apparatus 154 extends in front of the driver's seat.

As the display apparatus 154 fixed in front of the driver's seat, the display apparatus in any one of Embodiments 1 to 3 can be used. FIG. 25 shows an example in which the display apparatus 154 is one display surface consisting of display apparatuses arranged in a matrix of three columns and nine rows, i.e., 27 light-emitting apparatuses in total. Although a boundary between pixel regions is indicated by a dotted line in FIG. 25, the dotted line is not displayed in an actual display image and a seam is not generated or is less noticeable. Moreover, the display apparatus 154 may have a see-through structure including a light-transmitting region through which the outside can be seen.

The display apparatus 154 is preferably provided with a touch sensor or a non-contact proximity sensor. Alternatively, the display apparatus 154 is preferably operated by gestures with use of a camera or the like that is separately provided.

Although FIG. 25 illustrates a vehicle capable of autonomous driving having no handle (also referred to as steering wheel), the present invention is not limited thereto. A handle may be provided, and the handle may be provided with a display apparatus having a curved surface; in this case, the structure described in any one of Embodiments 1 to 3 can be employed.

In addition, a plurality of cameras 155 that take pictures of the situations at the rear side may be provided outside the vehicle. Although the camera 155 is provided instead of a side mirror in the example illustrated in FIG. 25, both the side mirror and the camera may be provided. As the camera 155, a CCD camera, a CMOS camera, or the like can be used. In addition, an infrared camera may be used in combination with such a camera. The infrared camera, which has a higher output level with a higher temperature of an object, can sense or extract a living body such as a human or an animal.

An image taken by the camera 155 can be output to a part or a whole of the display apparatus 154. This display apparatus 154 is mainly used for supporting driving of the vehicle. An image of the situation on the rear side is taken at a wide angle of view by the camera 155, and the image is displayed on the display apparatus 154 so that the driver can see a blind area to avoid an accident.

Furthermore, a distance image sensor may be provided over a roof of the vehicle, for example, and an image obtained by the distance image sensor may be displayed on the display apparatus 154. For the distance image sensor, an image sensor, LIDAR (Light Detection and Ranging), or the like can be used. An image obtained by the image sensor and the image obtained by the distance image sensor are displayed on the display apparatus 154, whereby more information can be provided to the driver to support driving.

In addition, a display apparatus 152 having a curved surface can be provided inside a roof of the vehicle, that is, in a roof portion, for example. In the case where the display apparatus 152 having a curved surface is provided in the roof portion or the like, the display apparatus described in any one of Embodiments 1 to 3 can be used.

The display apparatus 152 and the display apparatus 154 may also have a function of displaying map information, traffic information, television images, DVD images, and the like.

The image displayed on the display apparatus 154 can be freely set to meet the driver's preference. For example, television images, DVD images, or online videos can be displayed on an image region on the left side, map information can be displayed on an image region or the like at the center, and meters such as a speed meter and a tachometer can be displayed on an image region on the right side.

In FIG. 25, a display apparatus 159a and a display apparatus 159b are provided along a surface of the door 158a on the right side and a surface of the door 158b on the left side, respectively. The display apparatus 159a and the display apparatus 159b can each be formed using one or more display apparatuses. For example, one display surface is formed using display apparatuses arranged in one row and three columns.

The display apparatus 159a and the display apparatus 159b are provided to face each other.

A display apparatus having an image capturing function is preferably used as at least one of the display apparatuses 152, 154, 159a, and 159b.

For example, when the driver touches an image region of at least one of the display apparatuses 152, 154, 159a, and 159b, biological authentication such as fingerprint authentication or palm print authentication can be performed. The vehicle may have a function of setting an environment to meet the driver's preference when the driver is authenticated by biometric authentication. For example, one or more of adjustment of the position of the seat, adjustment of the position of the steering wheel, adjustment of the direction of the cameras 155, setting of brightness, setting of an air conditioner, setting of the speed (frequency) of wipers, volume setting of audio, and reading of the playlist of the audio are preferably performed after authentication.

Alternatively, a motor vehicle can be automatically brought into a state where the motor vehicle can be driven, e.g., a state where an engine is started or a state where an electric vehicle can be started, after the driver is authenticated by biological authentication. This is preferable because a key, which is conventionally necessary, is unnecessary.

Although the display apparatus that surrounds the driver's seat is described here, a display apparatus can be provided to surround also a passenger on a rear seat.

As described above, the structure of one embodiment of the present invention improves flexibility in design of a display apparatus and thus can improve design of the display apparatus. The display apparatus of one embodiment of the present invention can be suitably used in a vehicle or the like.

At least part of this embodiment can be implemented in combination with the other embodiments described in this specification as appropriate.

### Example

In this example, end portions of display panels each formed using a flexible substrate were overlapped with each other, and a vertical stripe that might be generated in a portion (the vicinity of a boundary) of the two stacked display panels was observed in each of the case of providing a light-blocking layer such as a black matrix and the case of not providing the light-blocking layer.

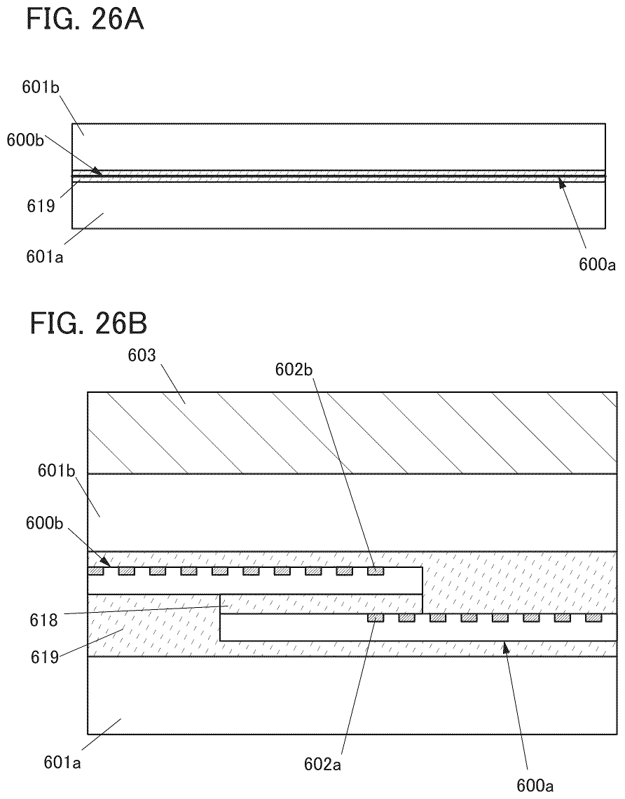

FIG. 26A is a schematic cross-sectional view illustrating the structure of the fabricated sample.

By employing a known method, two active matrix substrates having an organic EL apparatus were fabricated. A transistor and an organic EL apparatus were formed over a first film, a black matrix was formed over a second film, and then the films were bonded to fabricate a first display panel 600a. The first film and the second film were each formed using a film having a cycloolefin polymer with a refractive index of 1.53.

A second display panel 600b having the same pixel layout and the same structure as the first display panel 600a was fabricated in a similar manner. FIG. 26A illustrates a structure in which the first display panel 600a and the second display panel 600b are sandwiched between acrylic resin substrates 601a and 601b using a resin 619 for filling.

FIG. 26B shows an enlarged view of a structure where a circularly polarizing plate is provided over the acrylic resin substrate 601b.

As illustrated in FIG. 26B, an end portion of a pixel region of the first display panel 600a and an end portion of a pixel region of the second display panel 600b are fixed to overlap with each other using a resin 618 for adhesion. Note that position adjustment is performed so that a black matrix 602a of the first display panel 600a and a black matrix 602b of the second display panel 600b overlap with each other. Furthermore, as illustrated in FIG. 26B, a space between the two acrylic resin substrates 601a and 601b is filled with the resin 619 for filling. As the resin 618 for adhesion and the resin 619 for filling, an epoxy resin with a refractive index of 1.55 is used. These resins are not particularly limited to such a material as long as they are materials whose refractive indices have a small difference from the refractive indices of the first film and the second film, which are 1.53.

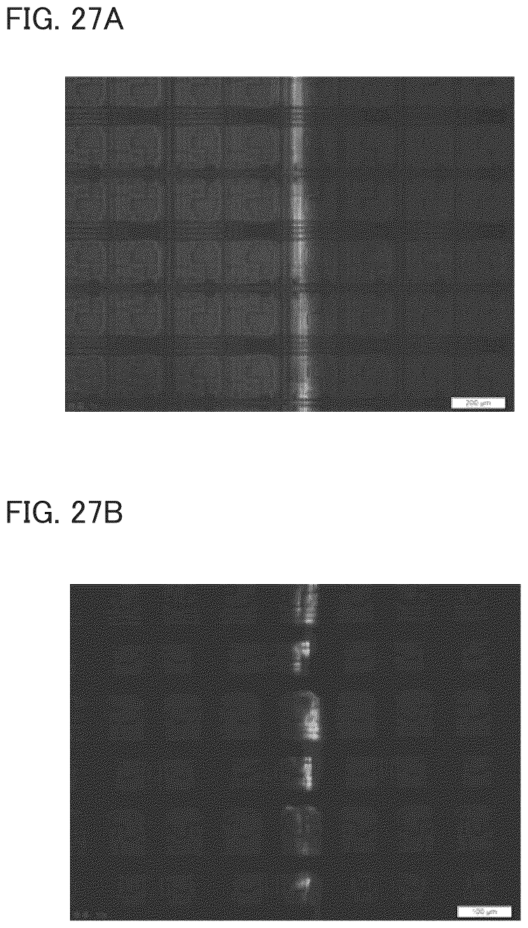

In addition, for comparison, a third display panel was fabricated by bonding the second film where a black matrix was not formed. In addition, a fourth display panel having the same pixel layout and the same structure as the third display panel was fabricated in a similar manner. FIG. 27A shows the result of observation performed on the structure, which is the same except for the black matrix, from above the circularly polarizing plate using a microscope.

FIG. 27B shows the result of observation performed on the structure with the black matrix from above the circularly polarizing plate.

In the result in FIG. 27B, the vertical stripe is less noticeable than that in FIG. 27A: thus, this example reveals that the structure with the black matrix is preferable.

Note that this example is an example for confirming that the appearance of the vertical stripe differs depending on the presence or absence of the black matrix, and is an experimental example where the two display panels are actually overlapped with each other in a simplified manner. The structure of this example is different from the numerous structures disclosed in this specification, and is not particularly limited.

### REFERENCE NUMERALS

10: support body, 11: support body, 12: wiring layer, 12a: wiring layer, 12b: wiring layer, 13: cover member, 14a: light-emitting direction, 14b: light-emitting direction, 15: region, 16a: display apparatus, 16b: display apparatus, 16c: display apparatus, 17a: display apparatus, 17b: display apparatus, 17c: display apparatus, 17d: display apparatus, 18a: electrode, 18b: electrode, 18d: electrode, 19: resin, 20: interlayer insulating film, 20a: driver circuit portion, 20b: driver circuit, 90B: light-emitting apparatus, 90G: light-emitting apparatus, 90R: light-emitting apparatus, 90S: light-receiving apparatus, 100: display region, 101: layer, 110: pixel, 110a: subpixel, 110b: subpixel, 110c: subpixel, 111: pixel electrode, 111a: pixel electrode, 111b: pixel electrode, 111c: pixel electrode, 111C: connection electrode, 111G: pixel electrode, 111R: pixel electrode, 112B: material layer, 112G: material layer, 112R: material layer, 113: common electrode, 113a: material layer, 113b: material layer, 113c: material layer, 114: material layer, 115: common electrode, 120: substrate, 121: protective layer, 122: resin layer, 124a: pixel, 124b: pixel, 125: insulating layer, 126: resin layer, 127: insulating layer, 130: connection portion, 130a: light-emitting apparatus, 130b: light-emitting apparatus, 130c: light-emitting apparatus, 131: insulating layer, 132: insulating layer, 140: connection portion, 151: dashboard, 152: display apparatus, 154: display apparatus, 155: camera, 156: outlet, 158a: door, 158b: door, 159a: display apparatus, 159b: display apparatus, 200: display panel, 200A: display panel, 200B: display panel, 201: substrate, 202: substrate, 203: functional circuit layer, 211: light-emitting apparatus, 211B: light-emitting apparatus, 211G: light-emitting apparatus, 211IR: light-emitting apparatus, 211R: light-emitting apparatus, 211W: light-emitting apparatus, 211X: light-emitting apparatus, 212: light-receiving apparatus, 213R: light-emitting and light-receiving apparatus, 220: finger, 221: contact portion, 222: fingerprint, 223: image-capturing range, 225: stylus, 226: path, 252: transistor, 258: transistor, 259: transistor, 260: transistor, 261: insulating layer, 262: insulating layer, 264: insulating layer, 265: insulating layer, 268: insulating layer, 271: conductive layer, 272a: conductive layer, 272b: conductive layer, 273: conductive layer, 275: insulating layer, 278: connection portion, 281: semiconductor layer, 281i: channel formation region, 281n: low-resistance region, 400: display apparatus, 411a: conductive layer, 411b: conductive layer, 411c: conductive layer, 412G: EL layer, 412S: photoelectric conversion layer, 413: common electrode, 414: organic material layer, 416: protective layer, 417: light-blocking layer, 421: insulating layer, 422: resin layer, 430b: light-emitting apparatus, 440: light-receiving apparatus, 442: adhesive layer, 451: substrate, 452: substrate, 453: substrate, 454: substrate, 455: adhesive layer, 462: display portion, 464: circuit, 465: wiring, 473: electrode, 500: display panel, 500a: display panel, 500b: display panel, 500c: display panel, 500d: display panel, 501: display region, 501a: display region, 501b: display region, 501c: display region, 501d: display region, 510: region, 510b: region, 510c: region, 510d: region, 520: region, 520b: region, 520c: region, 550: stacked-layer panel, 551: display region, 600a: display panel, 600b: display panel, 601a: acrylic resin substrate, 601b: acrylic resin substrate, 602a: black matrix, 602b: black matrix, 618: resin, 619: resin, 711: light-emitting layer, 712: light-emitting layer, 713: light-emitting layer, 720: layer, 720-1: layer, 720-2: layer, 730: layer, 730-1: layer, 730-2: layer, 750: light-emitting apparatus, 750B: light-emitting apparatus, 750G: light-emitting apparatus, 750R: light-emitting apparatus, 751: layer, 752: layer, 753B: light-emitting layer, 753G: light-emitting layer, 753R: light-emitting layer, 754: laver, 755: layer, 760: light-receiving apparatus, 761: layer, 762: layer, 763: layer, 775: layer, 790: EL layer, 790a: EL layer, 790b: EL layer, 791: lower electrode, 791B: pixel electrode, 791G: pixel electrode, 791PD: pixel electrode, 791R: pixel electrode, 792: upper electrode, 795: coloring layer

1. An electronic device comprising:
a display apparatus; and
a support body,
wherein the display apparatus comprises:
a first flexible substrate;
a second flexible substrate;
a first display panel formed over the first flexible substrate;
a second display panel formed over the second flexible substrate;
a first electrode electrically connected to the first display apparatus panel; and
a second electrode electrically connected to the second display panel,
wherein the support body comprises a curved surface and a wiring layer formed along the curved surface,
wherein the first display panel is electrically connected to the wiring layer through the first electrode,
wherein the second display panel is electrically connected to the wiring layer through the second electrode, and
wherein each of the first display panel and the second display panel is provided along the curved surface.

2. An electronic device comprising:
a display apparatus; and
a support body,
wherein the display apparatus comprises:
a first flexible substrate;
a second flexible substrate;
a first display panel formed over the first flexible substrate;
a second display panel formed over the second flexible substrate;
a first electrode electrically connected to the first display panel; and
a second electrode electrically connected to the second display panel,
wherein the first display apparatus comprises a pixel region,
wherein the pixel region comprises a first light-emitting apparatus, and a second light-emitting device provided adjacent to the first light-emitting apparatus, and
wherein each of the first light-emitting apparatus and the second light-emitting device comprises:
a lower electrode;
a first functional layer over the lower electrode;
a light-emitting layer over the first functional layer;
a second functional layer over the light-emitting layer; and
an upper electrode over the second functional layer.

3. The electronic device according to claim 2,
wherein each of the first light-emitting apparatus and the second light-emitting apparatus comprises:
the lower electrode;
the first functional layer over the lower electrode;
a first light-emitting layer over the first functional layer;
a common layer over the first light-emitting layer;
a second light-emitting layer over the common layer;
the second functional layer over the second light-emitting layer; and
the upper electrode over the second functional layer.

4. The electronic device according to claim 2,
wherein the first functional layer comprises one or both of a hole-injection layer and a hole-transport layer, and
wherein the second functional layer comprises one or both of an electron-transport layer and an electron-injection layer.

5. The electronic device according to claim 2,
wherein a side surface of the first functional layer and a side surface of the light-emitting layer are aligned or substantially aligned in a cross-sectional view.

6. The electronic device according to claim 3,
wherein a side surface of the first functional layer, a side surface of the first light-emitting layer, and a side surface of the second light-emitting layer are aligned or substantially aligned in a cross-sectional view.

7. The electronic device according to claim 1,
wherein light emitted from the first light-emitting apparatus and light emitted from the second light-emitting apparatus have the same color.

8. The electronic device according to claim 2,
wherein the first light-emitting apparatus comprises:
a first lower electrode;
a first functional layer over the first lower electrode;
a first light-emitting layer over the first functional layer;
a second functional layer over the first light-emitting layer; and
an upper electrode over the second functional layer, and
wherein the second light-emitting apparatus comprises:
a second lower electrode;
a third functional layer over the second lower electrode;
a second light-emitting layer over the third functional layer; and
a fourth functional layer over the second light-emitting layer.

9. The electronic device according to claim 2,
wherein the first light-emitting apparatus comprises:
a first lower electrode;
a first functional layer over the first lower electrode;
a third light-emitting layer over the first functional layer;
a first common layer over the third light-emitting layer;
a fourth light-emitting layer over the first common layer;
a second functional layer over the fourth light-emitting layer; and
an upper electrode over the second functional layer, and
wherein the second light-emitting apparatus comprises:
a second lower electrode;
a third functional layer over the second lower electrode;
a fifth light-emitting layer over the third functional layer;
a second common layer over the fifth light-emitting layer;
a sixth light-emitting layer over the second common layer;
a fourth functional layer over the sixth light-emitting layer; and
an upper electrode over the fourth functional layer.

10. The electronic device according to claim 8,
wherein each of the first functional layer and the third functional layer comprises one or both of a hole-injection layer and a hole-transport layer, and
wherein each of the second functional layer and the fourth functional layer comprises one or both of an electron-transport layer and an electron-injection layer.

11. The electronic device according to claim 8,
wherein light emitted from the first light-emitting apparatus and light emitted from the second light-emitting apparatus have different colors from each other.

12. The electronic device according to claim 9,
wherein each of the first functional layer and the third functional layer comprises one or both of a hole-injection layer and a hole-transport layer, and
wherein each of the second functional layer and the fourth functional layer comprises one or both of an electron-transport layer and an electron-injection layer.

13. The electronic device according to claim 9,
wherein light emitted from the first light-emitting apparatus and light emitted from the second light-emitting apparatus have different colors from each other.
